(19) United States
(12) Patent Application Publication
(10) Pub. No.: US 2025/0103782 A1
(43) Pub. Date: Mar. 27, 2025

(54) SUBSURFACE GEOMECHANICS AND FLOW MODELING AND QUANTITATIVE RISK ASSESSMENT

(71) Applicant: Schlumberger Technology Corporation, Sugar Land, TX (US)

(72) Inventors: Claudia Sorgi, Pau (FR); Oscar Gabriel Cortez Gomez, Houston, TX (US); Soham Sheth, Abingdon (GB); Tom Jönsthövel, Lysaker (NO); Vincenzo De Gennaro, Pau (FR); Andreia Mandiuc, Pau (FR)

(21) Appl. No.: 18/896,423

(22) Filed: Sep. 25, 2024

Related U.S. Application Data
(60) Provisional application No. 63/568,380, filed on Mar. 21, 2024.
(60) Provisional application No. 63/584,948, filed on Sep. 25, 2023.

(51) Int. Cl. G06F 30/28

(52) U.S. Cl. CPC G06F 30/28

(57) ABSTRACT

Certain aspects of the disclosure provide systems and methods for quantifying leakage risk in a geological storage complex. A method may include performing a plurality of simulated injections by executing geomechanical and fluid flow simulations on a subsurface model representing a geological storage complex, where model parameters are varied for one or more simulated injections. The method may include determining, for the one or more simulated injections, one or more leakage volumes for one or more surface locations in the geological storage complex, and calculating, for the one or more surface locations, one or more of: a leakage probability value indicating a simulated probability of leakage occurring at the surface location, or a leakage severity value indicating a simulated average amount of leakage volume at the surface location. The method may include determining leakage risk based on one or more of the leakage probability value or the leakage severity value.

### CROSS-REFERENCE TO RELATED APPLICATIONS

This application claims the benefit of and priority to U.S. Provisional Patent Application No. 63/584,948, filed on Sep. 25, 2023 and to U.S. Provisional Patent Application No. 63/568,380, filed on Mar. 21, 2024, the entire contents of which are hereby incorporated by reference.

### BACKGROUND

### Field

Aspects of the present disclosure relate to subsurface geomechanics and flow modeling.

### Description of Related Art

Carbon capture and storage (CCS) has emerged as an innovative technology in the ongoing efforts to mitigate the adverse effects of climate change caused by carbon dioxide (CO₂) emissions. The primary objective of CCS is to capture CO₂ emissions at their source and subsequently store them in a manner that prevents their release into the environment. In some cases, the first step in CCS is capturing the CO₂ at the source facility before it is emitted. Example capture techniques include pre-combustion capture, post-combustion capture, and oxyfuel combustion. Industrial facilities, power plants, and other significant emission sources may employ state-of-the-art technologies to separate and capture CO₂ from flue gases or directly from the ambient air. Common methodologies for this purpose encompass post-combustion capture, where CO₂ is separated after the combustion of fossil fuels; pre-combustion capture, wherein CO₂ is isolated before the full combustion of the fuel; and oxyfuel combustion, where combustion occurs in oxygen to produce a CO₂-rich exhaust. Advanced sorbents, cryogenic processes, and chemical solvents, among other techniques, facilitate efficient CO₂ separation. Captured CO₂ may then be compressed and transported to a geological storage site in a dense phase.

In some cases, the last step in CCS is the storage, often referred to as “sequestration,” of the extracted CO₂. Optimal storage locations are usually underground geological structures, such as exhausted oil and gas reservoirs, saline aquifers, or coal seams that are not suitable for mining. CO₂ is injected and stored, leveraging the natural trapping mechanisms of these geological structures to ensure long-term containment. When CO₂ is injected into the subsurface, it occupies pore space within rock formations. Over time, some injected CO₂ reacts with formation rocks and fluids to become immobilized. Impermeable caprock seals above the storage formation trap the buoyant CO₂ and prevent vertical migration. Lateral migration of the CO₂ plume is expected as injection continues over decades, and monitoring is applied to track the plume. As the CO₂ plume grows, it gradually displaces formation brine, increasing formation pressure around the injection site. The displacement of the formation brine can affect the storage reservoir's pore pressure and other geomechanical properties. Pressure management, often involving brine extraction, is typically applied to maintain safe operation pressures.

Carbon dioxide (CO₂) sequestration, while a promising technology for mitigating climate change, is not without its risks. Some of the potential risks associated with CO₂ sequestration include leakage, induced seismicity, groundwater contamination, and loss of reservoir integrity. These risk outcomes can lead to health and safety risks, negative public perception, long-term liability, economic viability, and operational challenges.

These storage sites' geological integrity, depth, and capacity are evaluated, such as to ensure minimal leakage and maximum storage efficiency. Monitoring technologies are deployed to track the location of the CO₂ plume and detect any potential leakage. However, a significant risk associated with CCS is the potential leakage of CO₂ from the storage complex through pathways such as faults, fractures, failed wellbores, and low permeability seals. Leakage can lead to safety concerns, environmental damage, contamination of underground drinking water sources, and reduced public acceptance of CCS technology.

Monitoring, measuring, and verification (MMV) methods are employed to manage risks and verify conformance to regulations. MMV methods rely heavily on simulations of CO₂ injection and fluid flow in the subsurface to predict the probability of leakage. These predictions are often generated using flow simulators that model multiphase fluid flow and transport in porous media and geomechanical simulators that model earth stresses, deformations, and failure from fluid injection. While flow and geomechanical simulators provide accurate physics-based predictions, simulations alone may not be sufficient to quantify risks of leakage of CO₂. Further, some simulations may be computationally intensive. For example, high-fidelity simulation of injection operations, plume migration, and potential leakage pathways may requires fine grid resolutions and long run times.

Assessing risks involves a systematic process to identify (risk assessment), analyze, prioritize, and score (risk analysis) the risks, develop mitigation strategies, and plan for MMV activities. In this context, risk assessment and analysis are often conducted involving qualitative approaches and/or subjective evaluations based on expert judgement.

Ensuring the safe storage of CO₂ over the long term requires an accurate management of the risks based on quantitative assessment of the behavior of the storage complex before, during, and after the injection operations. Existing CO₂ sequestration risk assessment approaches encompass a range of methodologies and frameworks aimed at comprehensively evaluating the potential hazards and consequences associated with Carbon capture and storage (CCS) projects

### SUMMARY

Certain aspects provide a method for quantifying leakage risk in a geological storage complex. The method may include performing a plurality of simulated injections by executing geomechanical and fluid flow simulations on a subsurface model representing a geological storage complex, wherein model parameters are varied for one or more simulated injections of the plurality of simulated injections. In some examples, the method includes determining, for the one or more simulated injections of the plurality of simulated injections, one or more leakage volumes for one or more surface locations in the geological storage complex. In some examples, the method includes calculating, for the one or more surface locations, one or more of: a leakage probability value based on the leakage volume determined for the surface location for the one or more simulated injections of the plurality of simulated injections, the leakage probability value indicating a simulated probability of leakage occurring at the surface location; or a leakage severity value based on the leakage volume determined for the surface location for the one or more simulated injections of the plurality of simulated injections, the leakage severity value indicating a simulated average amount of leakage volume at the surface location. In some examples, the method includes determining, for the one or more surface locations, a leakage risk based on one or more of the leakage probability value or the leakage severity value calculated for the surface location.

Certain aspects provide a method for performing probabilistic risk assessments for a geological storage complex. The method may include performing a plurality of simulations using a geomechanical model and a fluid flow property model of a geological storage complex, wherein model parameters are varied for one or more simulation of the plurality of simulations. In some examples, the method includes calculating a plurality of occurrence probabilities and a plurality of severity levels for one or more defined risk events based on the plurality of simulations. In some examples, the method includes determining, for the one or more defined risk events, a risk value based on the plurality of occurrence probabilities and the plurality of severity levels for the defined risk event.

Certain aspects provide a method for predicting fluid flow parameters. The method may include providing a first set of reservoir parameters to a reservoir flow simulator to generate one or more fluid flow parameters. In some examples, the method includes providing the one or more fluid flow parameters to a machine learning model, trained on data from a geomechanical simulator, to generate one or more predicted geomechanical parameters. In some examples, the method includes providing at least a subset of the one or more predicted geomechanical parameters to the reservoir flow simulator to generate one or more second fluid flow parameters.

Certain aspects provide a method for predicting flow effects or geomechanical effects for a subsurface reservoir. The method may include training a machine learning model on output from a first simulator, wherein one of the first simulator or a second simulator comprises a reservoir flow simulator and the other of the first simulator or the second simulator comprises a geomechanical simulator. In some examples, the method includes providing input parameters to the second simulator to generate a first output. In some examples, the method includes providing the first output to the machine learning model to predict a second output, wherein one of the first output or the second output are indicative of flow effects for a subsurface reservoir and the other of the first output or the second output are indicative of geomechanical effects for the subsurface reservoir.

Certain aspects provide a method of quantitative risk assessment of a CO₂ storage complex. The method may include generating a three-dimensional (3D) computational model representing geological properties of the CO2 storage complex. The method may also include obtaining an ensemble of results from the 3D computational model indicating an event occurrence based on iteratively adjusting at least one parameter of the 3D computational model, each adjustment of the at least one parameter reflecting an hypothesis of the state of the geological properties of the CO2 storage complex. The method may furthermore include calculating an event occurrence probability based on the ensemble of results. The method may in addition include determining a severity value based on the ensemble of results, the severity value representing consequences of the event occurrence. The method may moreover include generating a risk scoring calculated from the event occurrence probability multiplied by the severity value. The method may also include transmitting the risk scoring as the risk assessment to a risk management system.

Other aspects provide processing systems configured to perform the aforementioned methods as well as those described herein; non-transitory, computer-readable media comprising instructions that, when executed by a processors of a processing system, cause the processing system to perform the aforementioned methods as well as those described herein; a computer program product embodied on a computer readable storage medium comprising code for performing the aforementioned methods as well as those further described herein; and a processing system comprising means for performing the aforementioned methods as well as those further described herein.

The following description and the related drawings set forth in detail certain illustrative features of one or more aspects.

### DESCRIPTION OF THE DRAWINGS

The appended figures depict certain aspects and are therefore not to be considered limiting of the scope of this disclosure.

FIG. 1 depicts an example of a system that includes various management components to manage various aspects of a geologic environment, according to an embodiment.

FIG. 2 depicts details of a workflow for quantifying an overall leakage risk of a fluid from a geological storage complex in accordance with examples of the present disclosure.

FIG. 3 depicts example implementations of one or more machine learning models according to an embodiment.

FIGS. 4A-4C depict example implementations of one or more machine learning models according to an embodiment.

FIG. 5 depicts aspects of a risk management plan in accordance with examples of the present disclosure.

FIG. 6 depicts a conceptual model of an example CO₂ storage complex in accordance with examples of the present disclosure.

FIG. 7 depicts a graphical representation of a numerical model of an example CO₂ injection in accordance with examples of the present disclosure.

FIG. 8A and FIG. 8B depict top and sectional views of mechanical initial and boundary conditions of an example CO₂ storage complex in accordance with examples of the present disclosure.

FIG. 9 depicts hydraulic (flow) initial and boundary conditions of an example CO₂ storage complex in accordance with examples of the present disclosure.

FIG. 10 depicts coupled processes in accordance with examples of the present disclosure.

FIG. 11A depicts drainage and imbibition relative permeabilities in accordance with examples of the present disclosure

FIG. 11B depicts CO₂ solubility curves in accordance with examples of the present disclosure.

FIG. 12A, FIG. 12B, FIG. 12C and FIG. 12D depict fault modeling of an example CO₂ storage complex in accordance with examples of the present disclosure.

FIG. 13 depicts a fault permeability updating function in accordance with examples of the present disclosure.

FIG. 14A, FIG. 14B, FIG. 14C, FIG. 14D, FIG. 14E and FIG. 14F depict a side sectional view of an uncoupled base-case scenario CO₂ saturation plume and pressure plume of an example CO₂ storage complex in accordance with examples of the present disclosure.

FIG. 15A and FIG. 15B depict a top view of an uncoupled base-case scenario CO₂ saturation plume of an example CO₂ storage complex in accordance with examples of the present disclosure.

FIG. 16A, FIG. 16B and FIG. 16C depict a side sectional view of an example CO₂ storage complex showing stress distribution in accordance with examples of the present disclosure.

FIG. 17 depicts a representation of fault yield surface values F of Eq. 5 in accordance with examples of the present disclosure.

FIG. 18A, FIG. 18B, FIG. 18C, FIG. 18D, FIG. 18E and FIG. 18F depict a side sectional view of an coupled base-case scenario CO₂ saturation plume and pressure plume of an example CO₂ storage complex in accordance with examples of the present disclosure.

FIG. 19A, FIG. 19B, FIG. 19C, FIG. 19D, FIG. 19E and FIG. 19F depict a side sectional view of permeability, pressure and saturation results from an uncoupled base-case scenario and a coupled base-case-scenario of an example CO₂ storage complex in accordance with examples of the present disclosure.

FIG. 20 depicts a representation of an evolution of three components of the permeability tensor in f Eq. 9 in accordance with examples of the present disclosure.

FIG. 21A depicts a side sectional view of CO₂ penetration within a top seal of an example CO₂ storage complex after 40 years from injection halt in accordance with examples of the present disclosure.

FIG. 21B depicts an average field pressure decline in the uncoupled and coupled scenarios shown in FIG. 19A in accordance with examples of the present disclosure.

FIGS. 22A and 22B depict summary realizations in terms of CO₂ saturation plume distribution after 50 years using sample values set by bucket brigade delay sampling for the ensemble data of Table 4 in accordance with examples of the present disclosure.

FIG. 23A and FIG. 23B depict probability of leakage at the end of injection of an example CO₂ storage complex in accordance with examples of the present disclosure.

FIG. 24A and FIG. 24B depict leakage zones severity modeling at the end of injection of an example CO₂ storage complex in accordance with examples of the present disclosure.

FIG. 25 depicts leakage mass severity modeling of an example CO₂ storage complex in accordance with examples of the present disclosure.

FIG. 26 depicts distribution of overall leakage severity classes of an example CO₂ storage complex in accordance with examples of the present disclosure.

FIG. 27 depicts an example risk of leakage scoring matrix in accordance with examples of the present disclosure.

FIG. 28 depicts a leakage risk score at the end of injection of an example CO₂ storage complex in accordance with examples of the present disclosure.

FIG. 29 depicts a leakage risk score at site closure of an example CO₂ storage complex in accordance with examples of the present disclosure.

FIG. 30 depicts an example method of for quantifying leakage risk in a geological storage complex in accordance with examples of the present disclosure.

FIG. 31 depicts an example method for performing probabilistic risk assessments for a geological storage complex in accordance with examples of the present disclosure.

FIG. 32 depicts an example method for predicting fluid flow parameters in accordance with examples of the present disclosure.

FIG. 33 depicts an example method for predicting flow effects and geomechanical effects for a subsurface reservoir in accordance with examples of the present disclosure.

FIG. 34 depicts an example method for quantitative risk assessment of a CO₂ storage complex in accordance with examples of the present disclosure.

FIG. 35 depicts an example processing system on which aspects of the present disclosure can be performed.

To facilitate understanding, identical reference numerals have been used, where possible, to designate identical elements that are common to the drawings. It is contemplated that elements and features of one embodiment may be beneficially incorporated in other embodiments without further recitation.

### DETAILED DESCRIPTION

Aspects of the present disclosure provide apparatuses, methods, processing systems, and computer-readable mediums for subsurface geomechanics and flow modeling. For example, certain aspects provide techniques for quantifying risk in a geological storage complex. In certain aspects, a leakage risk of a fluid, such as CO₂ is quantified. Certain aspects provide techniques for training and/or utilizing one or more machine-learning models to perform geomechanics and flow modeling, such as part of performing leakage risk calculation, or for other uses.

Projects that capture and store CO₂ in underground reservoirs have gained traction as a practical way to reduce greenhouse gas emissions. However, these CCS endeavors have risks. One primary concern is the potential for CO₂ to escape from these underground storage sites through faults, fractures, poorly sealed wellbores, or other weak points. Such leakage could jeopardize underground resources, lead to atmospheric emissions, and ultimately result in project failure.

Existing methods for assessing risks in CCS endeavors vary widely and do not thoroughly capture the intricacies of the storage complex and associated leakage pathways. Additionally, existing approaches often fail to quantify event probabilities and severities based on model outcomes, thus lacking a comprehensive risk assessment.

Aspects of the present disclosure describe computer-based methods for predicting and quantifying risks, such as leakage risks, in a geological storage complex, such as for a CCS project. Additionally, the present disclosure describes methods for quantification of fault reactivation, lateral plume migration, seabed/surface heave, and potentially induced seismicity risks. For example, the computer-based methods can quantify risks associated with the leakage of fluids, such as CO₂ or host reservoir water, from a geological storage complex (also referred to as a storage reservoir). In certain aspects, the computer-based methods integrate uncertainty, flow, and geomechanical modeling on a geological model representing a geological storage complex to quantify one or more of the probability of occurrence and severity of potential events, such as leakage events. For example, a probability may indicate the likelihood that a stored fluid, such as CO₂ or host reservoir water, will breach containment and leak out of the geological storage complex. In an example, severity may represent the expected or predicted magnitude of a leakage event, such as in terms of volume or rate. In certain cases, overall leakage risk may be based on one or more of a probability or severity of an event. In an example, overall risk of an event (e.g., leakage of a fluid) may be calculated as a function (e.g., weighted average) of a probability of the event occurring and a predicted severity of the event should the event occur. Certain examples may be described herein with respect to quantifying leakage risk of a fluid in a geological storage complex. However, it should be noted that certain techniques discussed herein may also be applied to quantifying other risks in a geological storage complex. Further, certain examples may be described herein with respect to CO₂ as a fluid stored in a geological storage complex. However, it should be noted that certain techniques discussed herein may also be applied to other types of fluid stored in a geological storage complex.

Predicting and quantifying risks for a geological event may utilize geomechanical and fluid flow simulations and/or one or more machine learning models trained to predict fluid flow and/or geomechanical parameters of a geological storage complex. Such complex simulation or machine learning models are not capable of being performed in the human mind, due to the complexity of calculations, and therefore are necessarily computer-based solutions. Further, the techniques discussed herein for quantifying risk solve the technical problem of how to technically assess whether there is risk from a fluid stored in a geological complex, through a technical solution involving simulator(s) and/or machine learning model(s). They improve the technical field of subsurface fluid storage by assessing risk before risk events occur. Further, the techniques combine the use of multiple modeling techniques, such as different simulators, different machine learning models, and/or simulators and machine learning models to generate more accurate predictions, while in some cases, reducing computation complexity.

In some cases, performing risk quantification involves coupling flow simulations, which model the behavior of fluids in porous media, with geomechanical simulations, which assess changes in the subsurface stress and structure due to fluid injection operations. While these coupled simulations provide precise, physics-based predictions, they may also be computationally intensive.

Aspects of the present disclosure are directed to one or more machine learning models that simulate the behavior of physics-based numerical simulator(s) for flow and/or geomechanical processes. Numerical simulators based on computational methods may be used to model physical subsurface processes like multiphase fluid flow and geomechanical deformations. In certain aspects, a machine learning model may be used in place of one or more such numerical simulators to model one or more physical subsurface processes, such as for a portion of a risk quantification process. Use of a machine learning model, instead of a numerical simulator, may reduce computational complexity, thus improving the performance of the computing device on which the flow and/or geomechanical processes are performed. In particular, the machine learning models may provide outputs more efficiently and faster, thereby enabling the computing device to be used for other tasks, perform more simulations, etc.

In an example, a first machine learning model is trained to predict one or more fluid flow parameters (also referred to as fluid flow properties, or flow effects), such as pressure, saturation, phase velocity, composition, and/or the like, such as arising from a given set of reservoir conditions (also referred to as reservoir parameters, or subsurface parameters, or geological storage complex parameters) such as reservoir properties, fluid properties, operational constraints, facility constraints, well properties, initial conditions, aquifer parameters, and/or numeric controls, for a geological storage complex, such as a storage reservoir. It should be noted that the term “set” as used herein may refer to a set with “one or more” items. In an example, a second machine learning model is trained to predict, such as for a geological storage complex, one or more geomechanical parameters (also referred to as geomechanical properties, or geomechanical effects), such as mechanical deformation, stress, strain, propensity for fracture and/or fault, and/or the like, such as arising from a given set reservoir conditions, such as pressure, saturation, temperature change, and/or the like in the geological storage complex. In an example, the first and/or second machine learning model can utilize one or more neural networks, or other machine learning models, that enable capturing complex relationships between input subsurface parameters and simulated output responses. Such output responses can be made using less computations and less computing time and are performed faster than conventional numerical flow simulators and numerical geomechanical simulators. In such an approach, geomechanical effects arising from subsurface fluid flow can be quickly predicted, such as to enable quantification of fault reactivation risk, fracture growth risk, and/or other leakage pathways that could allow carbon dioxide to escape a storage zone. In some cases, the coupled simulators and machine learning models can determine risks that may lead to carbon dioxide leakage for a given subsurface formation and injection plan.

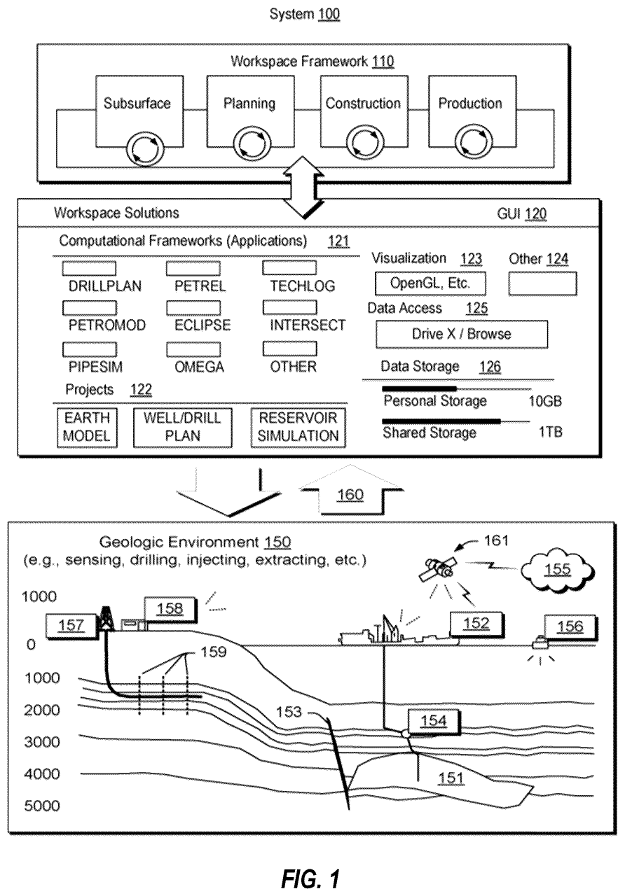

FIG. 1 shows an example of a system 100 that includes a workspace framework 110 that can provide for instantiation of, rendering of, interactions with, etc., a graphical user interface (GUI) 120. In the example of FIG. 1, the GUI 120 can include graphical controls for computational frameworks (e.g., applications) 121, projects 122, visualization 123, one or more other features 124, data access 125, and data storage 126.

In the example of FIG. 1, the workspace framework 110 may be tailored to a particular geologic environment, such as an example geologic environment 150. For example, the geologic environment 150 may include layers (e.g., stratification) that include a reservoir 151 (an example of, or part of, a geological storage complex) and that may be intersected by a fault 153. As an example, the geologic environment 150 may be outfitted with a variety of sensors, detectors, actuators, etc. For example, equipment 152 may include communication circuitry to receive and transmit information to one or more networks 155. Such information may include information associated with downhole equipment 154, which may be equipment to acquire information, assist with resource recovery, etc. Other equipment 156 may be located remote from a wellsite, including sensing, detecting, emitting, or other circuitry. Such equipment may include storage and communication circuitry to store and communicate data, instructions, etc. As an example, one or more satellites 161 may be provided for purposes of communications, data acquisition, etc. For example, FIG. 1 shows satellite 161 in communication with network 155 that may be configured for communications, noting that satellite 161 may additionally or alternatively include circuitry for imagery (e.g., spatial, spectral, temporal, radiometric, etc.).

FIG. 1 also shows the geologic environment 150 as optionally including equipment 157 and 158 associated with a well that includes a substantially horizontal portion that may intersect with one or more fractures 159. For example, consider a well in a shale formation that may include natural fractures, artificial fractures (e.g., hydraulic fractures) or a combination of natural and artificial fractures. For example, a well may be drilled for a laterally extensive reservoir. In such an example, lateral variations in properties, stresses, etc. may exist where an assessment of such variations may assist with planning, operations, etc., to develop a laterally extensive reservoir (e.g., via fracturing, injecting, extracting, etc.). As an example, equipment 157 and/or 158 may include components, a system, systems, etc., for fracturing, seismic sensing, analysis of seismic data, assessment of one or more fractures, etc.

As an example, a system may include a computational environment that can include various features of the DELFI environment (SLB, Houston, Texas), which may be referred to as the DELFI framework, which may be a framework of frameworks. As an example, the DELFI framework can include various other frameworks, which can include, for example, one or more types of models (e.g., simulation models, etc.). Some examples of frameworks can include the DRILLPLAN, PETREL, TECHLOG, PIPESIM, ECLIPSE, INTERSECT, VISAGE, MANGROVE, OMEGA and PETROMOD frameworks (SLB, Houston, Texas).

As an example, a system may include features of a simulation framework that provides components that allow for optimization of exploration and development operations (e.g., “E&P” operations). A framework may include seismic to simulation software components that can output information to increase reservoir performance, for example, by improving asset team productivity. Using such a framework, various professionals (e.g., geophysicists, geologists, and reservoir engineers) can develop collaborative workflows and integrate operations to streamline processes. Such a framework may be considered an application and may be considered a data-driven application (e.g., where data is input for purposes of simulating a geologic environment, decision making, operational control, etc.).

As an example, a system may include add-ons or plug-ins that operate according to specifications of a framework environment. As an example, various components may be implemented as add-ons (or plug-ins) that conform to and operate according to specifications of a framework environment (e.g., according to application programming interface (API) specifications, etc.).

The aforementioned DELFI environment is a secure, cognitive, cloud-based collaborative environment that integrates data and workflows with digital technologies, such as artificial intelligence and machine learning. For example, such an environment can provide for operations involving one or more computational frameworks. For example, various types of computational frameworks may be utilized within an environment, such as a drilling plan framework, a seismic-to-simulation framework, a measurements framework, a mechanical earth modeling (MEM) framework, an exploration risk, resource, and value assessment framework, a reservoir simulation framework, a surface facilities framework, a stimulation framework, etc. For example, one or more methods may be implemented at least in part via a framework (e.g., a computational framework) and/or an environment (e.g., a computational environment).

In the example of FIG. 1, the GUI 120 shows examples of computational frameworks, including the DRILLPLAN, PETREL, TECHLOG, PETROMOD, ECLIPSE, INTERSECT, PIPESIM and OMEGA frameworks that may be part of a DELFI environment.

The DRILLPLAN framework provides for digital well construction planning and includes features for the automation of repetitive tasks and validation workflows, enabling improved quality drilling programs (e.g., digital drilling plans, etc.) to be produced quickly with assured coherency.

The PETREL framework can provide for implementing various tasks in geosciences and geoengineering, for example, to analyze subsurface data from exploration to production of fluid from a reservoir.

The TECH LOG framework can handle and process field and laboratory data for a variety of geologic environments (e.g., deepwater exploration, shale, etc.). The TECHLOG framework can structure wellbore data for analyses, planning, etc.

The PETROMOD framework provides petroleum systems modeling capabilities that can combine one or more of seismic, well, and geological information to model the evolution of a sedimentary basin. The PETROMOD framework can predict if and how, a reservoir has been charged with hydrocarbons, including the source and timing of hydrocarbon generation, migration routes, quantities, and hydrocarbon type in the subsurface or at surface conditions.

The ECLIPSE framework provides a reservoir simulator (e.g., as a computational framework) with numerical solutions for fast and accurate dynamic behavior prediction for various reservoirs and development schemes.

The INTERSECT framework provides a high-resolution reservoir simulator for the simulation of detailed geological features and quantification of uncertainties; for example, by creating accurate production scenarios and, with the integration of precise models of the surface facilities and field operations, the INTERSECT framework can produce reliable results, which may be continuously updated by real-time data exchanges (e.g., from one or more types of data acquisition equipment in the field that can acquire data during one or more types of field operations, etc.). The INTERSECT framework can provide completion configurations for complex wells where such configurations can be built in the field, can provide detailed enhanced-oil-recovery (EOR) formulations where such formulations can be implemented in the field, can analyze application of steam injection and other thermal EOR techniques for implementation in the field, advanced production controls in terms of reservoir coupling and flexible field management, and flexibility to script customized solutions for improved modeling and field management control. The INTERSECT framework, as with the other example frameworks, may be utilized as part of the DELFI cognitive E&P environment, for example, for rapid simulation of multiple concurrent cases. For example, a workflow may utilize one or more of the DELFI on demand reservoir simulation features.

The PIPESIM simulator includes solvers that may provide simulation results such as, for example, multiphase flow results (e.g., from a reservoir to a wellhead and beyond, etc.), flowline and surface facility performance, etc. The PIPESIM simulator may be integrated, for example, with the AVOCET production operations framework (SLB, Houston Texas). As an example, a reservoir or reservoirs may be simulated with respect to one or more enhanced recovery techniques (e.g., consider a thermal process such as steam-assisted gravity drainage (SAGD), etc.). As an example, the PIPESIM simulator may be an optimizer that can optimize one or more operational scenarios at least in part via simulation of physical phenomena.

The OMEGA framework includes finite difference modelling (FDMOD) features for two-way wavefield extrapolation modelling, generating synthetic shot gathers with and without multiples. The FDMOD features can generate synthetic shot gathers by using full 3D, two-way wavefield extrapolation modelling, which can utilize wavefield extrapolation logic matches that are used by reverse-time migration (RTM). A model may be specified on a dense 3D grid as velocity and optionally as anisotropy, dip, and variable density. The OMEGA framework also includes features for RTM, FDMOD, adaptive beam migration (ABM), Gaussian packet migration (Gaussian PM), depth processing (e.g., Kirchhoff prestack depth migration (KPSDM), tomography (Tomo)), time processing (e.g., Kirchhoff prestack time migration (KPSTM), general surface multiple prediction (GSMP), extended interbed multiple prediction (XI MP)), framework foundation features, desktop features (e.g., GUIs, etc.), and development tools. Various features can be included for processing various types of data such as, for example, one or more of: land, marine, and transition zone data; time and depth data; 2D, 3D, and 4D surveys; isotropic and anisotropic (TTI and VTI) velocity fields; and multicomponent data.

The aforementioned DELFI environment provides various features for workflows as to subsurface analysis, planning, construction and production, for example, as illustrated in the workspace framework 110. As shown in FIG. 1, outputs from the workspace framework 110 can be utilized for directing, controlling, etc., one or more processes in the geologic environment 150 and, feedback 160, can be received via one or more interfaces in one or more forms (e.g., acquired data as to operational conditions, equipment conditions, environment conditions, etc.).

In the example of FIG. 1, the visualization features 123 may be implemented via the workspace framework 110, for example, to perform tasks as associated with one or more of subsurface regions, planning operations, constructing wells and/or surface fluid networks, and producing from a reservoir.

As an example, a visualization process can implement one or more of various features that can be suitable for one or more web applications. For example, a template may involve use of the JAVASCRIPT object notation format (JSON) and/or one or more other languages/formats. As an example, a framework may include one or more converters. For example, consider a JSON to PYTHON converter and/or a PYTHON to JSON converter. Such a converter may provide for interoperability, integration of code from one or more sources, etc.

As an example, visualization features can provide for visualization of various earth models, properties, etc., in one or more dimensions. As an example, visualization features can provide for rendering of information in multiple dimensions, which may optionally include multiple resolution rendering. In such an example, information being rendered may be associated with one or more frameworks and/or one or more data stores. As an example, visualization features may include one or more control features for control of equipment, which can include, for example, field equipment that can perform one or more field operations. As an example, a workflow may utilize one or more frameworks to generate information that can be utilized to control one or more types of field equipment (e.g., drilling equipment, wireline equipment, fracturing equipment, etc.). As an example, a visualization framework such as the OpenGL framework (Khronos Group, Beaverton, Oregon) may be utilized for visualizations. The OpenGL framework provides a cross-language, cross-platform application programming interface for rendering 2D and 3D vector graphics where the API may be used to interact with a graphics processing unit (or units), to achieve hardware-accelerated rendering.

As to a reservoir model (an example of a geological storage complex model) that may be suitable for utilization by a simulator, consider the acquisition of seismic data as acquired via reflection seismology, which finds use in geophysics, for example, to estimate properties of subsurface formations. For example, reflection seismology may provide seismic data representing waves of elastic energy (e.g., as transmitted by P-waves and S-waves, in a frequency range of approximately 1 Hz to approximately 100 Hz). Seismic data may be processed and interpreted, for example, to understand better the composition, fluid content, extent, and geometry of subsurface rocks. Such interpretation results can be utilized to plan, simulate, perform, etc., one or more operations for production of fluid from a reservoir (e.g., reservoir rock, etc.).

Field acquisition equipment may be utilized to acquire seismic data, which may be in the form of traces where a trace can include values organized with respect to time and/or depth (e.g., consider 1 D, 2D, 3D or 4D seismic data). For example, consider acquisition equipment that acquires digital samples at a rate of one sample per approximately 4 ms. Given a speed of sound in a medium or media, a sample rate may be converted to an approximate distance. For example, the speed of sound in rock may be on the order of around 5 km per second. Thus, a sample time spacing of approximately 4 ms would correspond to a sample “depth” spacing of about 10 meters (e.g., assuming a path length from source to boundary and boundary to sensor). As an example, a trace may be about 4 seconds in duration; thus, for a sampling rate of one sample at about 4 ms intervals, such a trace would include about 1000 samples where latter acquired samples correspond to deeper reflection boundaries. If the 4 second trace duration of the foregoing example is divided by two (e.g., to account for reflection), for a vertically aligned source and sensor, a deepest boundary depth may be estimated to be about 10 km (e.g., assuming a speed of sound of about 5 km per second).

As an example, a model may be a simulated version of a geologic environment. As an example, a simulator may include features for simulating physical phenomena in a geologic environment based at least in part on a model or models. A simulator, such as a reservoir simulator, can simulate fluid flow in a geologic environment based at least in part on a model that can be generated via a framework that receives seismic data. A simulator can be a computerized system (e.g., a computing system) that can execute instructions using one or more processors to solve a system of equations that describe physical phenomena subject to various constraints. In such an example, the system of equations may be spatially defined (e.g., numerically discretized) according to a spatial model that that includes layers of rock, geobodies, etc., that have corresponding positions that can be based on interpretation of seismic and/or other data. A spatial model may be a cell-based model where cells are defined by a grid (e.g., a mesh). A cell in a cell-based model can represent a physical area or volume in a geologic environment where the cell can be assigned physical properties (e.g., permeability, fluid properties, etc.) that may be germane to one or more physical phenomena (e.g., fluid volume, fluid flow, pressure, etc.). A reservoir simulation model can be a spatial model that may be cell-based.

A simulator can be utilized to simulate the exploitation of a real reservoir, for example, to examine different production scenarios to find an optimal one before production or further production occurs. A reservoir simulator does not provide an exact replica of flow in and production from a reservoir at least in part because the description of the reservoir and the boundary conditions for the equations for flow in a porous rock are generally known with an amount of uncertainty. Certain types of physical phenomena occur at a spatial scale that can be relatively small compared to size of a field. A balance can be struck between model scale and computational resources that results in model cell sizes being of the order of meters rather than a lesser size (e.g., a level of detail of pores). A modeling and simulation workflow for multiphase flow in porous media (e.g., reservoir rock, etc.) can include generalizing real micro-scale data from macro scale observations (e.g., seismic data and well data) and upscaling to a manageable scale and problem size. Uncertainties can exist in input data and solution procedures such that simulation results, too, are, to some extent, uncertain. A process known as history matching can involve comparing simulation results to actual field data acquired during the production of fluid from a field. Information gleaned from history matching can provide for adjustments to a model, data, etc., which can help to increase the accuracy of the simulation.

As an example, a simulator may utilize various types of constructs, which may be referred to as entities. Entities may include earth entities or geological objects such as wells, surfaces, reservoirs, etc. Entities can include virtual representations of actual physical entities that may be reconstructed for purposes of simulation. Entities may include entities based on data acquired via sensing, observation, etc. (e.g., consider entities based at least in part on seismic data and/or other information). As an example, an entity may be characterized by one or more properties (e.g., a geometrical pillar grid entity of an earth model may be characterized by a porosity property, etc.). Such properties may represent one or more measurements (e.g., acquired data), calculations, etc.

As an example, a simulator may utilize an object-based software framework, which may include entities based on pre-defined classes to facilitate modeling and simulation. As an example, an object class can encapsulate reusable code and associated data structures. Object classes can be used to instantiate object instances for use by a program, script, etc. For example, borehole classes may define objects for representing boreholes based on well data. A model of a basin, a reservoir, etc. may include one or more boreholes where a borehole may be, for example, for measurements, injection, production, etc. As an example, a borehole may be a wellbore of a well, which may be a completed well (e.g., for production of a resource from a reservoir, for injection of material, etc.).

While several simulators are illustrated in the example of FIG. 1, one or more other simulators may be utilized, additionally or alternatively. For example, consider the VISAGE geomechanics simulator, etc. The VISAGE simulator includes finite element numerical solvers that may provide simulation results such as for example, results as to compaction and subsidence of a geologic environment, well and completion integrity in a geologic environment, cap-rock and fault-seal integrity in a geologic environment, fracture behavior in a geologic environment, thermal recovery in a geologic environment, CO₂ disposal, etc. The MANGROVE simulator provides for the optimization of stimulation design (e.g., stimulation treatment operations such as hydraulic fracturing) in a reservoir-centric environment. The MANGROVE framework can combine scientific and experimental work to predict geomechanical propagation of hydraulic fractures, reactivation of natural fractures, etc., along with production forecasts within 3D reservoir models (e.g., production from a drainage area of a reservoir where fluid moves via one or more types of fractures to a well and/or from a well). The MANGROVE framework can provide results pertaining to heterogeneous interactions between hydraulic and natural fracture networks, which may assist with optimization of the number and location of fracture treatment stages (e.g., stimulation treatment(s)), for example, to increased perforation efficiency and recovery.

The PETREL framework provides components that allow for optimization of exploration and development operations. The PETREL framework includes seismic to simulation software components that can output information for use in increasing reservoir performance, for example, by improving asset team productivity. Through use of such a framework, various professionals (e.g., geophysicists, geologists, and reservoir engineers) can develop collaborative workflows and integrate operations to streamline processes (e.g., with respect to one or more geologic environments, etc.). Such a framework may be considered an application (e.g., executable using one or more devices) and may be considered a data-driven application (e.g., where data is input for purposes of modeling, simulating, etc.).

As mentioned, a framework may be implemented within or in a manner operatively coupled to the DELFI environment. As an example, the DELFI framework can include various other frameworks, which can include, for example, one or more types of models (e.g., simulation models, machine learning models, etc.).

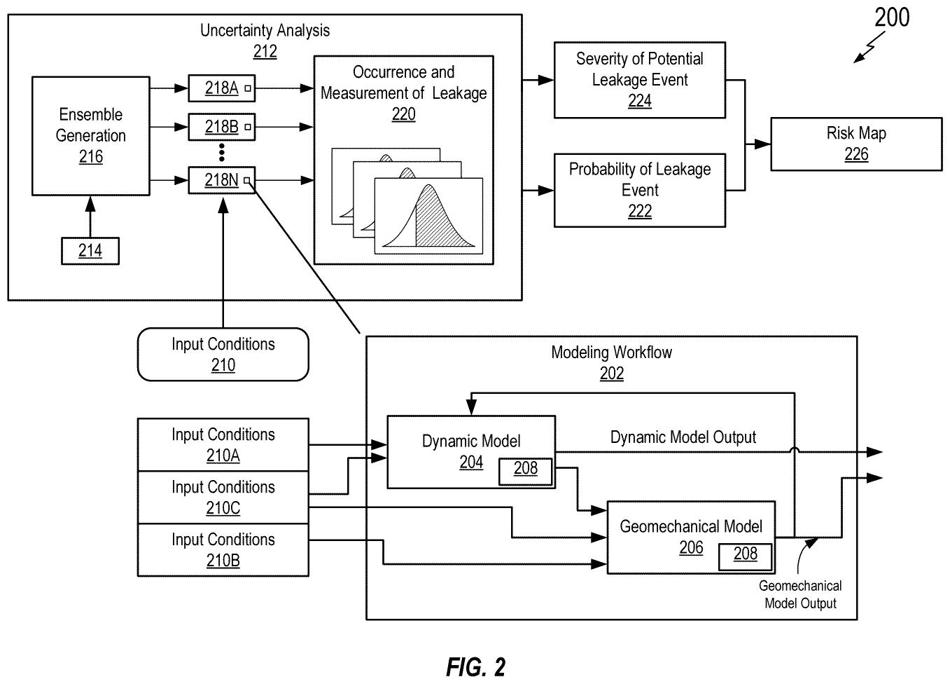

FIG. 2 illustrates an example workflow 200 for quantifying an overall leakage risk of a fluid from a geological storage complex. As depicted in FIG. 2, workflow 200 utilizes a modeling workflow 202 including a dynamic model 204, geomechanical model 206, and a static model 208 representing a geological storage complex. In some aspects, a static model 208 refers to a type of geological model that represents subsurface geologic structures and rock properties but may not simulate dynamic processes over time. In some aspects, static models may include one or more three-dimensional (3D) models constructed to capture the spatial distribution and properties of rock layers, faults, fractures, etc., based on available geologic and geophysical data. A static model may delineate key static features like reservoir boundaries, caprock extents, and structural features; however, a static model generally does not model fluid flow or geomechanical changes over time. In some aspects, a static model may incorporate petrophysical properties like porosity, permeability, and mineralogy throughout the 3D volume. These properties may be assumed to remain static or constant over time. In examples, static models provide the geological framework and rock property distribution on which dynamic simulations like flow modeling and geomechanical modeling are built.

The workflow 200 may incorporate a dynamic model 204. In some aspects, a dynamic model 204 may refer to a simulation model that includes time-dependent changes in a system. In subsurface modeling, a dynamic model may simulate processes like fluid flow, heat transfer, and geomechanical changes over time. In some aspects, dynamic modes may capture the evolution of a system, for example, pressure transients during hydrocarbon production or CO₂ injection. In some aspects, dynamic models may incorporate time-dependent inputs like injection/production rates and account for accumulated effects over time. Example inputs 210A to the dynamic model 204 include but are not limited to reservoir properties, fluid properties, operational constraints, facility constraints, well properties, initial conditions, aquifer parameters, and/or numeric controls. Example outputs of the dynamic model 204 may include pressure and/or saturation changes over time, cumulative production/injection, sweep efficiency, and/or the like. In carbon capture and storage projects, a dynamic model may be used for simulating CO₂ injection, plume migration, pressure buildup, and/or associated leakage risks over time, for example and may capture time-dependent effects that static geological models generally do not capture. In examples, geomechanical model 206 can also be referred to as a numerical dynamic model, flow simulator, or reservoir flow simulator.

The workflow 200 may incorporate a geomechanical model 206 based on the static model 208. In some aspects, a geomechanical model 206 may refer to a simulation model that analyzes the mechanical stresses, strains, and/or deformations in subsurface rocks under various loading conditions. In some aspects, a geomechanical model may simulates how rocks mechanically respond to changes in stress, pressure, and/or loading over time. Inputs 210B to the geomechanical model may include, but are not limited to, detailed rock mechanical properties such as Young's modulus, Poisson's ratio, and/or compressive/tensile strengths. In some aspects, a geomechanical model predict stress distribution, fracture propagation, subsidence, sand production, and/or other geomechanical effects. A geomechanical model may employ analysis techniques that may include, but are not limited to, analytical methods, finite element, finite difference, and discrete element methods. In some aspects, geomechanical models are often coupled with dynamic models, such as reservoir flow models, to capture stress-dependent permeability changes and vice versa. In carbon capture and storage applications, geomechanical models may help evaluate fault activation, fracture opening, caprock integrity, and containment under CO₂ injection conditions. By simulating mechanical deformation and failure, a geomechanical model can be fundamental for assessing leakage risks. In examples, a geomechanical model 206 can also be referred to as a numerical geomechanical model or a geomechanical simulator.

In some aspects, the dynamic model 204 and the geomechanical model 206 may be coupled together in the modeling workflow 202 to account for interactions between fluid flow, pressure changes, and geomechanical deformation during CO₂ injection. In some aspects, input conditions 210C, may include but are not limited to stresses, pressures, temperatures, and/or fluid compositions before injection, provide common input data for both geomechanical and dynamic simulators. The coupling enables the geomechanical effects of pressure and temperature changes and geochemical effects, like CO₂-rock interactions, to be reflected in the dynamic flow modeling of the dynamic model 204. Likewise, the geomechanical model 206 incorporates changes in pressure and/or saturation from the dynamic model 204. This two-way coupling ensures that the fluid flow simulations adequately capture the rock deformations, fault slippage, and/or fracture opening/closing predicted by the geomechanical model 206.

In the example workflow 200, an uncertainty analysis 212 may be performed. In some aspects, an uncertainty analysis 212 may refer to one or more simulations run across a range of values for key parameters 214 to account for inherent uncertainties in subsurface properties and behaviors. Since subsurface data may be limited, properties like permeability, porosity, and geomechanical strengths exhibit uncertainty. To account for this uncertainty, an ensemble generator 216 of the uncertainty analysis 212 may generate an ensemble 218 of models 218A-218N by varying uncertain parameters (e.g., key parameters 214) within expected ranges. In some aspects, each model 218A-218N realization represents a different plausible scenario based on the same or similar input conditions 210. In some aspects, simulating across the model ensemble 218 may provide a probabilistic assessment of potential outcomes and risks. For example, an uncertainty analysis can quantify the likelihood of containment failure or the probability distribution of fluid leakage rates. In some aspects, an uncertainty analysis may enhance reliability by capturing the range of possible behaviors rather than just a single base case model. In examples, each model (e.g., 218A) may be a simulated CO₂ injection. Sources of uncertainty (e.g., key parameters 214) may include, but are not limited to, reservoir properties, fault properties, injection parameters, etc. An ensemble 218 may include a plurality of models 218A-218N (e.g., 10, 100, 1000) to sample a range of uncertainties.

In some aspects, a surface may be defined within the model (e.g., 218A) for which a leakage risk may be calculated. In some aspects, the surface can be specified at a caprock interface or at another depth of interest based on containment objectives. For each realization in the ensemble 218 of modeled scenarios (e.g, 218A), the workflow 200 may track, as leakage measurement 220, whether leakage occurs across the defined surface; the workflow 200 may determine associated leakage rates and volumes at locations along the surface. Leakage may occur through activated faults, fractures, compromised caprock, or wellbores, depending on the given model run. Both localized leakage rates and total leakage volumes from the simulation results can be output. The surface may be defined to quantify leakage risk at the depths of greatest concern for containment, such as a potable aquifer zone or the ground surface.

In an example, to calculate leakage risk, the workflow 200 may determine the probability of a leakage event 222 occurring at locations across a defined surface. The probability of a leakage event 222 may be calculated as the fraction of model runs (e.g., 218A) that had non-zero leakage volume at each surface location. In certain cases, workflow 200 may determine the severity of potential leakage events 224, such as the average leaked volume across the ensemble 218 of model runs at each surface location. Finally, the overall quantified leakage risk value at each surface location may be calculated based on one or more of the probability and severity, for example, by multiplying the probability and severity values. The overall quantified leakage risk value at each surface location can be represented or otherwise displayed on a risk map 226.

However, performing the ensemble of coupled flow-geomechanical simulations, as discussed in FIG. 2, for meaningful risk assessment can be computationally expensive. While flow simulations may take up to several days for field-scale models, geomechanical simulations may take an order of magnitude longer.

Various approaches have been proposed to reduce the computational burden of coupled flow-geomechanical simulations. For example, integrated coupled simulators with advanced numerical techniques have been proposed to improve efficiency. However, these techniques face challenges in not offering enough flexibility in simulator coupling configurations.

Therefore, there remains a need for a more efficient and flexible approach to performing the coupled flow-geomechanical simulations required for quantifying risks in a geological storage complex. Aspects of the present disclosure address this need through the use of one or more machine-learning models tailored for improved computational performance.

In examples, one or more models of the modeling workflow 202 can be replaced with one or more machine learning models trained to emulate a flow simulator (e.g., dynamic model 204) and/or a geomechanical simulator (e.g., geomechanical model 206), respectively. In an example, a machine learning model may be a neural network. For example, the neural network may comprise encoder-decoder architectures such as autoencoders. A neural network emulating a flow simulator may be referred to as the flow model. A neural network emulating a geomechanical simulator is referred to as the geomechanical model.

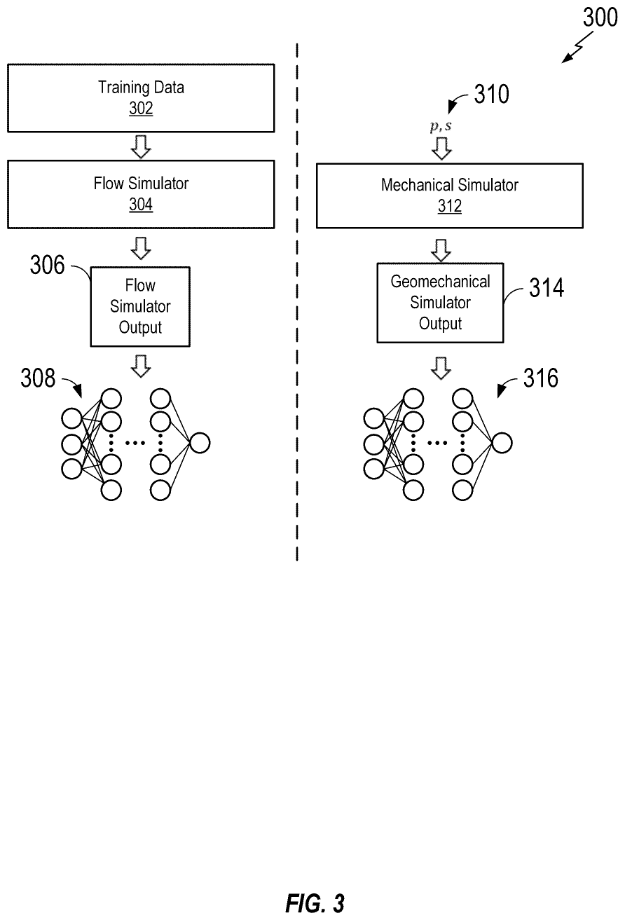

FIG. 3 depicts an example method 300 for training one or more machine-learning models in accordance with examples of the present disclosure. As depicted in FIG. 3, an ensemble of training data 302 may be generated by varying reservoir properties that affect fluid flow, such as porosity. This training data 302 may be input into a flow simulator 304, which computes and provides as simulator output 306, corresponding flow rates, pressures, and/or fluid saturations. The training data 302 and simulator output 306 may be used to train the flow machine learning model 308 to predict flow responses given a set of reservoir properties. In examples, the flow simulator 304 is the same as or similar to the dynamic model 204 (FIG. 2).

In some aspects, the geomechanical machine learning model 316 may be trained in a similar manner by generating an ensemble of training data 310 comprising properties that affect geomechanical deformation, such as pore pressure and/or saturation. This training data 310 may be input into a geomechanical simulator 312, which may compute, as output 314, stresses, strains, and/or changes in formation permeability. The training data 310 and geomechanical simulator 312 output 314 may be used to train the geomechanical machine learning model 316. In examples, the geomechanical simulator 312 is the same as or similar to the geomechanical model 206 (FIG. 2).

The inputs to generate the ensemble of training data 310 may be designed to simulate coupling with a flow simulator 304. For example, the pore pressure values may mimic pressure changes that would be computed by a flow simulator 304. Similarly, the inputs to generate the ensemble of training data 302 may be designed to simulate coupling with a geomechanical simulator 312, such as changes in porosity and permeability that would result from geomechanical effects. In this way, the machine learning models (e.g., 308 and 316) can learn not only the underlying physics but also the coupling between the physics.

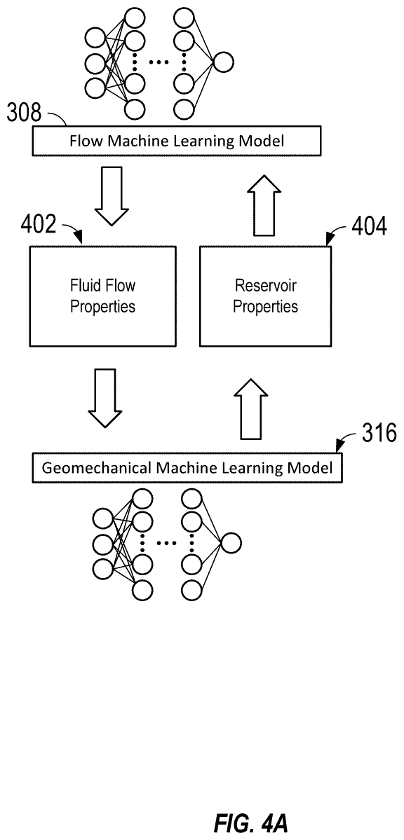

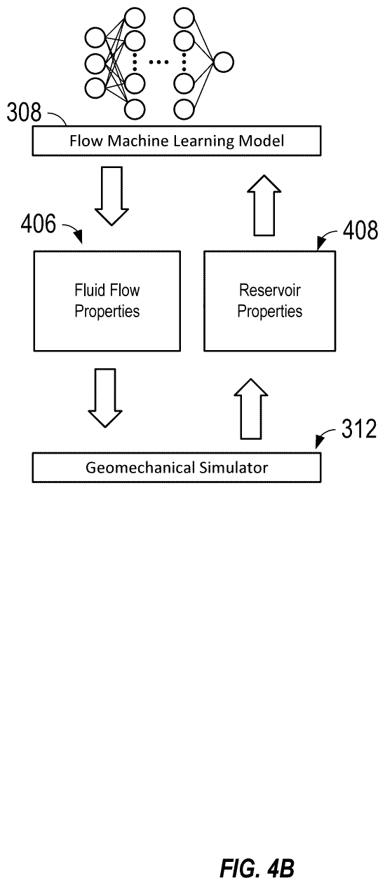

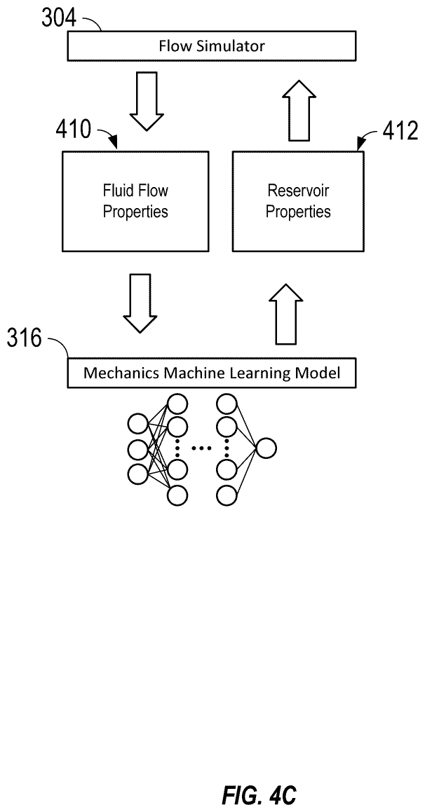

As depicted in FIG. 4A, after training, the flow machine learning model 308 and the geomechanical machine learning model 316 can be coupled together and used to emulate a coupled flow-geomechanical simulation. First, the flow machine learning model 308 may compute the fluid flow properties 402 resulting from a given set of reservoir properties. These fluid flow properties 402 may be passed to the geomechanical machine learning model 316, which may compute geomechanical deformation effects that would result, including any changes in reservoir properties 404. These changes in reservoir properties 404 can be fed back to the flow machine learning model 308, which may recompute the fluid flow properties 402 based on the updated reservoir properties 404. This process repeats for a desired number of coupling steps or until simulation end time.

As another example depicted in FIG. 4B, after training, the flow machine learning model 308 can be coupled to the geomechanical simulator 312. First, the flow machine learning model 308 computes the fluid flow properties 406 resulting from a given set of reservoir properties. These fluid flow properties 406 can be passed to the geomechanical simulator 312, which may compute the geomechanical deformation effects that would result, including any changes in reservoir properties 408. These changes in reservoir properties 408 may be fed back to the flow machine learning model 308, which recomputes the fluid flow properties 406 based on the updated reservoir properties 408. This process repeats for a desired number of coupling steps or until a simulation end time.

As another example depicted in FIG. 4C, after training, the geomechanical machine learning model 316 can be coupled to the flow simulator 304. First, the flow simulator 304 computes the fluid flow properties 410 resulting from a given set of reservoir properties. These fluid flow properties 410 can be passed to the geomechanical machine learning model 316, which compute the geomechanical deformation effects that would result, including any changes in reservoir properties 412. These changes in reservoir properties 412 may be fed back to the flow simulator 304, which recomputes the fluid flow properties 410 based on the updated reservoir properties 412. This process repeats for a desired number of coupling steps or until a simulation end time.

Although FIGS. 4A-4C depict the flow simulator 304 or the flow machine learning model 308 computing the fluid flow properties 410 resulting from a given set of reservoir properties before the geomechanical simulator 312 or geomechanical machine learning model 316 computing geomechanical deformation effects and changes to reservoir properties, it is understood that in some implementations, the geomechanical geotechnical simulator 312 or geomechanical machine learning model 316 may compute geomechanical deformation effects and changes in reservoir properties first, with the outputs of the geomechanical geotechnical simulator 312 or geomechanical machine learning model 316 (e.g., changes in reservoir properties) used as inputs to the flow simulator 304 or the flow machine learning model 308.

A reservoir simulation that incorporates a machine learning model may provide several benefits over traditional coupled reservoir simulation. First, because a machine learning model can emulate a complex physical simulator with high fidelity, the overall simulation can be orders of magnitude faster. This enables large ensembles of simulations to be run for meaningful risk analysis. Second, the system allows flexibility to couple simulation components in different configurations. For example, the flow machine learning model 308 could be coupled to the geomechanical simulator 312 for a hybrid approach. Third, certain aspects of the present disclosure may be applicable to various multiphysics problems beyond the specific application of CO₂ storage without deviating from the scope of the present disclosure.

In some aspects, the training data for the one or more machine learning models may be generated by running simulations on high-performance computing clusters. The trained model(s) can then be deployed on lower-cost hardware for routine simulation studies. In another aspect, the modeling workflow (e.g., modeling workflow 202) can incorporate additional one or more machine learning models trained to emulate other relevant coupled physics, such as thermal effects. The modular architecture enables additional machine learning models physics models to be readily integrated into existing modeling workflows.

### Quantitative Risk Assessment of CO₂ Leakage

Aspects of the present disclosure provide apparatuses, methods, processing systems, and computer-readable mediums that apply dynamic subsurface modeling to assess risks in a more precise, less subjective and quantitative manner, enabling a comprehensive and effective measurements, monitoring and verification (MMV) plans. By applying aspects of the present disclosure, MMV may evolve into modeling, measurements, monitoring and verification ((M)MMV). Aspects of the present disclosure may integrate flow and geomechanical-coupled behavior to assess caprock integrity and faults reactivation, and ultimately the risk of CO₂ leakage. Uncertainty analysis and a 4-dimensional (4D) probabilistic workflow may be employed to quantify the likelihood and consequences of CO₂ leakage and to score risks.

Aspects of the present disclosure provide a general framework to enable subsurface-modeling-based quantitative risk assessment (QRA) for use in a (M)MMV plan. Aspects of the present disclosure are described herein below with respect to the QRA of leakage risks through the fault and intact caprock for simplicity. However, other applications are contemplated as well, such as, but not limited to: 1) leakage risks through the caprock resulting from caprock failure, 2) lateral CO₂ migration leading to permit limits violation or inducing interferences with neighboring activities, and 3) leakage risks resulting from loss of well integrity. All these applications of aspects of the present disclosure can be used to formulate effective (M)MMV strategies for optimized and cost-effective risk mitigation.

Aspects of the present disclosure provide leakage QRA using a coupled numerical model. Certain aspects include estimating the probability of occurrence of leakages and their quantitative estimation of severity (potential consequences) if the leakages were to materialize. Additionally, according to certain aspects, leakage risk may be scored by multiplying the probability by the severity. The results can be presented both under the form of leakage risk geospatial distribution (within the model) and as a risk matrix.

In some aspects, measurement, monitoring, and verification (MMV) refers to the specific requirements and standards set by regulatory authorities to ensure that CCS projects comply with environmental and safety regulations. MMV constitutes a comprehensive risk management plan in which assessment and analysis enable categorizing and scoring risks based on the likelihood of the occurrence of an event and the consequences of that event.

As a part of a CCS project, MMV may provide assurance of risk mitigation, ensure operation conformance, and integrity throughout an efficient and cost-effective monitoring. Conformance may be evaluated by comparing measured and predicted performance (injectivity, capacity, and containment) using modeling.

In the context of CO₂ sequestration, modeling may involve combining various models and data sets that represent different component processes of CO₂ sequestration, such as geological, hydraulic, geochemical, and geomechanical processes, and allowing these processes to interact and influence one another within a single simulation. This interaction is also referred to as coupled modeling or, more succinctly, coupling. More specifically, may account for changes in pressure, temperature, stresses, and geochemical processes when CO₂ is injected into geological formations. Geochemical processes can lead to alterations of rock properties (fluid-rock interactions), affecting the distribution and movement of CO₂ in space and time. These changes can also cause deformation and failure of the rocks or instabilities of faults and fractures, altering the permeability of the reservoir or creating new unwanted pathways for CO₂ migration, ultimately affecting the injectivity and capacity of the storage complex over time.

In some aspects, fluid injection and reservoir pressurization are common processes in oil and gas operations (e.g., underground gas storage (UGS), advanced geothermal systems (AGS), hydraulic fracturing, enhanced oil recovery, water-alternating gas, steam-assisted gravity drainage). Although some phenomena are well known, some others are often disregarded, either based on evidence of marginal or no operational impact, or following arbitrary conjectures.

Underground pressurization of a subterranean formation, or repressurization of a depleted hydrocarbon-bearing reservoir, involves pressure and temperature changes as well as rock-fluid interaction (geochemical changes). These changes can also impact completion materials (steel, cement) of existing wells. The consequences of these changes in terms of surface and subsurface deformation and infrastructure integrity (i.e., wells, pipelines, production/injection systems) may depend on the magnitude, frequency, initial state of the system, and nature of the interacting components (fluids, rocks, completion materials). Aspects of the present disclosure may consider the coupled thermo-hydro-mechanical-(geo)chemical (THMC) processes associated with the deformation of the rock skeleton during the CO₂ motion in the porous space. Since flow of any component (gas, liquid, dense phases) happens within the connected porous space of the deformable rock or along fractures or faults (i.e., discontinuities), the main consequence of THMC coupling is the volumetric change, or equivalently, the porosity changes and the potential impact on the permeability change in rock in discontinuities. Permeability changes generally lead to different flow patterns and pressure distributions, therefore impacting CO₂ concentration and pressure plume prediction over time.

Certain aspects of the present disclosure apply modeling to objectively and quantitatively assess risks, advancing the MMV into a more operational process encompassing (M)MMV. Like many modeling approach, coupled modeling comes with its own set of uncertainties that are important to address, executing analyses allowing a quantification of the uncertainty associated with model inputs and its impact on the model's outputs. Aspects of the present disclosure may include a coupled (flow and geomechanics) numerical modeling with uncertainty, allowing for leakage quantitative risk assessment. Aspects of the present disclosure may link modeling with MMV by means of sensitivity and uncertainty analysis of a numerical models' ensemble.

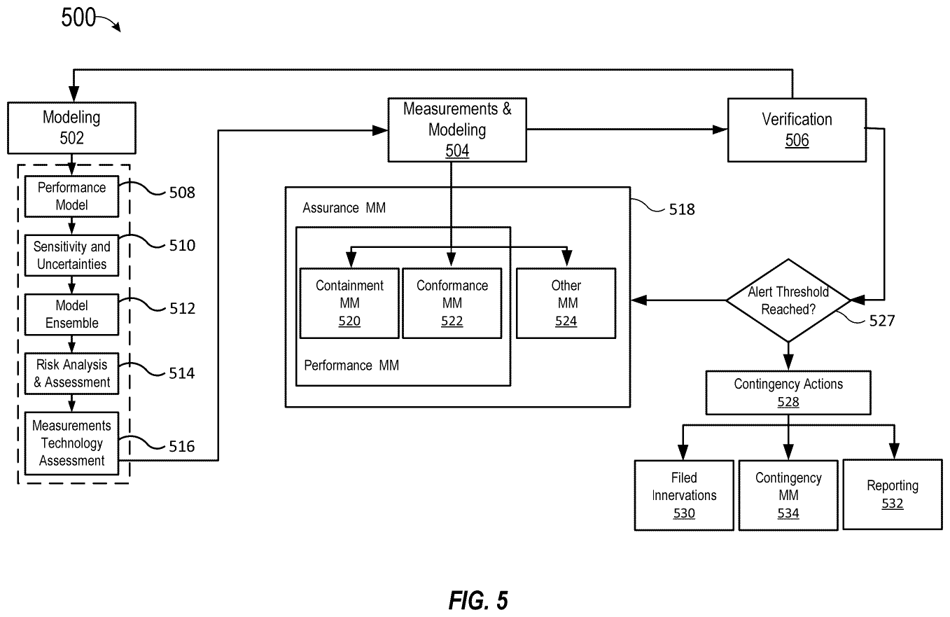

FIG. 5 depicts a comprehensive system 500 for modeling, measuring, monitoring, and verifying the performance of a subsurface operation, such as a carbon dioxide storage project or an oil and gas reservoir. The system 500 may include three components: a modeling component 502, a measurements and monitoring component 504, and a verification component 506, which may work together to ensure the safe and effective operation of the subsurface project.

The modeling component 502 may include several subcomponents that contribute to the creation and analysis of a comprehensive model of the subsurface operation. The performance model subcomponent 508 may generate a detailed model of the subsurface operation, taking into account various geological, geophysical, and engineering parameters. The sensitivity and uncertainties module 510 may assess the impact of uncertainties in the input parameters on the performance of the subsurface operation, while the models ensemble component 512 may generate a set of alternative models that capture the range of possible outcomes. Finally, the risk analysis and assessment module 514 may evaluate the risks associated with the subsurface operation using the models ensemble component 512 and the results of the sensitivity and uncertainty analysis module 510.

The measurements and monitoring component 504 may be responsible for collecting and analyzing data from the subsurface operation to ensure that it is performing as expected. The assurance monitoring and management (MM) module 518 may include three subcomponents: the containment MM module 520, which may monitor the containment of fluids within the subsurface operation; the conformance MM module 522, which may ensure that the operation is conforming to the planned design; and the other MM module 524, which may monitor other aspects of the operation, such as well integrity and surface facilities.

The verification component 506 may compare the data collected by the measurements and monitoring component 504 to predetermined thresholds at 527 and take appropriate actions if necessary. If the data indicates that the subsurface operation is not performing as expected, the verification component 506 may determine if contingency actions are needed. If so, the contingency actions module 528 may initiate field interventions 530 to address the issue, perform one or more contingency monitoring and management operations 534 to monitor the issue, and the reporting module 532 may generate a report detailing the actions taken and the results achieved. The report may then be used to update the models ensemble and the risk analysis and assessment module in the modeling component 502, allowing for continuous improvement of the subsurface operation.

The arrows in the diagram depicted in FIG. 5 may indicate the flow of information between the various components and subcomponents of the system. The modeling component 502 provides input to the measurements and monitoring component 504, which in turn provides data to the verification component 506. The verification component 506 may provide feedback to the modeling component 502, allowing for continuous updating and refinement of a subsurface operation model.

Thus, system 500 may provide a comprehensive approach to managing subsurface operations, ensuring that they are safe, effective, and efficient. By integrating modeling, monitoring, and verification components, the system enables operators to make informed decisions based on a detailed understanding of the subsurface environment and the potential risks associated with the operation.

To further enhance the risk assessment capabilities of system 500, numerical results from the dynamic subsurface modeling can be used to assess the probability and severity of potential risks in a more precise and quantitative manner. This may be achieved by assigning probability distributions to selected inputs to represent their variability. The Box-Behnken design, a sampling method known for its less intensive computational requirements, may be adopted to propagate uncertainty through a base model. However, aspects of the present disclosure are not limited to the Box-Behnken design and can operate independently of the selected sampling methodology. Other sampling methodologies may be used without deviating from the core principles of the present disclosure.

Aspects of the present disclosure have been validated using multiple model simulations with different sampled values for the uncertain inputs and a model ensemble has been created. The outputs of the ensemble have been analyzed using a 4D probabilistic approach to quantify probability and severity (consequences) of CO₂ leakages. Linking the probability and severity, a mapping and scoring of CO₂ leakage risk can be obtained, providing a comprehensive, less subjective and quantitative definition of risks via modeling to support the (M)MMV plan definition. By combining advanced coupled modeling, probabilistic analysis, and interactive 3D visualization, aspects of the present disclosure may provide a holistic, objective, and innovative representation of simulations results, allowing effective explanation and communication of the main findings to stakeholders (engineers, project managers and authorities), facilitating informed decision-making and risk mitigation strategies.

### Conceptual Numerical Model of CO₂ Injection and Storage

To demonstrate aspects of the present disclosure outlined above, a simple conceptual model has been built to analyze some relevant coupled processes developing during CO₂ injection. Dynamic coupled analyses have been performed to account for the mechanical and flow behavior during and after CO₂ injection.

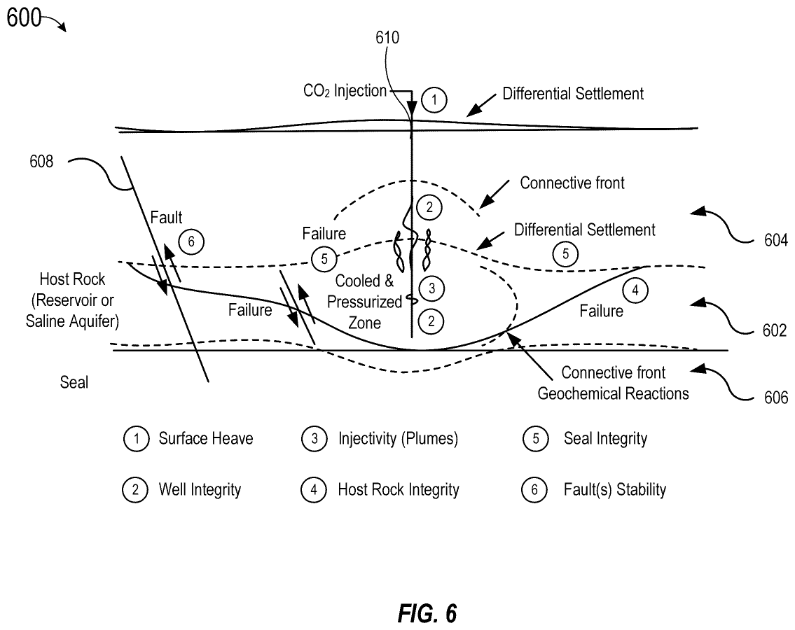

In accordance with some aspects of the present disclosure, a conceptual model of CO₂ injection and storage model 600 is presented in FIG. 6. The CO₂ injection and storage model 600, may include one or more well(s) 610, host rock 602 (depleted reservoir or saline aquifer), seal(s) 604 and 606, fault(s) 608, and/or fractures defines the so-called storage complex. In some aspects, and in the perspective of a quantitative risk assessment, a main objective of a numerical model is to anticipate stress changes caused by pressure changes, temperature changes, and the interaction of materials (rocks, steel, and cement) with CO₂. Four main trapping mechanisms may ensure permanent storage of the CO₂ underground: structural and stratigraphic, hydrodynamic, solubility, and mineral (geochemical). Because stress changes can potentially indicate failures within a storage complex, the objective of the numerical model of the storage complex may be to assess, in accordance with certain aspects of the present disclosure, if predicted failures induce CO₂ leakage risks, and therefore assess containment. The same model may also enable investigation of the other two storage performance factors of the potential site, namely, injectivity and capacity. For brevity, description of certain aspects of the present disclosure focus on the containment factor to quantify leakage risk. For the sake of simplicity, without losing the general concept of validity, a simple numerical example inspired from the scheme in FIG. 6 is considered, focusing exclusively on the structural and stratigraphic trapping, and on the risk of leakage through faults, such as fault 608. However, aspects of the present disclosure can be implemented with any combination of the four main trapping mechanisms identified above without deviating from the scope of the present disclosure. Moreover, consideration of other trapping mechanisms, in addition to the structural and stratigraphic trapping, may increase the accuracy of qualitative risk assessment in exchange for an increase in computational resource usage.

### Case Study Model

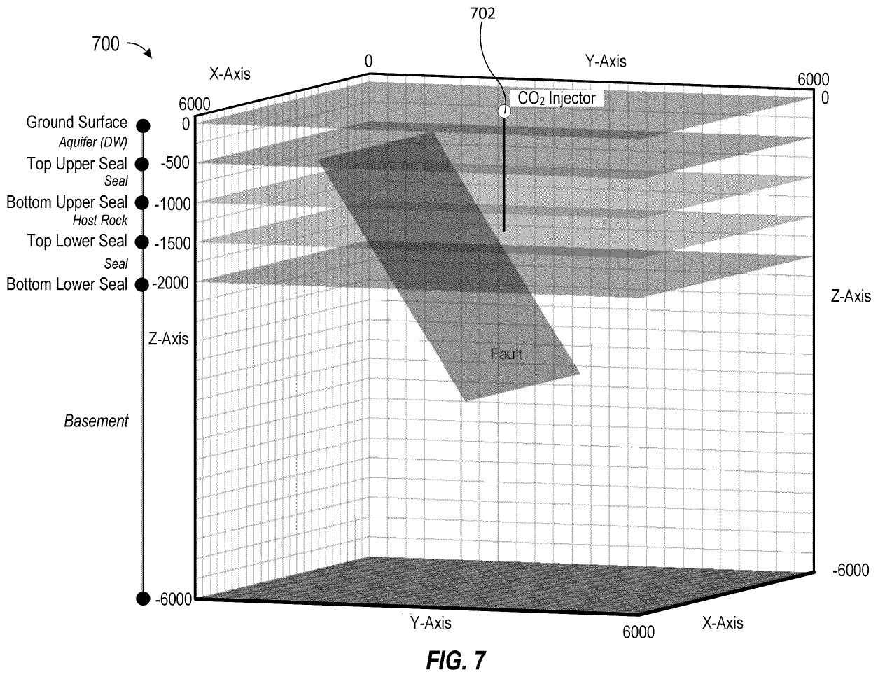

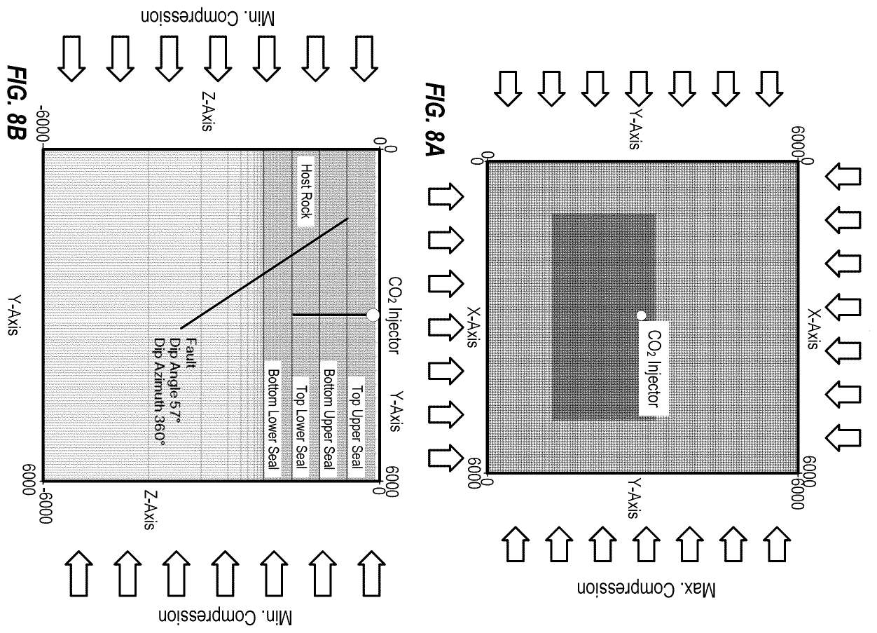

FIG. 7 depicts the geometry of the numerical model 700 used to mimic the CO₂ injection process in a saline aquifer. The storage complex represented by the model 700 includes one injector well 702, the host rock (saline aquifer), and two low-permeability seals (upper and lower). A fault with dip angle equal to 57° and dip azimuth 360° intercepts both seals, the host rock, and the basement. In some aspects, the numerical model depicted in FIG. 7 may be centered around the injector well 702. It extends 6 km north-south and 6 km east-west. The depth of the model has been assigned at z=6 km. The space discretization is obtained by means of an orthogonal mesh (pillar grid) consisting of equal-length elements in x and y horizontal directions (50 m). The vertical resolution of the mesh may be constant from the ground surface down to the bottom lower seal as depicted in FIG. 8A and FIG. 8B. In such a model, the thickness of the elements is equal to 25 m. The mesh may be completed from the bottom lower seal down to the model base (z=6 km) considering 10 divisions with thickness increasing with a geometric factor equal to 1.5. The final grid may include 1,296,000 elements and 1,332,331 nodes.

### Mechanical and Hydraulic Initial and Boundary Conditions

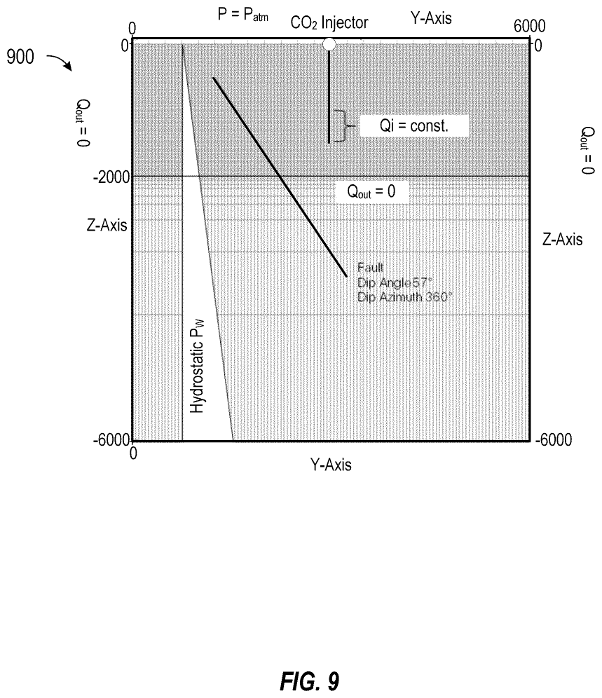

FIGS. 8A, 8B, and 9 depict initial and boundary conditions, as well as a numerical integration scheme, for a coupled hydro-mechanical model of a CO₂ storage complex in accordance with examples of the present disclosure. In aspects, the model depicted in FIG. 8A and FIG. 8B may simulate the injection of CO₂ into a host rock formation and assess the potential for fault reactivation and CO2 leakage. That is, FIG. 8A depicts a top view of mechanical and hydraulic initial and boundary conditions applied to the numerical model (e.g., FIG. 7), in accordance with aspects of the present disclosure. The model is submitted to the gravity load, and horizontal stress disequilibrium is imposed by means of displacements-controlled compression on lateral boundaries. That is, a minimum compression (total minimum horizontal stress) may be applied in the north-south direction. This choice ensures consistency of the imposed initial normal faulting stress regime with predefined fault orientation. In some examples, other configurations are possible and could be analyzed. In some aspects, the base of the model is free to move only horizontally (roll constraints).

The top of the model (ground surface) may be at atmospheric pressure and free to move in all directions. In some aspects, it may be assumed that a continuous water phase at initial hydrostatic pressure fills the porous space. The top of the basement at −2000M depth and the lateral boundaries are closed boundaries to flow (flow rate Qₒᵤₜ is zero). A constant flow injection rate Qᵢ may be imposed along the section of the well penetrating the host rock.

FIG. 8B depicts a section view north-south through the injector well of the numerical model, illustrating the mechanical and hydraulic initial and boundary conditions, in accordance with aspects of the present disclosure. The model comprises several geological layers, including a top upper seal, host rock, top lower seal, bottom lower seal, and bottom upper seal.

In some examples, a fault with a dip angle of 57° and dip azimuth of 360° is included in the model. The fault may intersect the host rock layer and extend into the upper and lower seals. The presence of the fault adds complexity to the model and allows for analysis of potential fluid flow and mechanical interactions along the fault plane. In some aspects, the well injector penetrates through the geological layers and terminates within the host rock. In some aspects, the well injector serves as the conduit for CO₂ injection into the host rock layer. The boundary conditions at the well injector, such as injection rate and pressure, can be specified to simulate different injection scenarios.

The model domain is discretized into a grid of elements to facilitate numerical simulations. The grid resolution may be refined in regions of interest, such as near the well injector and fault, to capture localized effects accurately. In some examples, the grid resolution is optimized to balance computational efficiency and accuracy of the simulation results. The initial and boundary conditions for the mechanical and hydraulic aspects of the model may be defined based on a specific geological setting and injection scenario being studied. These conditions may include initial stress state, pore pressure distribution, fluid properties, and injection parameters. By incorporating realistic initial and boundary conditions, the model aims to provide meaningful insights into the coupled processes occurring during CO2 injection and storage.

FIG. 9 depicts a hydraulic (flow) initial and boundary conditions for the numerical model of CO₂ injection in a section view north-south through the injector well, in accordance with aspects of the present disclosure. The model may consider the fluid flow dynamics within the geological formation during CO₂ injection. The top of the model may be initially set at atmospheric pressure, representing the pressure condition at the ground surface. This boundary condition allows for fluid exchange between the model domain and the atmosphere, if necessary. In some examples, the atmospheric pressure may be set to a specific value based on the location and elevation of the injection site.

A constant flow injection rate Qᵢ may be imposed along the section of the well penetrating the host rock. The injection rate determines the volume of CO₂ being introduced into the formation per unit time. In some aspects, the injection rate can be varied to study different injection scenarios and their impact on the fluid flow and pressure distribution within the formation.

The lateral boundaries and the bottom of the model are set as no-flow boundaries (e.g., Qₒᵤₜ=0), indicating that there is little to no fluid exchange across these boundaries. This assumption may be commonly made in reservoir simulations to simplify the model and focus on the fluid flow within the defined model domain. However, in some examples, specific flow boundary conditions may be applied based on the geological setting and the presence of adjacent formations.

The fault is represented as a distinct feature within the model domain. In some aspects, the fault may have different hydraulic properties compared to the surrounding rock matrix, such as enhanced permeability or reduced permeability due to fault gouge or mineralization. The hydraulic characteristics of the fault can influence the fluid flow patterns and pressure distribution in the vicinity of the fault zone. The hydrostatic pressure distribution within the model domain may be initialized based on the depth and the fluid properties. In some examples, the initial pressure distribution may be obtained from field measurements or estimated based on the regional hydrostatic gradient. The accurate representation of the initial pressure conditions may be used to simulate the fluid flow behavior during CO₂ injection.

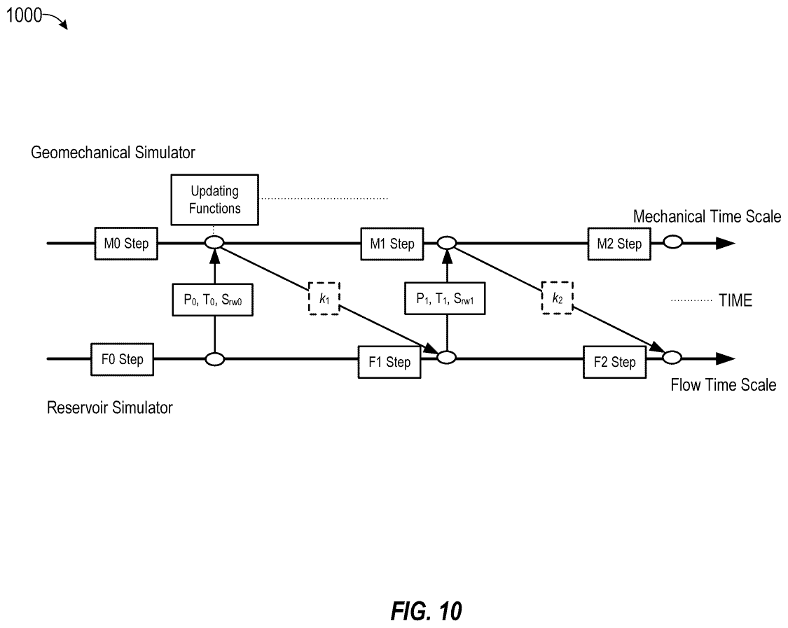

FIG. 10 depicts a schematic diagram 1000 of a loose explicit coupled numerical integration arrangement used for simulations, in accordance with aspects of the present disclosure. The arrangement involves the interaction between a geomechanical simulator and a reservoir simulator to model the coupled processes occurring during CO₂ injection and storage. In some aspects, the geomechanical simulator of FIG. 10 may be an example of the geomechanical simulator 206 of FIG. 2. In some aspects, the reservoir simulator of FIG. 10 may be an example of the geomechanical simulator 206 of FIG. 2. The geomechanical simulator may simulate the mechanical behavior of the geological formation and account for the mechanical properties of the rocks, such as stiffness, strength, and deformation characteristics. In some examples, the geomechanical simulator may utilize constitutive models, such as elasticity or elastoplasticity, to describe the stress-strain relationship of the formation.

In some aspects, the reservoir simulator may model the fluid flow and transport processes within the porous media of the geological formation, accounting for properties of the fluids, such as density, viscosity, and compressibility, as well as the characteristics of the porous media, including porosity, permeability, and relative permeability. In some aspects, the reservoir simulator may employ numerical methods, such as finite difference or finite element techniques, to solve the governing equations of fluid flow. In some aspects, one or both of the geomechanical simulator or the reservoir simulator depicted in FIG. 10 may be implemented using a machine-learning model as described with respect to FIGS. 2-4C and FIGS. 30-33.

The coupling between the geomechanical simulator and the reservoir simulator may be achieved through the exchange of relevant variables at discrete time steps. The geomechanical simulator may provide the updated pore volume, porosity, and permeability to the reservoir simulator at the beginning of each time step. These variables may be influenced by the mechanical deformation of the formation due to changes in stress state. In some aspects, the reservoir simulator uses the updated pore volume, porosity, and permeability to simulate the fluid flow and transport processes for the current time step and may calculate the pressure, temperature, and saturation distributions within the formation based on the governing equations and the specified boundary conditions.

In some aspects, the updated pressure, temperature, and saturation values may be passed back to the geomechanical simulator as input for the next time step. The geomechanical simulator may use these values to compute the corresponding changes in stress state and mechanical deformation of the formation. In some aspects, the coupling process continues iteratively, with the geomechanical simulator and reservoir simulator exchanging information at each time step. The mechanical time scale and flow time scale may be different, depending on the specific problem and the desired temporal resolution. In some examples, the time steps for the geomechanical simulator (M₀ Step, M₁ Step, M₂ Step) and the reservoir simulator (F₀ Step, F₁ Step, F₂ Step) can be synchronized or staggered to optimize the computational efficiency and accuracy of the simulations.

As introduced earlier, the main consequence of coupling is the volumetric change, or equivalently, the porosity changes and their impact on the permeability of rock and discontinuities. This is schematically identified by the symbols k₁, k₂ (etc.) in FIG. 10, where kᵢ (i=1, 2 . . . , n) represent updated permeabilities at each converged geomechanical time-step Mᵢ that are passed into the flow simulator to solve the hydraulic problem at flow time-step Fᵢ₊₁.

### Mechanical and Flow Properties (Base Case)

A linear distribution of mechanical properties with depth up to the bottom lower seal has been considered to define the base-case scenario. Constant mechanical properties have been assigned within the basement (Table 1).

TABLE 1

| | Young's | Poisson's | | Friction | Permeability | | |
|---|---|---|---|---|---|---|---|
| | Modulus | Ratio | UCS | Angle | Poro- | kₕ = | Density |
| Zone | (GPa) | (—) | (bar) | (degrees) | sity | k_{v (md)} | (g/cm³) |
| Aquifer | 1 − | 0.35 + | 71 − | 26 − | 0.25 | 1000 | 2.0 |
| Upper Seal | 0.01 z | 8.1 | 0.9 z | 0.01 z | 0.01 | 0.1 | 2.1 |
| Host Rock | | 10⁻⁵z | | | 0.15 | 100 | 2.0 |
| Lower Seal | | | | | 0.01 | 0.1 | 2.15 |
| Basement | 37 | 0.17 | 2200 | 48 | 0.01 | 0.1 | 2.3 |

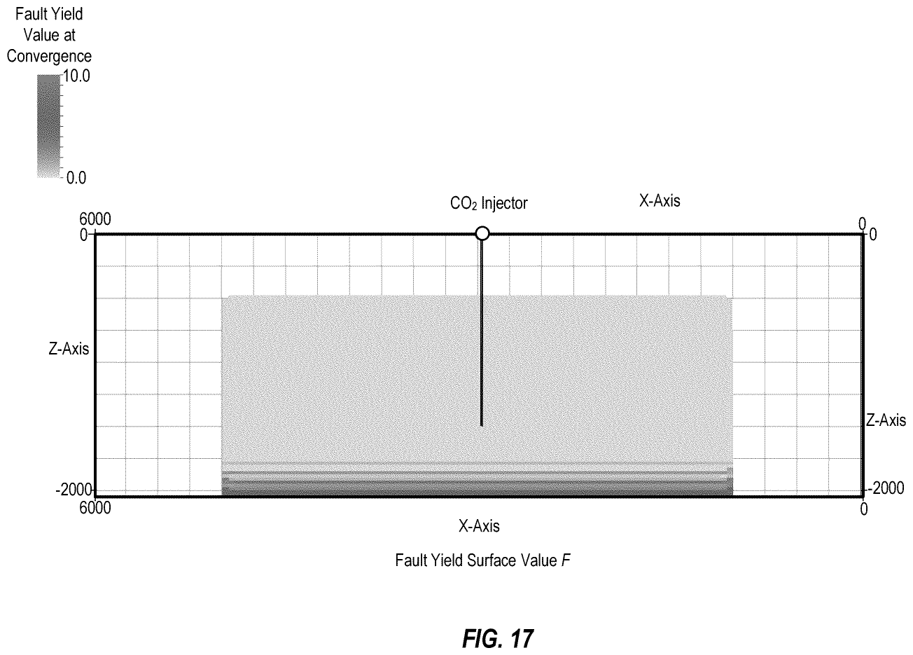

The flow properties, together with further details of the model geometry, are shown in FIG. 17 along the section north-south through the injector well and listed in Table 1. It's worth noting that three low permeability layers (kx=ky=kz=0.001 md) have been included in the model. Two layers bound the top and bottom of the host rock (saline aquifer). The third layer cuts the shallower 500-m thick formation, mimicking the top of a drinkable water aquifer. The two impervious layers delimiting up and down the host rock have been introduced on purpose to emphasize the role played by the coupled processes during CO₂ injection. It is well known that the impervious seals will generate a physical trapping mechanism related to the capillary pressure mobilized at the interface between the host rock and the seals (particularly the top seal). The two impervious layers have been integrated to enhance the retention properties of the seals above the physically admitted capillary threshold, thereby creating a permeability barrier to CO₂ flow. By doing this, the intersections of the fault plane with the top and bottom seal horizons become the potential weak zones where CO₂ can leak if the movements of the fault from pressure changes induce the fault's opening and consecutive permeability increase.

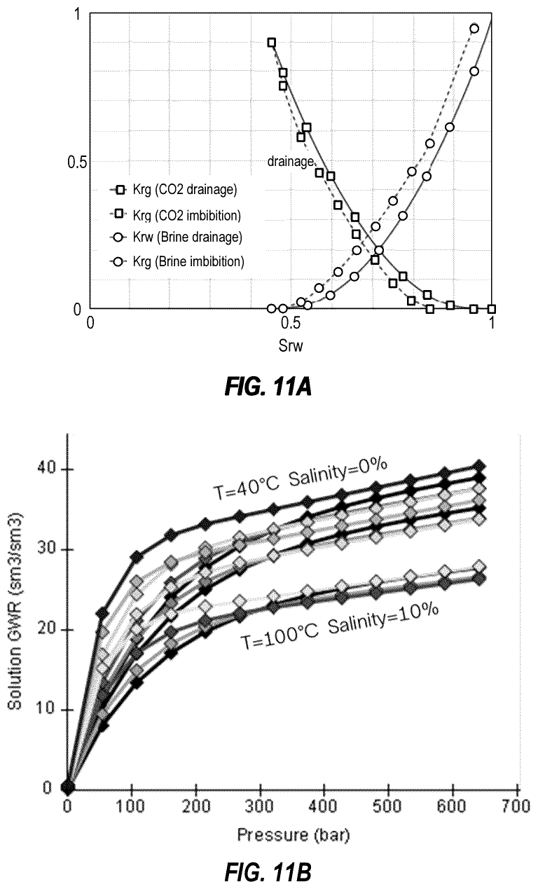

The compositional fluid model includes pure CO₂ and sodium chloride (NaCl) components, the latter being a neutral component type. The modified Peng-Robinson equation of state was used to model gas/aqueous phase equilibrium and obtain accurate gas solubility in the aqueous phase while accounting for salinity dependence. The aqueous phase dependency of density and viscosity on pressure and temperature in the presence of multiple dissolved components (CO₂ and NaCl, for example) may be considered via the Ezrokhi's method. The relative permeabilities curves for drainage and imbibition for CO₂ and brine are shown in FIG. 11A. Solubility has been considered including component solubility tables relating CO₂/H₂O solution ratio to pressure for a range of salinity from 0% to 10% and a range of temperature from 40° C. to 100° C. (FIG. 11B).

FIG. 11A illustrates the relative permeability curves for drainage and imbibition processes as a function of water saturation S_{rw}. The relative permeability represents the ability of a fluid phase to flow through the porous medium in the presence of other fluid phases. In the context of CO₂ storage, the drainage process refers to the displacement of brine by injected CO₂, while imbibition refers to the displacement of CO₂ by brine.

The drainage relative permeability curves for CO₂ (Kg (CO₂ drainage)) and brine (Krw (brine drainage)) are shown, respectively. These curves describe the relative permeability of each phase as a function of water saturation during the drainage process. As the water saturation decreases, the relative permeability of CO₂ increases, indicating the increasing ability of CO₂ to flow through the porous medium. The imbibition relative permeability curves for CO₂ (Krg (CO2 imbibition)) and brine (Krw (brine imbibition)) are represented by the dashed lines, respectively. These curves describe the relative permeability of each phase during the imbibition process, where brine displaces CO₂. The imbibition curves typically exhibit hysteresis, meaning that the relative permeability values differ from those observed during drainage.

FIG. 11B depicts CO₂ solubility curves for variable pressure, temperature, and salinity conditions. CO₂ solubility refers to the amount of CO₂ that can dissolve in brine under specific reservoir conditions. Understanding CO₂ solubility can be used when predicting the long-term storage capacity and behavior of injected CO₂ in geological formations. The CO₂ solubility curves are plotted as a function of pressure (in bar) for different temperature and salinity scenarios. The blue curve represents the CO₂ solubility at a temperature of 40° C. and a salinity of 0%, while the yellow curve corresponds to a temperature of 100° C. and a salinity of 10%. These curves demonstrate the impact of temperature and salinity on CO₂ solubility.

As pressure increases, the CO₂ solubility also increases, indicating that more CO₂ can dissolve in brine at higher pressures. However, the rate of increase in solubility varies depending on the temperature and salinity conditions. In some examples, higher temperatures and lower salinities generally favor higher CO₂ solubility, as observed in the blue curve compared to the yellow curve. The CO₂ solubility curves provide insights into the potential for CO₂ dissolution and long-term storage in geological formations. By considering the specific pressure, temperature, and salinity conditions of a target reservoir, engineers and scientists can estimate the amount of CO₂ that can be permanently stored through solubility trapping mechanisms.

In some aspects, the relative permeability and CO₂ solubility data presented in FIG. 11B can be used as input parameters for numerical simulations of CO₂ storage systems. These simulations help predict the flow behavior, migration, and ultimate fate of injected CO₂ in geological formations, aiding in the design and optimization of CO₂ storage projects. In some aspects, the model has been initialized with a pressure of 122 bar at a datum depth of 1250 m (middle of the host rock layer) and constant temperature of 40° C. (isothermal conditions). The compositional simulation case considers an initial condition with 99% H₂O, 1% NaCl, and no CO₂.

### Fault Modeling and Permeability Evolution

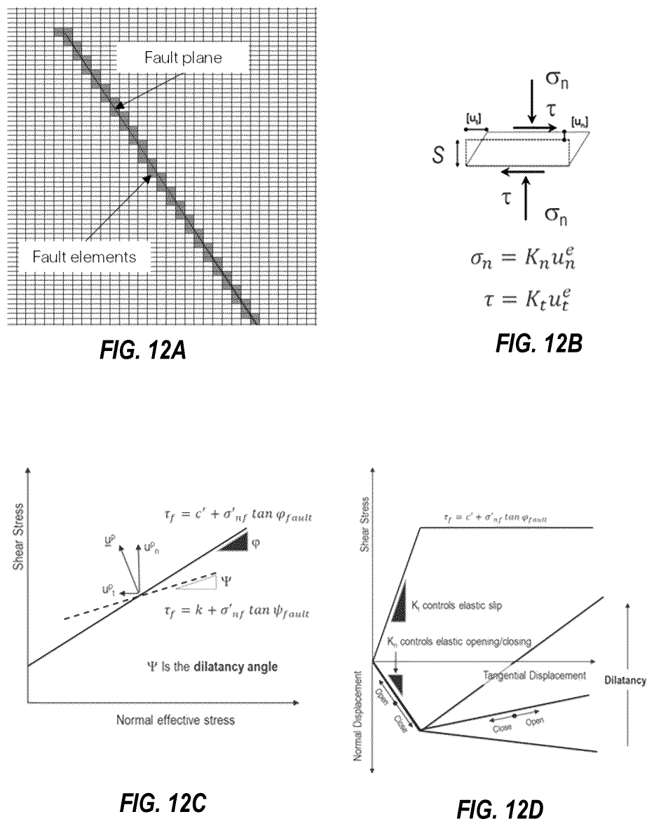

FIGS. 12A-D illustrate the representation of a fault plane and fault elements in a numerical model, along with the governing equations for fault behavior, in accordance with aspects of the present disclosure. The characterization and modeling of faults may be used for understanding their impact on fluid flow and geomechanical behavior in geological systems.

FIG. 12A depicts the representation of a fault plane within a numerical grid. The fault plane may be discretized into individual fault elements, which may be embedded within the volumetric grid cells. Each fault element may be associated with specific properties and constitutive relationships that govern its behavior. The fault elements may be defined by their geometrical characteristics, such as orientation, dip angle, and thickness. In some examples, the fault elements may be assigned different hydraulic and mechanical properties compared to the surrounding rock matrix to capture the unique behavior of fault zones. These properties can include permeability, porosity, stiffness, and strength parameters.

The discretization of the fault plane into fault elements allows for the accurate representation of fault geometry and the incorporation of fault-specific flow and geomechanical processes in the numerical model. By explicitly modeling the fault elements, the impact of faults on fluid flow, pressure distribution, and stress state can be simulated and analyzed.

FIG. 12B depicts the governing equations for fault behavior in the numerical model. The equations describe the relationship between shear stress (τ), normal stress (σₙ), and fault slip displacement (uₜ). It's common practice in reservoir engineering studies to impose either constant faults permeability or assign variable permeability base on predefined evolution laws. The predefined evolution laws may be developed by experimentation on the geological structure of a given storage complex. Alternatively, the predefined evolution laws may be developed based on published data for particular materials. The predefined evolution laws reflect the interaction between certain parameters of the model. For example, an interaction may exist between the porosity of the host rock and pressure, thus a predefined evolution law may be provided to express this relationship. By acknowledging and taking into consideration these interactions between parameters, implementations of certain aspects of the present disclosure may increase the accuracy of the risk assessments. The hydro-mechanical coupling allows can be used to calculate what the permeability changes should be, taking account of all geomechanical parameters. In particular, the permeability of the fault may depend on its tendency to open or close under the applied state of stress. The latter may evolve over time as a function of the pressure change; therefore, the effective stress change, induced by initial CO₂ injection and consecutive gravity dominated storage. This physical mechanism is enabled by the hydro-mechanical coupling.

In some aspects, the fault mechanical behavior may be modeled by individual elements and their corresponding mechanical material properties. A methodology that may be adopted is known as the “equivalent material” approach. The behavior of the intact rock and the faults is lumped within the elements of the mesh intersected by the fault plane (FIG. 12A). The equivalent material is thus formulated by smearing the influence of the fault plane throughout the respective volumes that it occupies.

Appropriate constitutive relationships may be developed for the equivalent material whose response considers the interaction of all the constituent components. Therefore, in each element of the mesh intersected by the fault, a local coordinates system (defined by the normal and tangential axes to the fault plane) may be used to describe the equivalent material that accounts for both the deformation and failure behavior of the constituents, intact rock, and fault. The main difference between these two components (i.e., rock and fault) is that a fault permits normal and tangential relative displacements to the plane to develop. The fundamental assumption behind this approach is that the relative movements, when divided by the thickness of the equivalent material (t), can be interpreted as equivalent to continuum strains. The total global strain tensor at each mesh element is calculated by summing the global strain tensor for the intact rock with that of the fault. Considering the elastic uniaxial compressibility of the rock, this reads (Eqs. 1 and 2):

$$\frac{σ}{{E}_{eq}} = \frac{σ}{{E}_{rock}} + \frac{σ}{{E}_{fault}} = \frac{σ}{{E}_{rock}} + \frac{σ}{{K}_{n} t} \qquad ( 1 )$$

$${E}_{eq} = f {E}_{rock} \qquad ( 2 )$$

The fault stiffness is defined in both normal and shear directions. Rearranging Eq. 1 and Eq. 2, the following can be obtain:

$${K}_{n} = \frac{f}{( 1 - f ) t} {E}_{rock} \qquad ( 3 )$$

It's commonly assumed that the tangential stiffness Kₛ is equal to 50% of the normal stiffness Kₙ:

$${K}_{s} = \frac{{K}_{n}}{2} \qquad ( 4 )$$

By means of this formulation, the equivalent medium accounts for the stiffness and orientation of the fault as well as the compressibility of the rock (FIG. 12B). The thickness of the equivalent material (t) introduces an internal length parameter that may be used in FEM modeling to simulate the discontinuity behavior by means of a continuum solid element (thin layer element) and avoid numerical locking. The compliances of the fault depend on the fraction “f” in Eq. 3. This parameter can be used to obtain the sensitivity of the results to the fault stiffness, the latter being a well-known uncertain parameter.

Mohr-Coulomb failure criterion with a non-associated flow rule (dilatancy angle ψ_{fault}=5°) has been considered to describe the fault behavior if failure condition is reached (FIG. 12C). Thus:

$$F = {τ}_{f} - {c}^{′} - {σ}_{nf}^{′} tan {φ}_{fault} \leq 0 \qquad ( 5 )$$

$$Q = {τ}_{f} - {τ}_{o} - {σ}_{nf}^{′} tan {φ}_{fault} \qquad ( 6 )$$

where F is the yield surface, Q the plastic potential function, and τ_{f} and σ′_{nf} are the effective shear and normal stress acting on the fault plane, respectively. The friction angle of the fault φ_{fault} has been considered equal to a fraction of the rock internal friction angle (typical values in literature are obtained assuming φ_{fault}=0.75 φ_{rock}). The cohesion c′ has been assumed negligible.

When the stress reaches the plastic threshold F, the fault can slide, generating irreversible tangential displacements u^{p}ₜ and irreversible normal displacements u^{p}ₙ. The non-associated flow rule for this model can be expressed:

$${du}_{n}^{p} = d Λ \frac{\partial Q}{\partial τ} = d Λ ; \qquad ( 7 )$$

$${du}_{n}^{p} = d Λ \frac{\partial Q}{\partial {σ}_{n}^{′}} = d Λ tan {ψ}_{fault} ;$$

$$δ = \frac{{du}_{n}^{p}}{{du}_{t}^{p}} = tan {ψ}_{fault}$$

where dΛ is the plastic multiplier and δ is the dilatancy coefficient. The latter express the irreversible opening occurring on the plastically sliding fault (FIG. 12C). Considering again the case of CO₂ injection and pressurization, if reservoir pressure increases leading to a fault's destabilization, an irreversible (plastic) opening will increase the fault's transmissibility, thus raising the risk of CO₂ leakage. The total fault opening is given by:

$${u}_{n} = {u}_{n}^{e} + {u}_{n}^{p} \qquad ( 8 )$$

where u^{e}ₙ and u^{p}ₙ are the elastic and plastic normal displacement, respectively. Assuming the rock mechanics sign convention, compression generates positive strains or, equivalently, for the discontinuity, positive normal displacements uₙ. Therefore, it is evident that in the elastic regime (τ<τ_{f}, FIG. 12D) the discontinuity will always compact (close) during normal effective stress increase or dilate (open) when normal effective stress decreases. During the injection process reservoir pressure increases, leading to decreasing effective normal stress on the fault plane and decreasing clamping of the fault with tendency to opening. This process can also lead to a fault's slipping and destabilization. Of particular interest here, the opening will increase a fault's permeability, thus amplifying the possible risk of CO₂ leakage.

With Eq. 8 the hydro-mechanical coupling associated with the fault's instability may be translated numerically by means of permeability changes, thus quantifying the leakage. Aspects of the present disclosure may first identify the fault's flow properties. The permeability tensor K of the “equivalent material” called fault is derived from the matrix permeability tensor Kₘ of the intact rock and the fault permeability tensor K_{f}. This reads:

$$K = [ \begin{matrix}{k}_{x} & 0 & 0 \\ 0 & {k}_{y} & 0 \\ 0 & 0 & {k}_{z}\end{matrix} ] = {K}_{m} + {K}_{f} = [ \begin{matrix}{k}_{x}^{m} & 0 & 0 \\ 0 & {k}_{y}^{m} & 0 \\ 0 & 0 & {k}_{z}^{m}\end{matrix} ] + ( \frac{{V}_{f}}{{V}_{cell} 12 {a}^{2}} ) [ \begin{matrix}{n}_{x} & 0 & 0 \\ 0 & {n}_{y} & 0 \\ 0 & 0 & {n}_{z}\end{matrix} ] \qquad ( 9 )$$

where V_{f} is the volume of the fault, V_{cell} is the volume of the cell, nᵢ (i=x, y, z) are the local to global transformation components, a function of the direction cosines defining the fault's plane orientation in the Cartesian reference system. The initial matrix permeability tensor Kₘₒ is available from the flow reservoir model properties (kₓ^{mo}=k_{y}^{mo}=k_{z}^{mo}). The initial fault permeability tensor is generally calculated using the classical cubic law if an initial aperture “a” is defined. Aspects of the present disclosure may consider the fault permeability as scaled to the value given for the fault/matrix permeability ratio, assumed equal to 0.1.

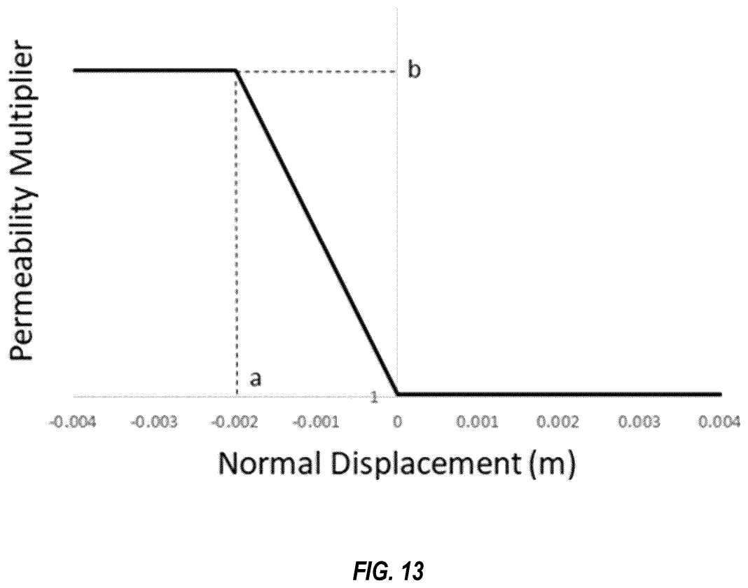

Considering now Eq. 8, during simulations, fault local permeability updating is imposed considering the evolution law in FIG. 13 expressed in the form:

$$\begin{matrix}{k}_{t} = {bk}_{to} ∀ {u}_{n} \leq - a \\ {k}_{t} = \frac{b}{a} {k}_{to} ∀ - a \leq {u}_{n} \leq 0 \\ {k}_{t} = {bk}_{to} ∀ {u}_{n} \geq 0\end{matrix} \qquad ( 10 )$$

where kₜ is the local in-plane (tangential) updated permeability and kto the local in-plane (tangential) initial permeability. The local permeabilities kₜ and kₙ are then transformed to the global coordinate system to define the updated fault permeability tensor K_{f} in Eq. 9 and added to the matrix permeability tensor Kₘ. The latter has not been modified in this example, which means that the rock matrix permeability doesn't change as a function of the rock porosity changes. This condition can be easily relaxed in future simulations. It should be noticed that conditions (Eq. 10) don't include updating of the initial out of plane (normal) permeability kno. Also, for the time being, a fault's closing (i.e., uₙ≥0) is not considered to change (decrease) the initial in-plane (tangential) permeability kₜₒ. Both hypotheses can be further relaxed in future studies. Table 2 summarizes the parameters used for the fault in the base-case scenario.

TABLE 2

| | Initial | Normal | Shear | | | |
|---|---|---|---|---|---|---|
| | Perme- | Stiff- | Stiff- | Friction | | Dilation |
| Initial | ability | ness | ness | Angle | Cohesion | Angle |
| Porosity | (md) | (bar/m) | (bar/m) | (degrees) | (bar) | (degrees) |
| 0.001 | 0.001 | 40000 | 15000 | 20 | 0.01 | 5 |

### Base-Case Simulation Results

The results of a base-case scenario implementing certain aspects of the present disclosure are discussed, herein, considering: 1) standalone flow simulation (uncoupled base case) and 2) hydro-mechanical coupling (coupled base case). The base-case scenario was run considering the parameters in Table 1 and Table 2 together with initial and boundaries conditions presented in FIG. 8A-FIG. 9. An injection rate of 5,000,000 m³/d has been considered (standard ISA conditions: P_{ISA}=1.013 bar, T_{ISA}=15° C., □CO₂=1.87 kg/m³). This corresponds at initial reservoir conditions (Pₒ=122 bar and Tₒ=40° C.) to a mass rate of about 3.4 MTPA assuming a CO₂ density of approximately 700 kg/m³ (supercritical state). The injection period extends to 10 years (2025 to 2035), followed by 40 years of equilibration (2035 to 2075).

### Standalone Flow Simulation (Uncoupled Base Case)

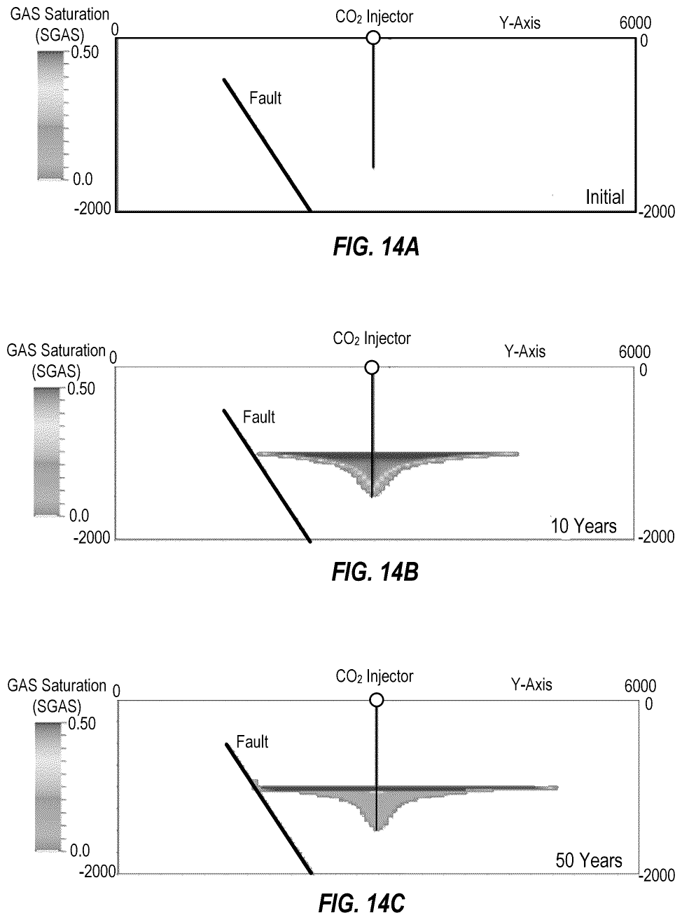

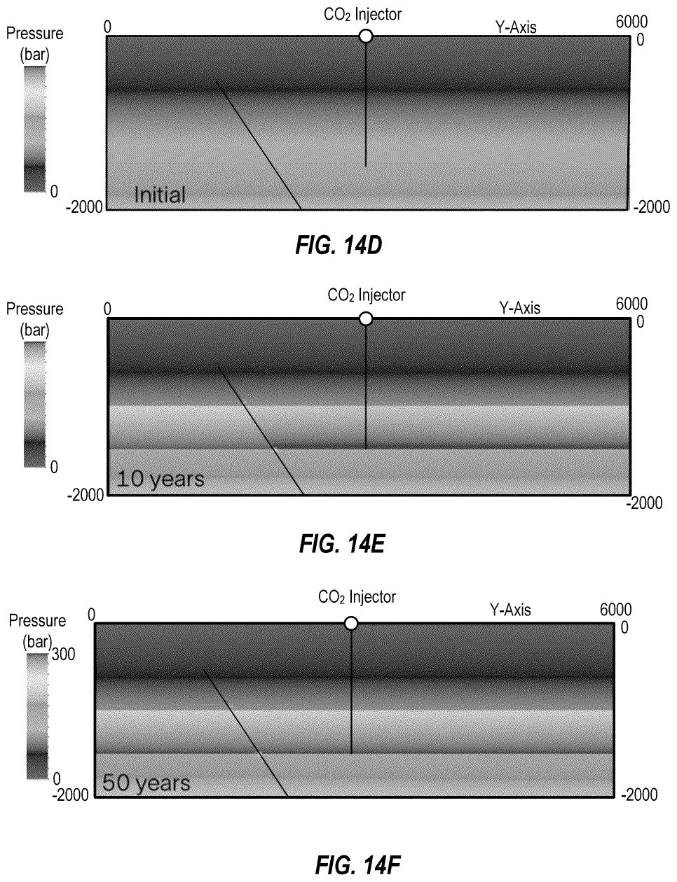

In the uncoupled base case, the communication between the dynamic reservoir simulator and the geomechanical simulator in FIG. 10 is not considered. The flow simulator runs in standalone mode. Thus, the permeability of the fault is not modified as a function of its possible opening. As shown in FIG. 14A-FIG. 14C, the CO₂ concentration plume develops with the typical “curved inverted cone” shape, contained on the top by the low-permeability barrier imposed by the upper seal at 1,000-m depth. An asymmetric concentration plume evolution is observed at the end of injection, after 10 years, because the fault acts as a low-permeability barrier. While the concentration plume's shape asymmetry is amplified after 50 years, the pressure plume, in contrast, is only slightly perturbated by the presence of the fault (FIG. 14D-FIG. 14F). This is because the pressure field can accommodate around the fault plane and within the lateral closed boundaries of the model as the fault plane doesn't extend up to the lateral model's boundaries.

That is, FIGS. 14A-14C depict the CO₂ saturation plume at the initial state, after 10 years of injection, and after 50 years of injection, respectively. The CO₂ saturation plume represents the spatial distribution of CO₂ within the porous media of the geological formation. As an initial state (FIG. 14A), the CO₂ saturation is zero throughout the model domain, indicating that no CO₂ has been injected yet. The geological formation is assumed to be initially saturated with native fluids, such as brine or hydrocarbons. After 10 years of injection (FIG. 14B), the CO₂ saturation plume has developed around the injector well. The plume exhibits a characteristic shape, with higher CO₂ saturation values near the injection point and gradually decreasing saturation towards the edges of the plume. The extent and shape of the plume depend on various factors, such as the injection rate, formation permeability, and buoyancy effects. After 50 years of injection (FIG. 14C), the CO₂ saturation plume has expanded further, covering a larger area of the geological formation. The plume has migrated both laterally and vertically, driven by the continued injection of CO₂ and the interplay of viscous, capillary, and gravitational forces. The saturation distribution within the plume may exhibit complex patterns, influenced by the heterogeneity of the formation and the presence of structural features like faults or layers with different properties.

FIGS. 14D-14F illustrate the pressure plume at the initial state, after 10 years of injection, and after 50 years of injection, respectively. The pressure plume represents the spatial distribution of pressure changes induced by CO2 injection.

At the initial state (FIG. 14D), the pressure distribution is uniform, reflecting the hydrostatic pressure gradient in the geological formation prior to CO₂ injection. The initial pressure serves as a reference state for evaluating the pressure changes caused by injection. After 10 years of injection (FIG. 14E) the pressure plume has developed, showing an increase in pressure in the vicinity of the injector well. The pressure increase is most pronounced near the injection point and gradually dissipates with distance from the well. The extent and magnitude of the pressure plume depend on factors such as the injection rate, formation permeability, and boundary conditions. After 50 years of injection (FIG. 14F), the pressure plume has expanded further, encompassing a larger area of the geological formation. The pressure increase has propagated both laterally and vertically, influencing a wider region around the injector well. The pressure distribution may exhibit spatial variations, depending on the formation properties and the presence of flow barriers or conduits.

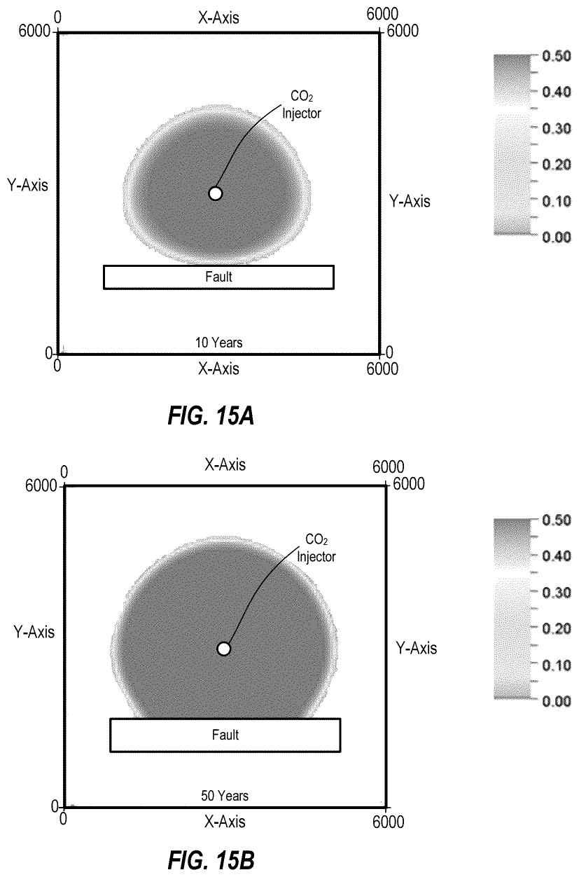

The uncoupled base-case scenario assumes that the CO₂ injection and the resulting saturation and pressure changes do not significantly affect the geomechanical properties of the formation. In some aspects, this simplification allows for a focused analysis of the fluid flow and pressure behavior without considering the complex coupled effects between fluid flow and geomechanics. This condition is better visible in FIG. 15A and FIG. 15B, where the CO₂ saturation plume extension at the top of the host rock is shown after 10 years (end of injection, FIG. 15A) and 50 years, at site closure (FIG. 15B). It's worth noticing that the CO₂ accumulation at the top of the host rock after 50 years is also accompanied by the accumulation of CO₂ against the fault because of its low permeability. The “push” of the CO₂ against the fault 40 years after injection halt is enough to allow a minimum amount of CO₂ leaking along the fault and penetrating the low-permeability seal (see FIG. 14C). The first CO₂ leakage is visible 20 years after the end of injection. After 30 years from injection cease, the maximum CO₂ concentration is 6% in the top seal for a maximum penetration of 70 m. As noted, the top seal thickness is 500 m. No further CO₂ leakage is observed in the remaining 10 years, resulting from the average field pressure decline.

### Coupled Base Case

In the coupled base case, the same injection strategy has been applied and fault permeability updating function (Eq. 10 and FIG. 13) has been enabled by means of the coupling scheme described in FIG. 10. For the sake of demonstrating the impact of a fault's reactivation on leakage and assess quantitatively the consequences, the present example considers solely fault permeability updating. Rock permeabilities are not modified during the injection process and in the subsequent gravitational equilibration.

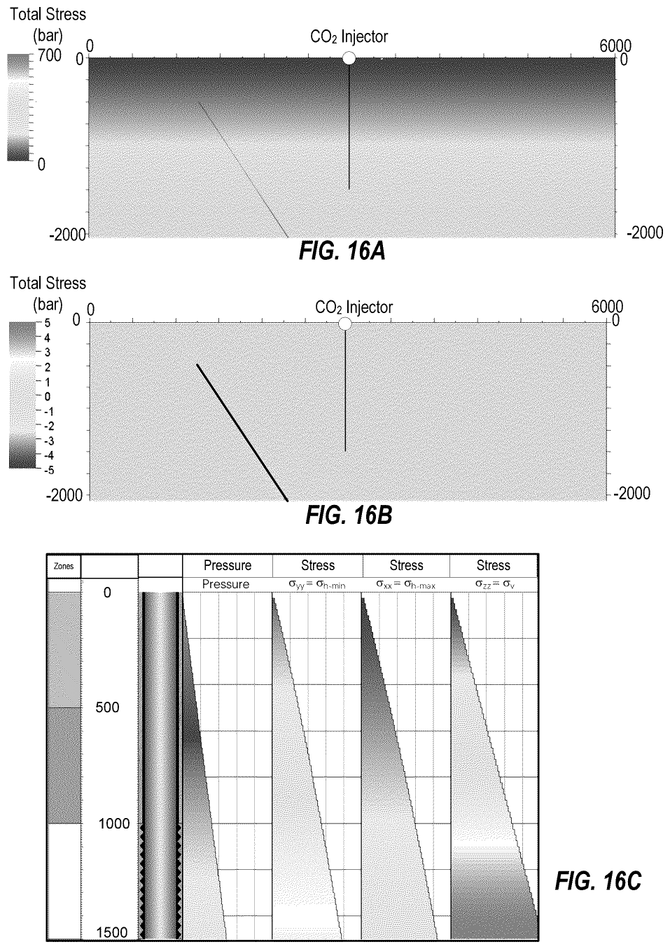

FIG. 16A shows the initial minimum total horizontal stress distribution on a north-south section through the injector well, obtained imposing the boundary conditions in FIGS. 8A-FIG. 9 given the “layered cake” geometry and the homogeneous lateral distribution of mechanical properties, initial stresses are principal and aligned with external boundary conditions. This can be verified by inspecting the distribution of the initial shear stress in FIG. 16B, with values equal to zero everywhere. The fault plane is the only geometrical and hydro-mechanical heterogeneity introduced within the model. Non-zero, yet negligible values of the shear stress (<3 bar), are barely visible near the deeper part of the fault. This is where mechanical properties contrast between fault and surrounding rock and applied stresses are likely to generate a minor fault's movement during the stress initialization step. These movements can be associated to a local plastic slip of the fault. To confirm this hypothesis, the fault yield surface values F in Eq. 5 are plotted in FIG. 17. Owing to Eq. 5, the condition F≤0 satisfies the elastic equilibrium of the fault and the absence of failed (reactivated) zones. As it can be inferred from FIG. 17, the zone of shear stress perturbation depicted in FIG. 16B corresponds to a narrow zone at the base of the fault where the initial stress state triggers a localized failure (F>0). Therefore, this zone is close to shear failure (incipient reactivation), while most of the fault plane is elastic (stable). The resulting initial state of stress reproduces a normal faulting stress regime (sh<sH<sV) (FIG. 16C).

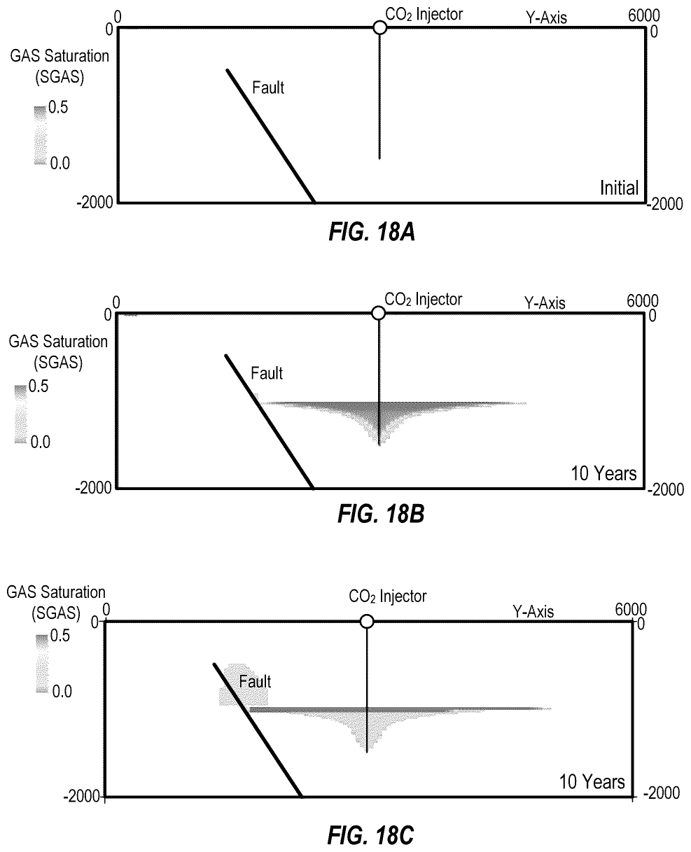

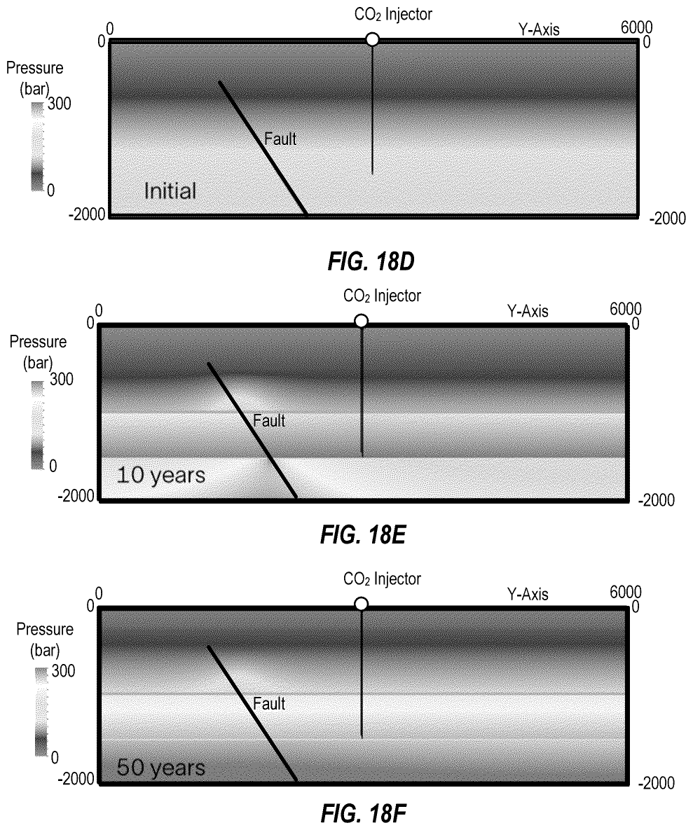

Moving from the initial state, the injection between 2025 and 2035 generates, as expected, a pressure perturbation within the storage complex, leading to effective stress changes. It's important to mention that failure of the caprock during the 50 years' simulation is not observed. Like the uncoupled case, FIGS. 18A-F shows the evolution of the CO₂ concentration plume and the pressure plume on a vertical section striking north-south through the well injector. FIGS. 18A-18F depict the CO₂ saturation plume at the initial state, after 10 years of injection, and after 50 years of injection, respectively, for the coupled base-case scenario. The CO₂ saturation plume represents the spatial distribution of CO₂ within the porous media of the geological formation, considering the geomechanical effects. At the initial state (FIG. 18A), the CO₂ saturation is zero throughout the model domain, indicating that no CO₂ has been injected yet. This initial condition is similar to the uncoupled scenario, as the geomechanical effects have not yet come into play.

After 10 years of injection (FIG. 14B), the CO₂ saturation plume has developed around the injector well, showing a similar pattern to the uncoupled scenario. However, the coupled scenario may exhibit slight differences in the plume shape and extent due to the influence of geomechanical deformation on the pore space and fluid flow properties. After 50 years of injection (FIG. 18C), the CO₂ saturation plume has expanded further, encompassing a larger area of the geological formation. The coupled scenario may display variations in the plume migration and distribution compared to the uncoupled scenario, as the geomechanical effects have had a longer time to influence the fluid flow behavior.

FIGS. 18D-18F illustrate the pressure plume at the initial state, after 10 years of injection, and after 50 years of injection, respectively, for the coupled base-case scenario. The pressure plume represents the spatial distribution of pressure changes induced by CO₂ injection, taking into account the geomechanical coupling effects. At the initial state (FIG. 18D), the pressure distribution is uniform, similar to the uncoupled scenario. The initial pressure serves as a reference state for evaluating the pressure changes caused by CO₂ injection. After 10 years of injection (FIG. 18E), the pressure plume has developed, showing an increase in pressure in the vicinity of the injector well. The coupled scenario may exhibit differences in the pressure distribution compared to the uncoupled scenario, as the geomechanical deformation affects the pore space and fluid flow properties, influencing the pressure propagation. After 50 years of injection (FIG. 18F), the pressure plume has expanded further, encompassing a larger area of the geological formation. The coupled scenario may display variations in the pressure distribution and magnitude compared to the uncoupled scenario, as the long-term geomechanical effects have had a significant impact on the fluid flow behavior.

By comparing the CO₂ saturation plume and pressure plume between the coupled and uncoupled scenarios, FIGS. 18A-18F highlight the consideration of geomechanical coupling in the modeling and analysis of CO₂ storage systems. The coupled scenario provides a more comprehensive and realistic representation of the subsurface processes, accounting for the complex interactions between fluid flow, geomechanical deformation, and their impact on CO₂ plume migration and pressure distribution. That is, the results are different from the uncoupled case in FIGS. 14A-14F. First, in contrast with the uncoupled case, in the coupled case the asymmetric concentration plume evolution is also accompanied by a heterogeneous pressure plume. Second, the CO₂ concentration plume reaches the fault earlier, already after 9 years. At the end of the injection, after 10 years, the fraction of CO₂ penetrating the upper seal is about 6%, and the penetration front thickness is about 70 m. Both are comparable with similar numbers predicted after 30 years from injection cease with the uncoupled scenario (FIG. 14A). Lastly, the difference between the uncoupled and coupled case is even more evident after 50 years. A CO₂ concentration plume of about 6% has penetrated the upper seal, expanding up to the seal top at 500-m depth. Therefore, it's evident that the coupled case provides a more pessimistic prediction concerning the risk of CO₂ leakage out of the host rock.

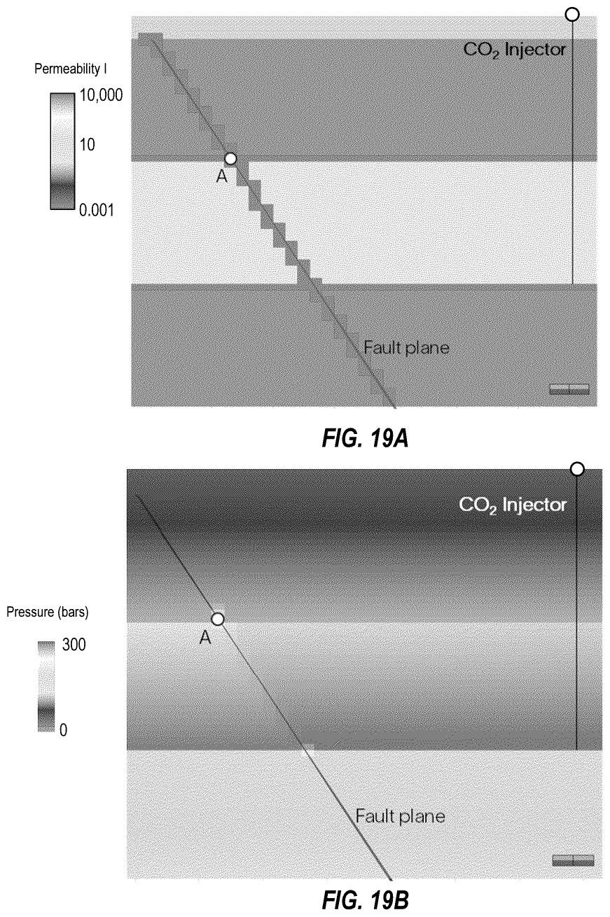

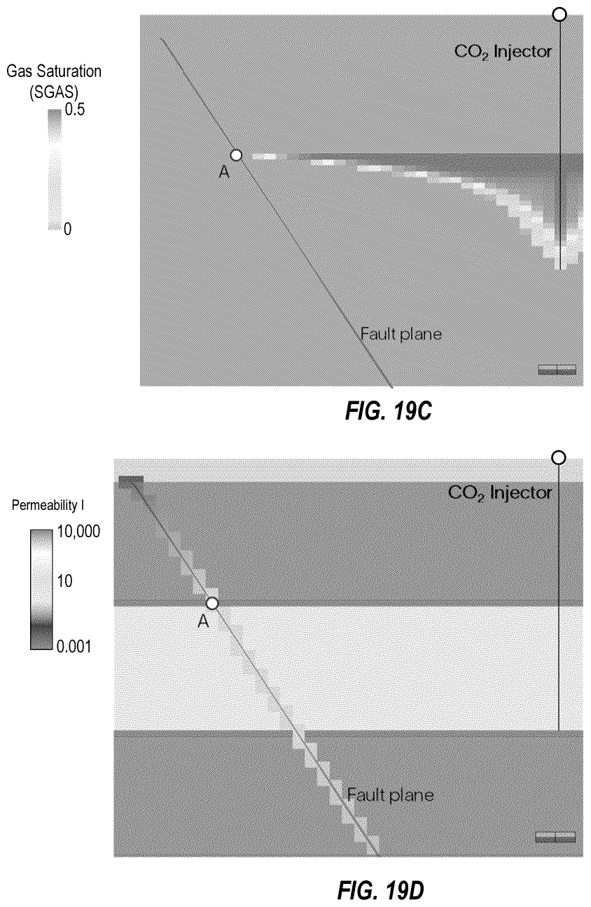

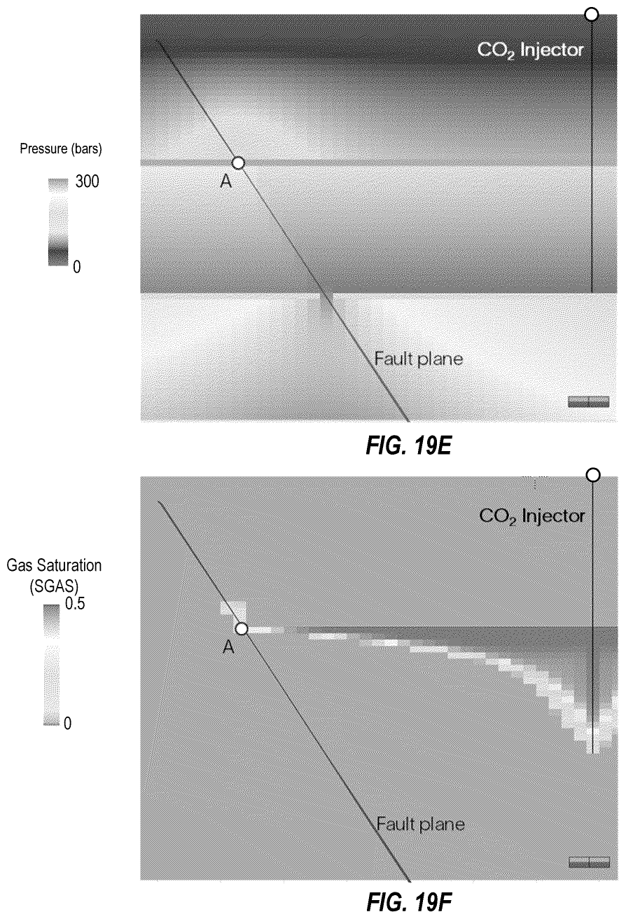

To understand the origins of these differences and highlight the importance of the coupled processes, FIGS. 19A-F shows, for both uncoupled and coupled scenarios, the patterns of the permeability component kₓ, pressure, and CO₂ saturation in 2035 (end of injection). As can be observed, the first major difference is associated with the permeability changes. For the sake of conciseness, without losing generalities, only the kₓ component distribution is plotted. While in the uncoupled case the permeability remains unchanged during the 10 years' injection period, in the coupled case fault permeability increases based on the evolution law in Eq. 10 (FIG. 19A, FIG. 19D). Using, for example, a=2 10⁻³ m and b=1 10⁵; these values can be calibrated assuming a range of admissible fault permeability to be explored. Thus, in the coupled scenario, the fault acts as a weak point, breaching the low-permeability barriers of the upper and lower seals. It should be noted that for the selected coupled scenario, the permeability updating leads to permeability tensor components within the fault of the same order of magnitude of those of the intact rock (kₓ=k_{y}=k_{z}=0.1 md) (FIG. 19D). Accordingly, the fault may not be a preferential flow corridor for CO₂ within the upper seal. This is confirmed by the saturation plume extension predicted after 40 years of gravitational stabilization shown in FIG. 19C. It's important to emphasize that in the coupled case the pressure plume doesn't pressurize only the host rock layer like in the uncoupled scenario (FIG. 19B). A pressure buildup is also observed in the upper and lower seal (FIG. 19C). This pressure buildup and consecutive dissipation in the seals induce a lower pressurization of the host rock, enabling the CO₂ saturation front to travel at a longer distance from the injector within the host rock toward the fault. Consequently, in the coupled scenario the CO₂ reaches the fault already at the end of injection, after 10 years.

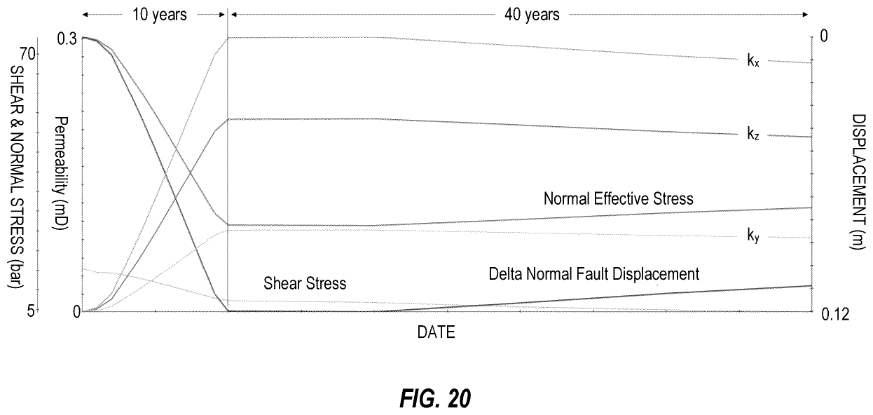

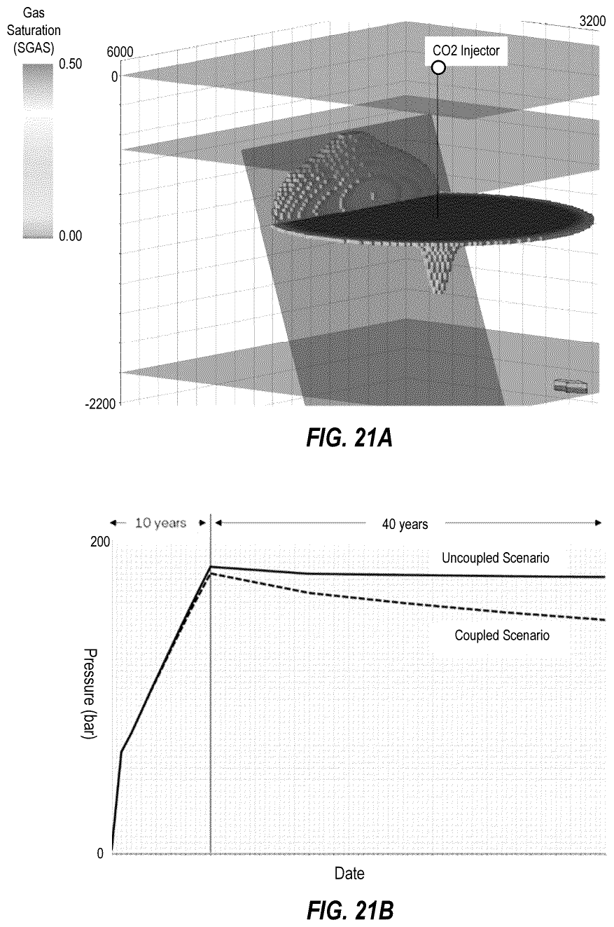

To further inspect the coupled processes effects acting on the fault, FIG. 20 shows, for the point A at the base of the upper seal (FIGS. 19A-F), the evolution of the three components of the permeability tensor in Eq. 9, together with the shear and normal effective stresses acting on the fault and the normal relative displacement of the fault. During the 10 years' injection period the progressive pressure buildup decreases the effective normal stress acting on the fault plane. This causes a decreasing clamping of the fault with tendency to opening. A slight decrease of the shear stress is also observed. A fault opening (i.e., negative variation of the normal fault displacement), in turn, increases the components of the permeability tensor according to Eq. 10. A fault opening during injection develops also within the elastic regime and with a slightly decreasing shear stress. Therefore, CO₂ leakage is not solely associated to fault slip and reactivation (failure), as commonly admitted. Following the 10 years of injection, pressure progressively dissipates and equilibrates in the host rock and the seals during the remaining 40 years. This leads to a small increase of the normal effective stress over time and a slight closure of the fault, with corresponding decrease of the permeability components kₓ, k_{y} and k_{z}. FIG. 21A shows the final extension of the CO₂ saturation plume in 2075 for the coupled case, together with the evolution of the average field pressure for both coupled and uncoupled scenarios (FIG. 21B). As can be observed, CO₂ leakage within the upper seal and pressure dissipation within the upper and lower seals leads to a more pronounced pressure decline in the coupled scenario.

As can be inferred from this analysis, the knowledge of CO₂ concentration plume extension is a second-order factor with respect to the leakage risk evaluation. The most critical factor is the CO₂ pressure plume. Its evolution is substantially different considering rigorous coupled behavior since host rock inflation or fault opening imply a faster traveling pressure front. This condition is fundamental to consider in the case of some monitoring applications, such as micro-seismic events prediction.

### Uncertainty Analysis

Any numerical model brings an intrinsic uncertainty associated with its parameters. Some of these parameters may have a clear physical meaning and be linked to measurements. Some other parameters may just act as tuning factors of the model. Furthermore, even admitting that all parameters have a clear physical meaning, the calibration of one given parameter against the corresponding measurement is also subjected to the uncertainty of the measurement itself. The limited accessibility to subsurface data obviously amplifies the uncertainty of inputs and, therefore, the uncertainty of the outcomes. Uncertainty analysis has been the object of increasing interest in many fields of investigation related to the subsurface, particularly in recent years with the raising adoption of artificial intelligence techniques, uncertainty being one technique that makes artificial intelligence possible.

In the case of CO₂ sequestration evaluation, uncertainties exist for the host rock characterization, particularly for saline aquifers, because of the typical lack of a reliable database. In depleted oil or gas fields these uncertainties are considered of less concern for the reservoir (host rock), as the data are generally available from previous hydrocarbon extraction activities. However, when it comes to seals characterization, data paucity is generally recognized for both oil or gas depleted reservoirs and saline aquifers.

Because not all the uncertain parameters of the models have the same impact on the outcomes, in practice a preliminary sensitivity analysis is used to provide a more complete understanding of a model's behavior. Sensitivity analysis helps identify critical model inputs, which can then be the focus of uncertainty analysis to account for variations and uncertainties in those inputs. Probabilities are then used to quantify uncertainty. The numerical results of the subsurface coupled model defined in a previous section have been used to assess probability and severity of occurring risks in a more precise and quantitative manner. Probability distributions have been assigned to some selected inputs to represent their variability. In certain aspects of the present disclosure, bucket brigade delay (BBD) sampling may be adopted as a sampling method to propagate uncertainty through the coupled base model.

To illustrate aspects of the present disclosure, three uncertain variables are chosen to explore the response surface of the base coupled model; namely, the injection rate, the permeability of the seal, and the permeability of the drinkable water aquifer (DW) (FIG. 7). Among these variables, the injection rate can't be strictly considered as an uncertain parameter because this is generally imposed in the injection plan. Our choice here has been dictated by the obvious impact that the injection rate has on the hydro-mechanical coupled behavior in terms of pressure plume evolution. The uncertainty variables, base-case values, and ranges considered for the BBD analysis are shown in Table 3. A uniform distribution has been considered for all the variables. The sample values set by the BBD sampler are shown in Table 4. A total of 13 realizations are defined by the BBD sampler. These realizations (i.e., numerical runs) define the models ensemble enabling us to assess probability and severity of an occurring leakage event and provide a quantitative risks assessment (QRA), without involving qualitative approaches or subjective evaluations based solely on expert judgement.

TABLE 3

| Variable | Base Value | Minimum | Maximum |
|---|---|---|---|
| Injection rate (m³/d) | 5,000,000 | 1,000,000 | 10,000,000 |
| Seal permeability multiplier | 1 | 0.01 | 100 |
| Aquifer (DW) permeability | 1 | 0.01 | 100 |
| multiplier | | | |

TABLE 4

| | | Upper Seal | Aquifer |
|---|---|---|---|
| | Injection Rate | Permeability | Permeability |
| Run | (m³/d) | multiplier | multiplier |
| 1 | 5.5e+06 | 50.005 | 50.005 |
| 2 | 1e+06 | 0.01 | 50.005 |
| 3 | 1e+06 | 100 | 50.005 |
| 4 | 1e+07 | 0.01 | 50.005 |
| 5 | 1e+07 | 100 | 50.005 |
| 6 | 1e+06 | 50.005 | 0.01 |
| 7 | 1e+06 | 50.005 | 100 |
| 8 | 1e+07 | 50.005 | 0.01 |
| 9 | 1e+07 | 50.005 | 100 |
| 10 | 5.5e+06 | 0.01 | 0.01 |
| 11 | 5.5e+06 | 0.01 | 100 |
| 12 | 5.5e+06 | 100 | 0.01 |
| 13 | 5.5e+06 | 100 | 100 |

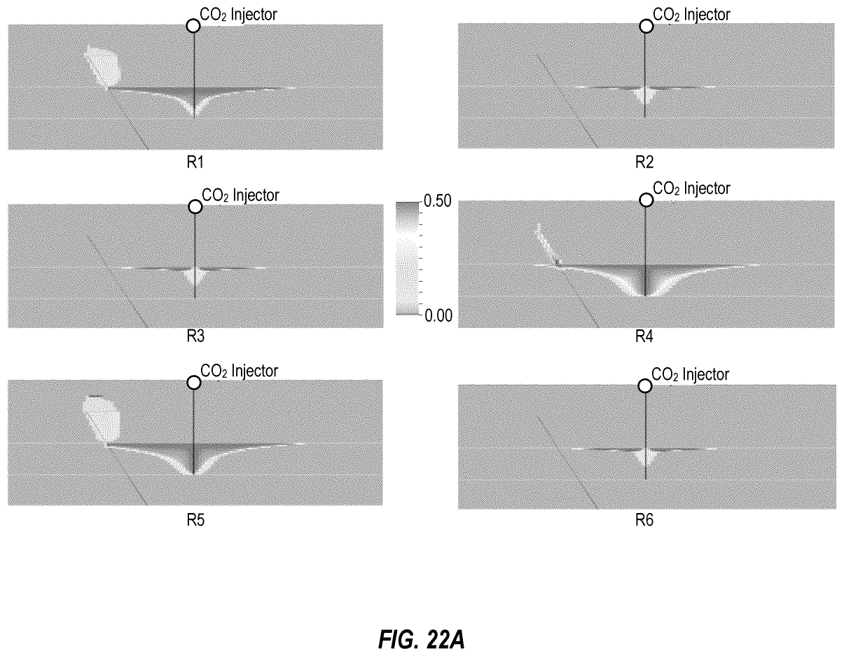

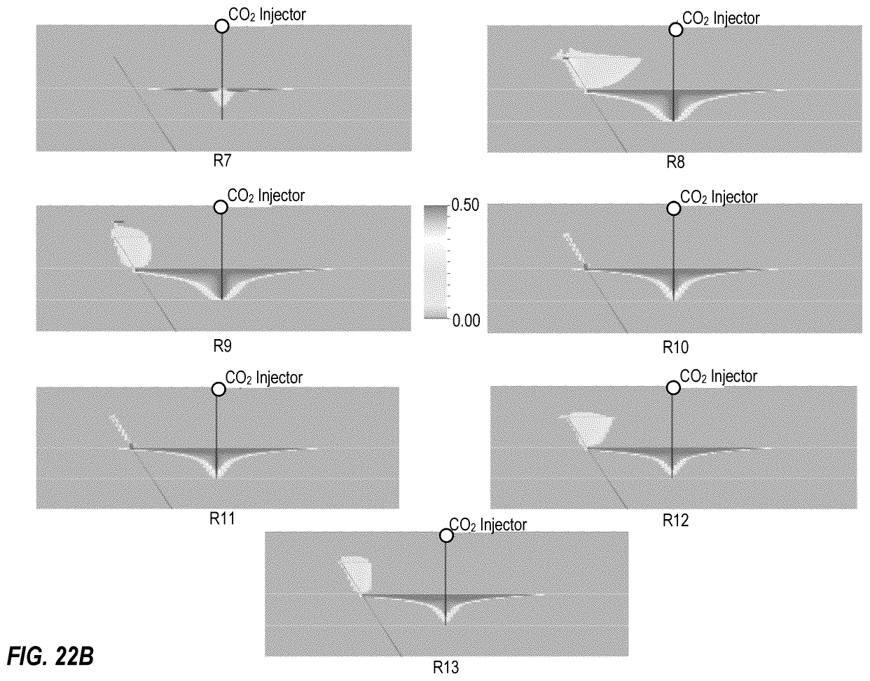

A summary of the realizations in terms of CO₂ saturation plume distribution after 50 years (site closure) using sample values set by the BBD sampler for the selected ensemble is shown in FIGS. 22A and 22B. Analogous to FIGS. 18A-FIG. 18F, results are inspected along the section north-south through the injector well. The combination of the sampled variables in Table 4 reproduces multiple patterns of CO₂ concentration plume spreading. These patterns are influenced by the heterogeneity of the permeabilities in the upper seal, the fault, and the shallower aquifer (DW). Although the results in FIGS. 22A and 22B refer to the year 2075, the ensemble offers a quantitative image of the main mechanical and hydraulic variables influencing the storage process for each timestep. The treatment of these data in terms of quantitative risk assessment is presented in the next section.

### Quantitative Risk Assessment Methodology

In risk assessment and probability theory, probability and likelihood are related concepts but are used in slightly different ways: (1) probability is a precise and computable measure of the chance of an event occurring. It is expressed as a numerical value between 0 and 1, where 0 represents an impossible event, and 1 represents a certain event; and (2) likelihood is a more qualitative term often used in a subjective sense to describe the perceived chance or probability of an event happening. It is often expressed in terms like “high,” “moderate,” or “low” to convey a sense of the event's probability without specifying precise numerical values.

With the objective of quantifying the risk of leakage certain aspects may calculate the probability of a leakage occurrence using the results of the uncertainty analysis built consuming the subsurface coupled model and the models ensemble results discussed in the previous section. These results constitute a precise and quantifiable measure, in the probability space, of the chance of the event to occur. Similarly, certain aspects may provide a quantification of the severity of leakage depending on the location of the event occurrence and the CO₂ mass released. Finally, leakage probability and severity are combined to provide leakage risk scoring.

Post-processing of the models ensemble results is a crucial step in evaluating the diversity of the outputs of the models within the ensemble. A probabilistic 4D approach has been developed to translate models ensemble results into a synthetic and useful information. For each timestep tₛ of each realization nᵣ (nᵣ=13 for example), the probability P^{L}(tₛ) of a leakage event E out of the host rock has been calculated within each cell n_{c} of the grid that is not part of the host rock, investigating in how many models of the ensemble the leakage occurs. The number of cells n_{c} not part of the host rock is

$${n}_{c} = n - {n}_{h} \qquad ( 11 )$$

where n is the total number of cells and nₕ is the number of cells within the host rock. The probability of leakage out of the host rock at timestep tₛ is:

$${P}_{L} ( {t}_{s} ) = \frac{{\sum }_{i = 1}^{{n}_{r}} {E}_{ij}^{L} ( {S}_{rCO 2} )}{{n}_{r}} ∀ i ∈ ( i , {n}_{r} ) and j ∈ ( i , {n}_{c} ) \qquad ( 12 )$$

where S_{rCO2} is the relative CO₂ saturation and

$${E}_{ij}^{L} ( {S}_{rCO 2} ) = \{ \begin{matrix}1 if {S}_{rCO 2} > 0 \\ o if {S}_{rCO 2} = 0\end{matrix} \qquad ( 13 )$$

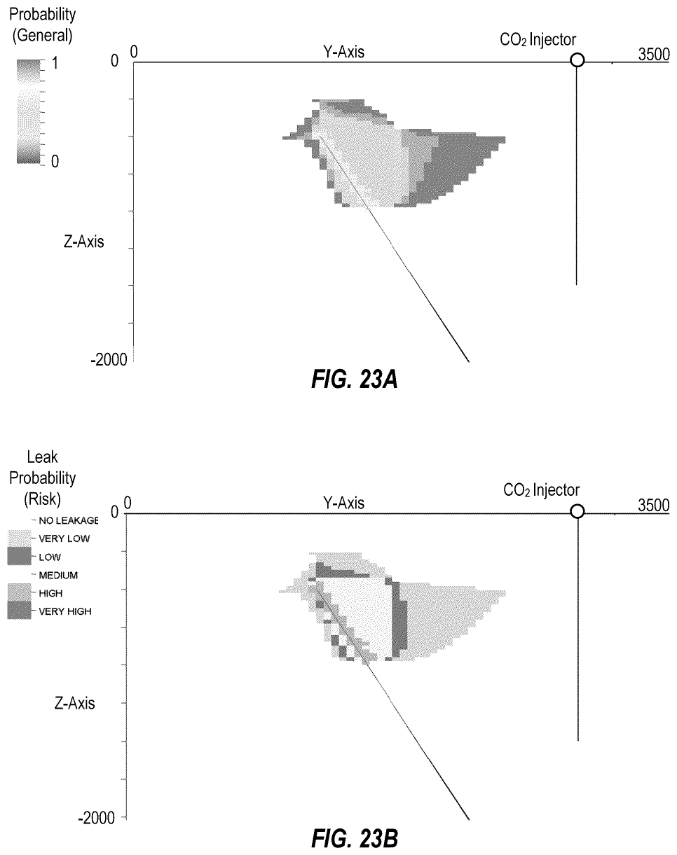

Consistent with previous analysis of the coupled base case, the following description focuses on two timesteps: the end of injection (2035) and the site closure (2075). Thus, the evolutive nature of the risk notion can be emphasized. The probability of leakage at end of injection, Eq. 12, is presented in FIG. 23A. For the sake of clarity, focus will be directed to the vertical section striking north-south through the injector well. Nonetheless, these results are available for the storage complex in a whole. Based on computed leakage probability P_{L}(tₛ), five classes have been defined (FIG. 23B) as follows:
P_{L1} very low probability: 0<P_{L}(tₛ)≤0.2
P_{L2} low probability: 0.2<P_{L}(tₛ)≤0.4
P_{L3} medium probability: 0.4<P_{L}(tₛ)≤0.6
P_{L4} high probability: 0.6<P_{L}(tₛ)≤0.8
P_{L5} very high probability: 0.8<P_{L}(tₛ)≤1
   as intuitively expected, and here rigorously calculated, the probability of leakage is high within the fault plane. Nevertheless, leakage event, although initiated by the fault opening, develops also because of the influence of another independent uncertain variable: the permeability of the upper seal.

Aspects of the present disclosure may define vector [P_{Li}] i∈(1,5) to describe the five leakage probability classes as follows:

$$[ {P}_{Li} ] = [ \begin{matrix}5 \\ 4 \\ 3 \\ 2 \\ 1\end{matrix} ] \qquad ( 14 )$$

Once the events probability is explored, the severity of a CO₂ leakage can be quantified considering its consequences, including (but not limited to): operational, CO₂ storage performance, economic or environmental impacts. Consequences for the environment and human health are logically considered as first priorities by regulators and stakeholders.

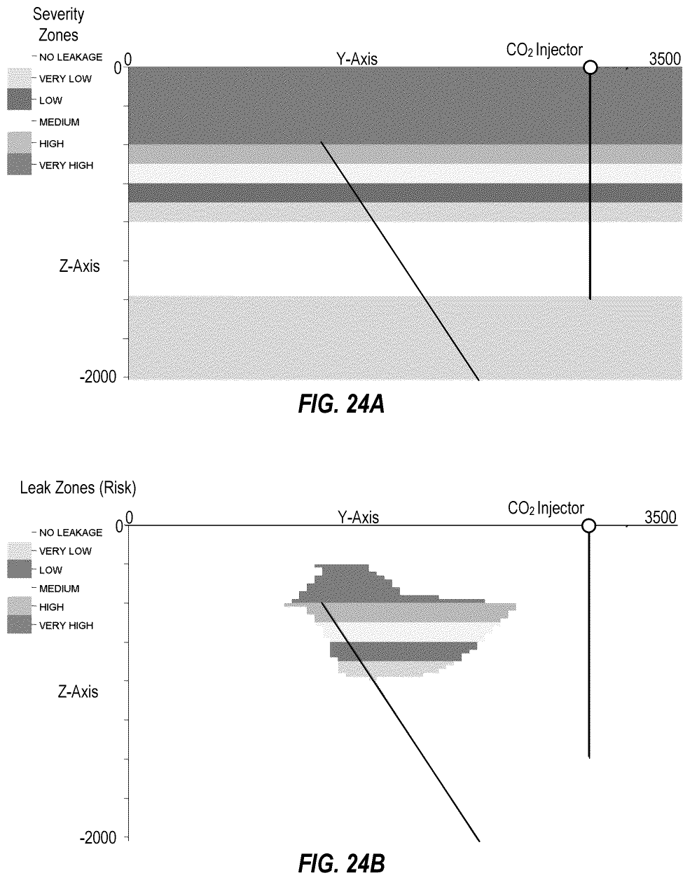

In the current case study model leakage severity has been addressed considering the zones of the leakage and the CO₂ mass released. A 3D property has been created to define five zones representing different degrees of zones severity S_{Z} if a leakage should happen in one of them. As starting choice, the zones defined for the purpose of this study show an increasing severity when moving vertically from the host rock to the surface (FIG. 24A). It's important to note that consequences of a CO₂ leakage are considered the greatest from the DW aquifer up to the surface, hence maximum severity is assigned. Therefore, S_{Zi}=1 is the very low zone severity (green) and S_{Zi}=5 is the very high zone severity (red). This is a working hypothesis that can be changed depending on specific project objectives and needs.

Aspects of the present disclosure may define the vector [S_{Zi}] i∈(1,5) to describe the five zones severity classes as follows:

$$[ {S}_{zi} ] = [ \begin{matrix}5 \\ 4 \\ 3 \\ 2 \\ 1\end{matrix} ] \qquad ( 15 )$$

Combining the 3D property that defines the five zones representing different degrees of zones severity S_{Zi}(FIG. 24A) and the 3D property that defines the leakage occurrence (Eq. 11), it is possible to quantify the leakage severity in terms of events zones. This is shown in FIG. 24B for the end of injection (2035).

It's worth noting that results in FIG. 24B don't discriminate the severity in terms of released mass of CO2. To quantify this severity, the percentage of leaked CO₂ mass M_{CO2}^{L} compared to the amount of CO₂ that a given cell can host may be considered. This quantity is directly available from the simulation results as:

$${M}_{CO 2}^{L} = {ρ}_{CO 2} {V}_{CO 2} = {ρ}_{CO 2} {S}_{rCO 2} ϕ {V}_{c} \qquad ( 16 )$$

where ρ_{CO2} is the CO₂ density, S_{rCO2} is the partial CO₂ saturation, ϕ is the porosity and V_{c} is the cell volume. Five different mass severity classes may be defined depending on the maximum amount of CO₂ mass hosted in the cell. This is controlled by the irreducible water saturation S_{rw}^{irr} that is:

$${M}_{CO 2}^{Max} = {ρ}_{CO 2} ( 1 - ( 1 - {S}_{rW}^{irr} ) ϕ {V}_{c} \qquad ( 17 )$$

From the relative permeabilities plots in FIG. 11A and FIG. 11B it may be inferred that S_{rW}^{irr}≈0.55. Identifying the percentage of leaked CO₂ at a given timestep tₛ as M_{CO2}^{L}(tₛ), the mass severity classes S_{Mi} are defined as:
S_{M1} very low severity: 0<M_{CO2}^{L}(tₛ)≤0.2 of the M_{CO2}^{Max}
S_{M2} low severity: 0.2<M_{CO2}^{L}(tₛ)≤0.4 of the M_{CO2}^{Max}
S_{M3} medium severity: 0.4<(M_{CO2}^{L}(tₛ)≤0.6 of the M_{CO2}^{Max}
S_{M4} high severity: 0.6<M_{CO2}^{L}(tₛ)≤0.8 of the M_{CO2}^{Max}
S_{M5} very high severity: 0.8<M_{CO2}^{L}(tₛ)≤1 of the M_{CO2}^{Max}

For each timestep M_{CO2}^{L}(tₛ) is calculated for each cell n_{c}, where leakage occurs as the average of the CO₂ masses obtained from the nᵣ realizations, therefore:

$${M}_{CO 2 ij}^{L} ( {t}_{s} ) = \frac{{\sum }_{i = 1}^{{n}_{r}} {M}_{CO 2 ij}^{L}}{{n}_{r}} ∀ i ∈ ( 1 , {n}_{c} ) \qquad ( 18 )$$

Aspects of the present disclosure may define the vector [S_{Mi}] i∈(1,5) to describe the five mass severity classes as follows:

$$[ {S}_{Mi} ] = [ \begin{matrix}5 \\ 4 \\ 3 \\ 2 \\ 1\end{matrix} ] \qquad ( 19 )$$

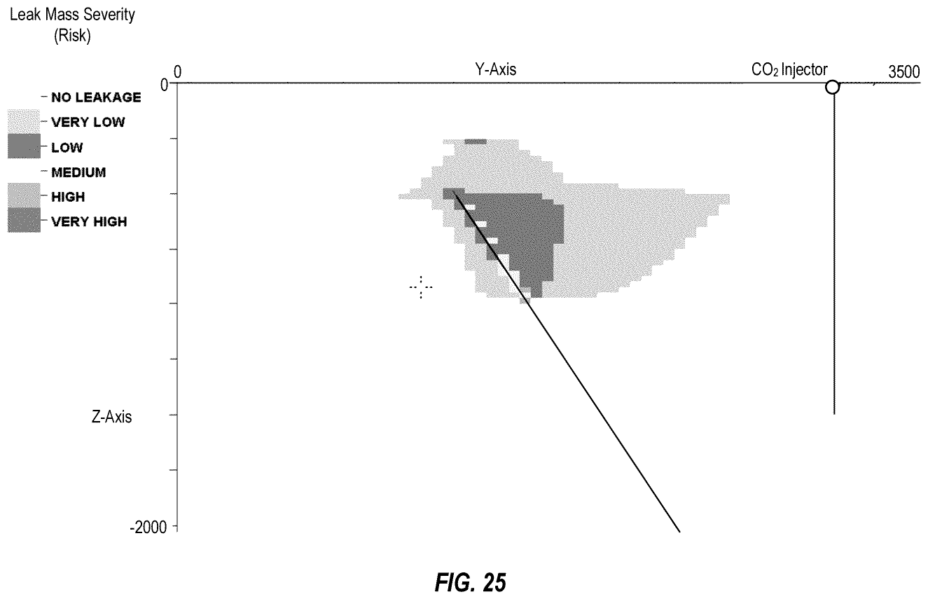

A 3D property has been calculated to define the five mass severity classes S_{Mi} using Eqs. 18 and 19. For the timestep 2035, the mass severity property is shown in FIG. 25.

To quantify the overall severity, the zones severity (Eq. 15) and the mass severity (Eq. 19) are combined in Eq. 20:

$$[ {M}_{sij} ] = {[ {S}_{zi} ] [ {S}_{Mj} ]}^{T} = [ \begin{matrix}5 & 10 & 15 & 20 & 25 \\ 4 & 8 & 12 & 16 & 20 \\ 3 & 6 & 9 & 12 & 15 \\ 2 & 4 & 6 & 8 & 10 \\ 1 & 2 & 3 & 4 & 5\end{matrix} ] \qquad ( 20 )$$

The severity matrix [M_{Sij}] can be used to define the overall leakage severity classes S_{Li}:
S_{L1}=very low severity: 0<M_{Sij}≤5
S_{L2}=low severity: 5<M_{Sij}≤10
S_{L3}=medium severity: 10<M_{Sij}≤15
S_{L4}=high severity: 15<M_{Sij}≤20
S_{L5}=very high severity: 20<M_{Sij}≤25

Aspects of the present disclosure may define the vector [S_{Li}] i∈(1,5) to describe overall leakage severity classes:

$$[ {S}_{Li} ] = [ \begin{matrix}5 \\ 4 \\ 3 \\ 2 \\ 1\end{matrix} ] \qquad ( 21 )$$

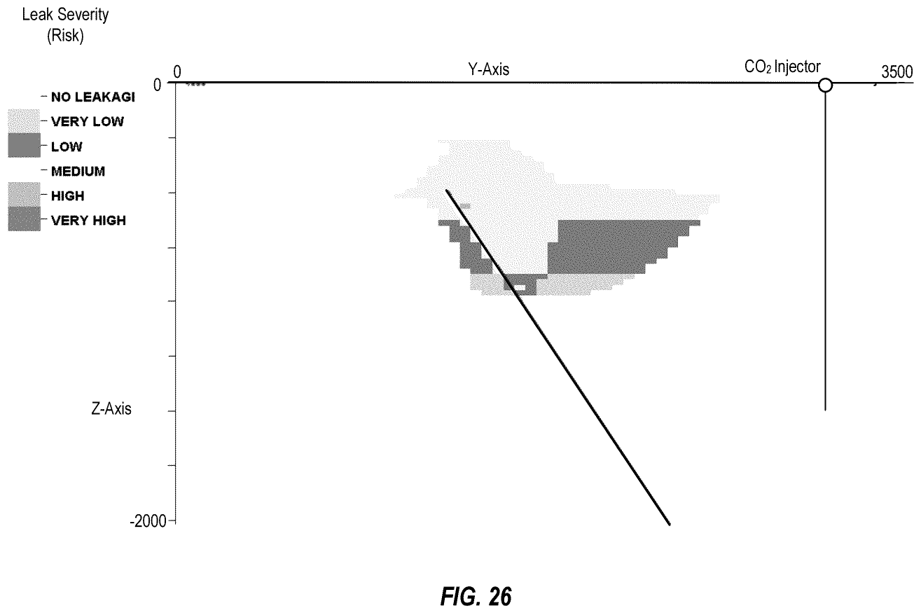

FIG. 26 shows the geospatial distribution of the overall leakage severity classes S_{Li} associated with the simulated CO₂ injection in 2035. These results underline the dependency of the severity upon the location of the leakage event. Thus, for the same amount of leaked CO₂, the higher severity is identified in the upper part of the storage complex, where the location severity is the higher based on the current choice of the severity zones (FIG. 24A).

Given the objective evaluation, in the probability space, of the chance of the event to occur enabled by the model's ensemble results, leakage probability classes (Eq. 14) and leakage severity classes (Eq. 21) at each timestep are multiplied to score the risk of leakage with the matrix [R_{Lij}]:

$$[ {R}_{Lij} ] = {[ {P}_{Li} ] [ {S}_{Li} ]}^{T} = [ \begin{matrix}5 & 10 & 15 & 20 & 25 \\ 4 & 8 & 12 & 16 & 20 \\ 3 & 6 & 9 & 12 & 15 \\ 2 & 4 & 6 & 8 & 10 \\ 1 & 2 & 3 & 4 & 5\end{matrix} ] \qquad ( 22 )$$

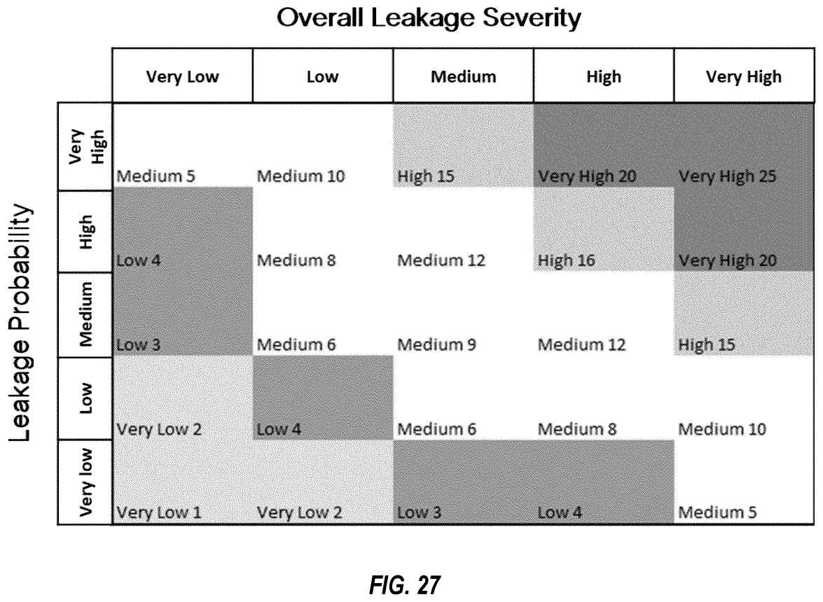

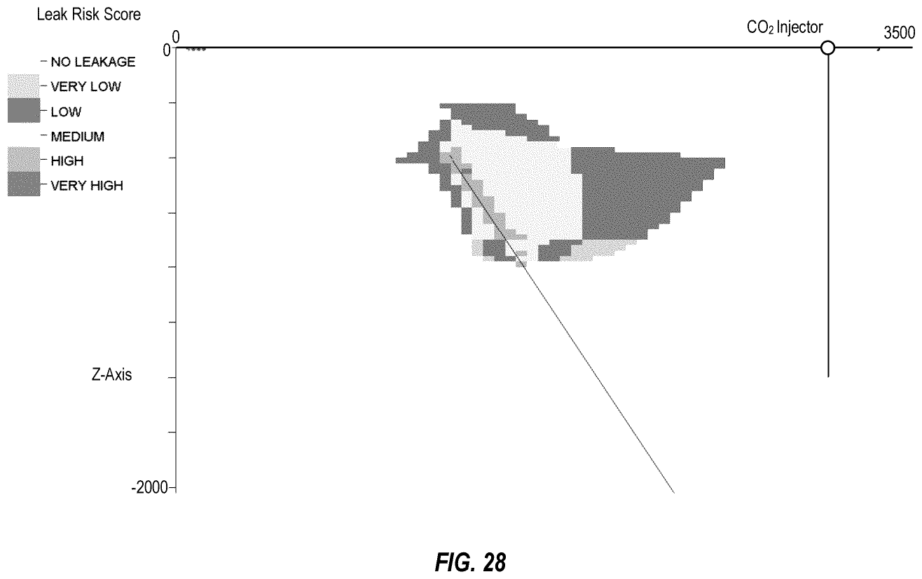

The risk of leakage matrix [R_{Lij}] can also be visualized in the traditional formalism shown in FIG. 27. The resulting geospatial distribution of the risk of leakage scoring at the end of injection (2035) is shown in FIG. 28. As can be observed, consistently with the calculated probability (FIG. 23B) and the leakage mass severity (FIG. 26), the mapped risk score is from “medium” to “high” when impacting the DW aquifer.

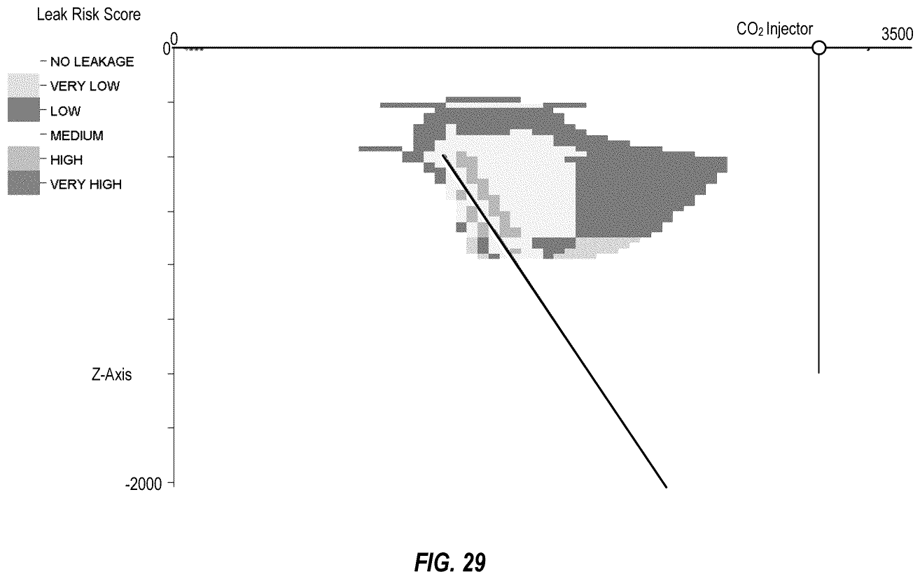

As previously commented, the probability of a leakage event to occur varies over time during the sequestration process. This is equivalent to state that the risk of leakage matrix (Eq. 22) in each point of the storage complex evolves with time. Aspects of the present disclosure may easily demonstrate this risk time dependency quantitatively. FIG. 29 shows the leakage risk score at site closure (2075). These results can be compared with the homologous at end of injection (2035) in FIG. 28. As can be observed, the high-risk score around the fault in 2035 migrates above the fault in 2075. Also, the leakage risk in terms of zone extension and score increases in the upper part and slightly decreases in the lower part of the storage complex, both for area extension and risk category. This result translates a direct physical mechanism associated with the upward migration of the injected CO2.

Certain aspects of the present disclosure may rely on the use of the numerical results of dynamic subsurface coupled modeling to assess and quantify the risks in a more precise, less subjective, and quantitative manner, enabling a comprehensive definition of effective (M)MMV plans.

The conceptual model described in the present disclosure integrates flow and geomechanical coupled behavior to assess the probability of faults reactivation or caprock integrity and eventually the risk of CO₂ leakage. Uncertainty analysis and a 4D probabilistic workflow are used to quantify CO₂ leakage risk.

In the uncoupled base case, the communication between the dynamic reservoir simulator and the geomechanical simulator has not been considered. Therefore, the flow simulator runs in standalone mode and the permeability of the fault is not modified as a function of its possible opening or closing during injection and consecutive long-term storage.

In the coupled base case, the same injection strategy has been applied and fault permeability updating has been considered based on mechanism controlled by its geomechanical behavior. The coupled simulation results show that starting from the initial state, the injection between 2025 and 2035 and the consecutive equilibration under gravity load doesn't generate failure of the caprock. On the other hand, during injection, the fault opens under a combined effect of initial elastic decreasing clamping (decrease of the effective normal stress) and fault reactivation (failure). This leads to fault permeability increase and CO₂ leakage. The coupled model's ensemble results show that the amount of leakage varies as a function of imposed rates and combination of permeabilities of host rock and seals. Processing of the model's ensemble results has allowed to quantify the probability and severity of CO₂ leakage, and ultimately to score the resulting risk. The following points can be highlighted:

During CO₂ injection the progressive pressure buildup decreases the effective normal stress acting on the fault plane. This causes a decreasing clamping of the fault with a tendency to opening.

Fault opening increases the components of the permeability tensor, creating a preferential path for CO₂ leakage; following injection, pressure progressively dissipates and equilibrates in the host rock and the seals.

Fault opening during injection develops also within the elastic regime. Therefore, CO₂ leakage is not solely associated to fault slip and reactivation (failure), as commonly admitted. Some quantity of CO₂ could already leak before any unwanted fault reactivation.

During the equilibration period under the action of the gravity field an increase of the normal effective stress over time and closure of the fault is observed, with corresponding decrease of the permeability components. Long term storage is less prone to risk of fault leakage.

Pressure dissipation within the upper and lower seals across the transmissive fault leads to a more pronounced pressure decline that is clearly detected by the coupled scenario. The lower pressurization of the host rock enables the CO₂ saturation front to travel at a longer distance from the injector within the host rock toward the fault. Consequently, the coupled case provides a more pessimistic, therefore conservative, prediction of the risk of CO₂ leakage out of the host rock.

Related to the previous point, it is apparent that the knowledge of CO₂ concentration plume extension is a second-order factor with respect to the leakage risk evaluation. The most critical factor is the CO₂ pressure plume extension. Its evolution is substantially different considering rigorous coupled behavior, as host rock inflation or fault opening imply a faster-traveling pressure front. This condition is fundamental to consider when defining monitoring programs.

The uncertainty analysis has offered further insights related to other possible leakage events. This analysis has helped identifying direct leakage across the upper seal. This event, although initiated by the fault opening, develops because of the influence of another independent uncertain variable: the permeability of the upper seal.

The model's ensemble created during the uncertainty analysis has been used to calculate the probability of CO₂ leakage, as the ratio of the number of models in the ensemble that predict leakage versus the total number of models. Probability has been calculated in each cell of the 3D grid providing a geospatial distribution of the probability of occurrence of CO₂ leakage.

CO₂ leakage severity has been addressed considering where the leakage is predicted to occur and the amount (mass) of CO₂ released. This combined severity allows to better assess consequences of a leakage. If a reduced amount of mass of CO₂ is released in a critical zone the severity will be high while if the same occurs in a non-sensitive zone, it will be low.

In the present disclosure, five zones have been defined assuming an increasing severity when moving vertically from the host rock to the surface. This working hypothesis can be changed depending on site-specific requirements. The definition of these zones can be dictated by local regulations (e.g., lateral extension of the permit), population exposure, presence of nearby activities, environmental constraints, etc.). Five mass severity classes have been defined looking at the percentage of leaked CO₂ mass M^{L} compared to the amount of CO₂ that a given cell can host. Zone and mass severity have been combined to define the overall severity of the CO₂ leakage.

The definition of severity within a risk assessment framework is a multifaceted outcome shaped by various factors, including the perceived magnitude of potential issues and the specific constraints, regulations, and stakeholders associated with a particular site or context. Consequently, the definition of severity must be tailored and adapted for each site, reflecting its unique characteristics, challenges, existing regulation, and stakeholder considerations to foster a comprehensive and contextually relevant risk management approach. In a quantitative risk assessment workflow, it's important to identify objective metrics. These metrics are selected for numerical weighting purposes, to identify the areas in the grid that can be important leakage pathways and require attention for analysis. If other metrics can be identified and used to assess leakage severity, the proposed methodology offers an original numerical treatment and improve objective evaluation of risks quantification. As for any numerical model, the spatial discretization has an implicit impact on the outcomes of the analysis. Hence, as for any numerical simulation, the results of the proposed workflow depend on the careful definition of the resolution of the numerical grid. In this respect, although the intention is to provide an objective quantitative assessment, the meaning of severity could still be based on some sort of expert judgement.

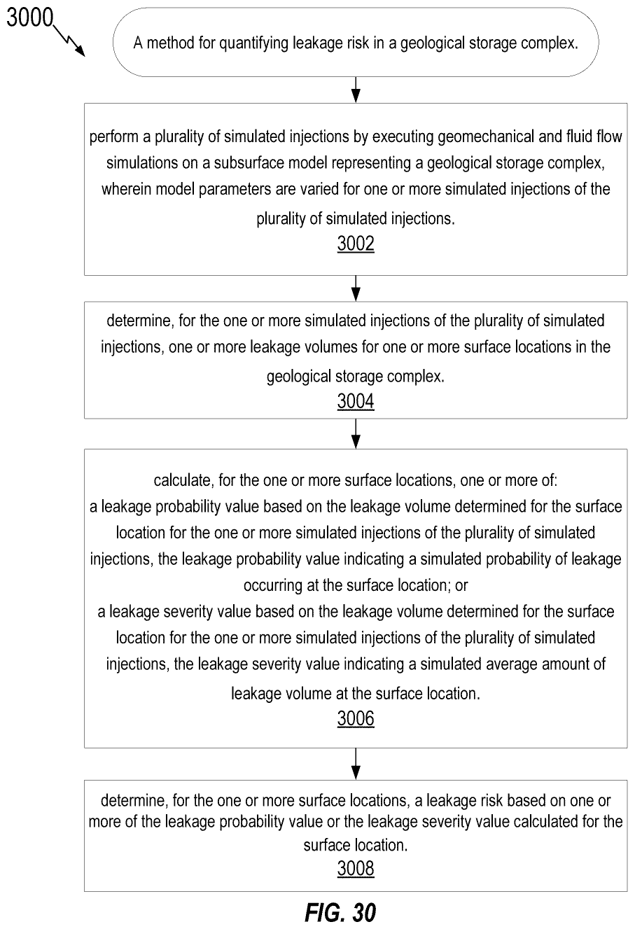

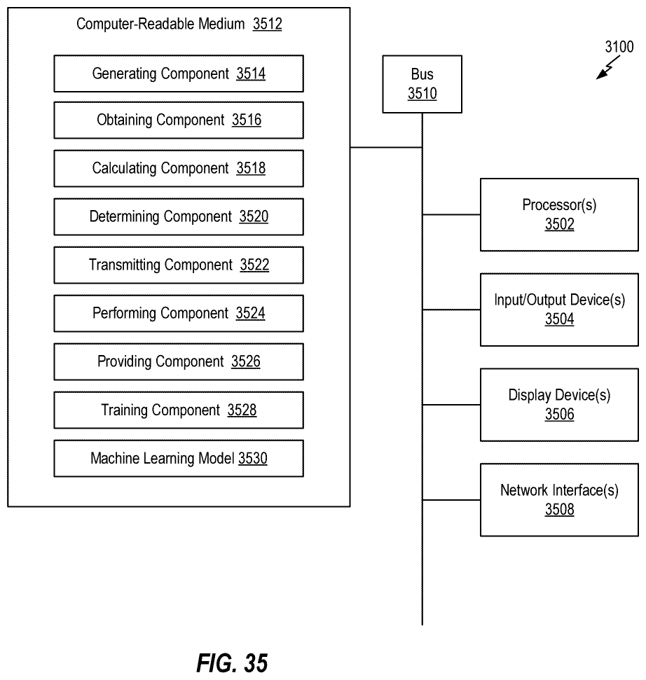

FIG. 30 depicts an example method 3000 for quantifying leakage risk in a geological storage complex. Method 3000 may be performed by one or more processor(s) of a computing device, such as processor(s) 3502 of computing system 3500 described below with respect FIG. 35.

Method 3000 begins, at step 3002, with performing a plurality of simulated injections by executing geomechanical and fluid flow simulations on a subsurface model representing a geological storage complex, wherein model parameters are varied for one or more simulated injections (e.g., each of the plurality of simulated injections) of the plurality of simulated injections.

Method 3000 proceeds to step 3004, with determining, for the one or more simulated injections of the plurality of simulated injections, one or more leakage volumes for one or more surface locations in the geological storage complex.

Method 3000 optionally proceeds to step 3006, with calculating, for the one or more surface locations, one or more of: a leakage probability value based on the leakage volume determined for the surface location for the one or more simulated injections of the plurality of simulated injections, the leakage probability value indicating a simulated probability of leakage occurring at the surface location; or a leakage severity value based on the leakage volume determined for the surface location for the one or more simulated injections of the plurality of simulated injections, the leakage severity value indicating a simulated average amount of leakage volume at the surface location.

Method 3000 optionally proceeds to step 3008, with determining, for the one or more surface locations, a leakage risk based on one or more of the leakage probability value or the leakage severity value calculated for the surface location.

In some aspects of method 3000, the leakage risk is based on the leakage probability value.

In some aspects of method 3000, the leakage risk is based on the leakage probability value and the leakage severity value.

In some aspects of method 3000, the leakage risk is based on the leakage severity value.

In some aspects of method 3000, the model parameters comprise one or more of: fluid injection rate, fluid injection pressure, fluid injection location, or fluid injection duration.

In some aspects of method 3000, the one or more surface locations comprise one or more of: a well, a fault, or a caprock.

In some aspects, method 3000 further includes generating a risk assessment report that includes the leakage risk for the one or more surface locations; and displaying the risk assessment report on a user interface.

In some aspects of method 3000, the risk assessment report comprises a risk map that includes a visual representation of the leakage risk for the one or more surface locations.

In some aspects of method 3000, the geological storage complex comprises a subsurface reservoir for storing one or more of: carbon dioxide, hydrogen, or natural gas.

In some aspects of method 3000, the leakage risk is calculated by multiplying the leakage probability value by the leakage severity value for each surface location.

In some aspects, method 3000 further includes updating the subsurface model based on the leakage risk; and performing a second plurality of simulated injections using the updated subsurface model.

In some aspects, method 3000 further includes determining a risk mitigation strategy based on the leakage risk; and implementing the risk mitigation strategy at the geological storage complex.

In some aspects of method 3000, the risk mitigation strategy comprises one or more of: adjusting fluid injection parameters, reinforcing wellbores, or installing additional monitoring equipment.

In some aspects of method 3000, the leakage probability value and the leakage severity value are calculated using one or more machine learning models trained on historical data from the geological storage complex or from similar geological storage complexes.

In some aspects of method 3000, the one or more machine learning models comprise one or more of: a neural network, a support vector machine, a decision tree, or a random forest.

In some aspects of method 3000, determining the leakage risk comprises: comparing the leakage risk to a predetermined risk threshold; and identifying a surface location as a high-risk location if the leakage risk exceeds the predetermined risk threshold.

Note that FIG. 30 is just one example of a method, and other methods including fewer, additional, or alternative operations are possible consistent with this disclosure.

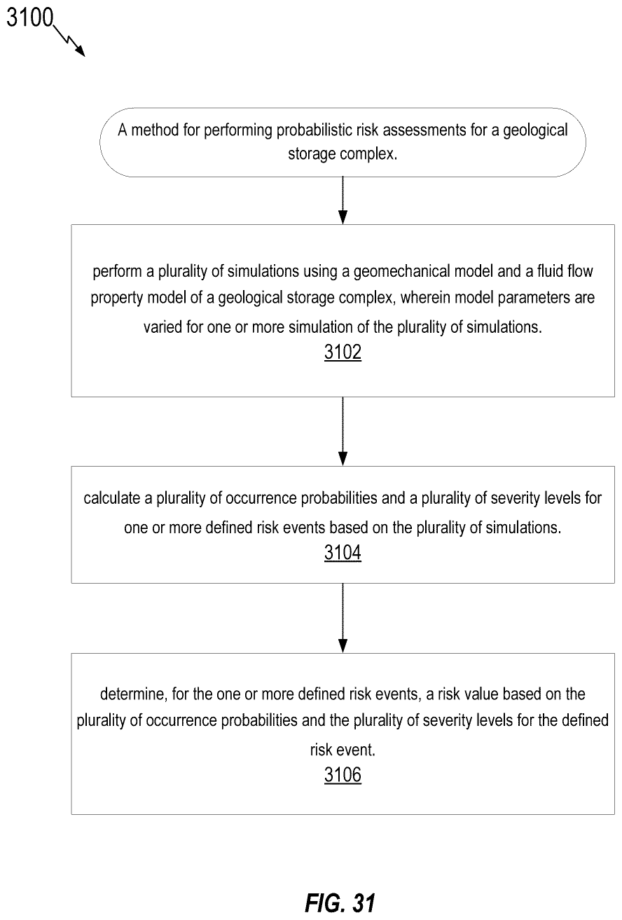

FIG. 31 depicts an example method 3100 for performing probabilistic risk assessments for a geological storage complex. Method 3100 may be performed by one or more processor(s) of a computing device, such as processor(s) 3502 of computing system 3500 described below with respect FIG. 31.

Method 3100 begins, at step 3102, with performing a plurality of simulations using a geomechanical model and a fluid flow property model of a geological storage complex, wherein model parameters are varied for one or more simulation of the plurality of simulations.

Method 3100 proceeds to step 3104, with calculating a plurality of occurrence probabilities and a plurality of severity levels for one or more defined risk events based on the plurality of simulations.

Method 3100 proceeds to step 3106, determining, for the one or more defined risk events, a risk value based on the plurality of occurrence probabilities and the plurality of severity levels for the defined risk event.

In some aspects of method 3100, the model parameters comprise one or more of: fluid injection rate, fluid injection pressure, fluid injection location, or fluid injection duration.

In some aspects of method 3100, the one or more defined risk events comprise one or more of: caprock fracturing, wellbore leakage, fault reactivation, or induced seismicity.

In some aspects, method 3100 further includes generating a risk assessment report that includes the risk value for the one or more defined risk events; and displaying the risk assessment report on a user interface.

In some aspects of method 3100, the risk assessment report comprises a risk matrix that includes a plurality of cells, each cell corresponding to a different combination of occurrence probability and severity level.

In some aspects of method 3100, the risk matrix is color-coded based on the risk value of each cell.

In some aspects of method 3100, performing the plurality of simulations comprises: performing a first subset of the plurality of simulations using the geomechanical model to generate geomechanical simulation results; and performing a second subset of the plurality of simulations using the fluid flow property model and the geomechanical simulation results to generate fluid flow simulation results.

In some aspects of method 3100, the geomechanical simulation results comprise one or more of: stress, strain, or displacement.

In some aspects of method 3100, the fluid flow simulation results comprise one or more of: fluid pressure, fluid saturation, or fluid velocity.

In some aspects of method 3100, the geological storage complex comprises a subsurface reservoir for storing one or more of: carbon dioxide, hydrogen, or natural gas.

In some aspects of method 3100, the risk value is calculated by multiplying an occurrence probability of the plurality of occurrence probabilities by a severity level of the plurality of severity levels for each defined risk event.

In some aspects, method 3100 further includes updating the geomechanical model or the fluid flow property model based on the risk value; and performing a second plurality of simulations using the updated geomechanical model or the updated fluid flow property model.

In some aspects, method 3100 further includes determining a risk mitigation strategy based on the risk value; and implementing the risk mitigation strategy at the geological storage complex.

In some aspects of method 3100, the risk mitigation strategy comprises one or more of: adjusting fluid injection parameters, reinforcing wellbores, or installing additional monitoring equipment.

In some aspects of method 3100, the occurrence probability of the plurality of occurrence probabilities and the severity level of the plurality of severity levels for each defined risk event are calculated using one or more machine learning models trained on historical data from the geological storage complex or from similar geological storage complexes.

Note that FIG. 31 is just one example of a method, and other methods including fewer, additional, or alternative operations are possible consistent with this disclosure.

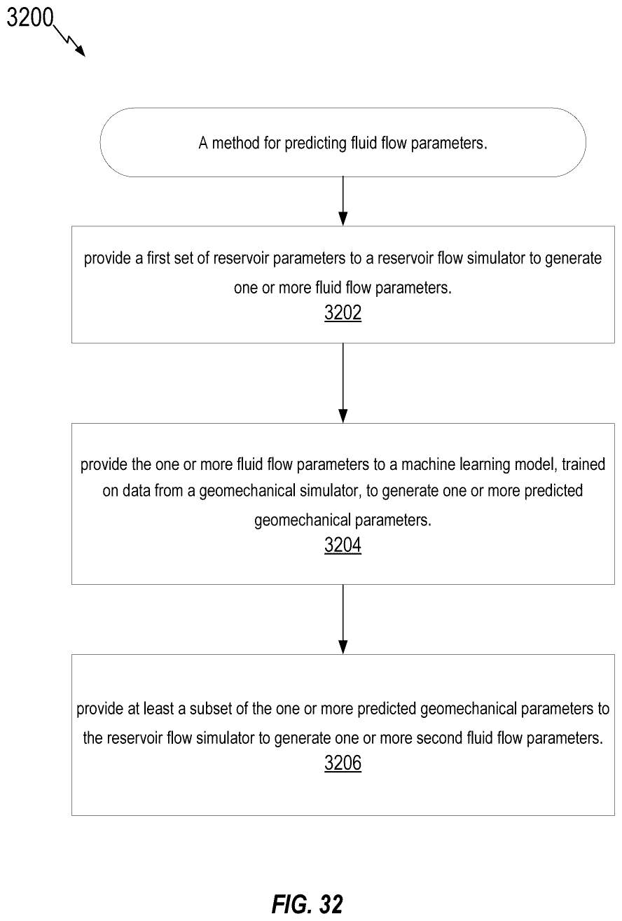

FIG. 32 depicts an example method 3200 for predicting fluid flow parameters. Method 3200 may be performed by one or more processor(s) of a computing device, such as processor(s) 3502 of computing system 3500 described below with respect FIG. 35.

Method 3200 begins, at step 3202, with providing a first set of reservoir parameters to a reservoir flow simulator to generate one or more fluid flow parameters.

Method 3200 proceeds to step 3204, with providing the one or more fluid flow parameters to a machine learning model, trained on data from a geomechanical simulator, to generate one or more predicted geomechanical parameters.

Method 3200 proceeds to step 3206, with providing at least a subset of the one or more predicted geomechanical parameters to the reservoir flow simulator to generate one or more second fluid flow parameters.

In some aspects of method 3200, the first set of reservoir parameters comprises one or more of: porosity, permeability, fluid saturation, or fluid pressure.

In some aspects of method 3200, the one or more fluid flow parameters comprise one or more of: fluid velocity, fluid pressure, or fluid saturation.

In some aspects of method 3200, the one or more predicted geomechanical parameters comprise one or more of: stress, strain, or displacement.

In some aspects, method 3200 further includes providing the one or more second fluid flow parameters to the machine learning model to generate one or more updated predicted geomechanical parameters.

In some aspects, method 3200 further includes iteratively providing the one or more updated predicted geomechanical parameters to the reservoir flow simulator and resulting fluid flow parameters based on the updated predicted geomechanical parameters back to the machine learning model until a convergence criterion is met.

In some aspects of method 3200, the convergence criterion comprises a maximum number of iterations or a minimum change in the predicted geomechanical parameters between iterations.

In some aspects of method 3200, the machine learning model comprises a neural network with an input layer, one or more hidden layers, and an output layer.

In some aspects of method 3200, the neural network is trained using a backpropagation algorithm.

In some aspects of method 3200, the machine learning model is trained on a dataset comprising pairs of fluid flow parameters and corresponding geomechanical parameters generated by the geomechanical simulator.

In some aspects of method 3200, the dataset is preprocessed before training the machine learning model, the preprocessing comprising one or more of: normalization, feature scaling, or dimensionality reduction.

In some aspects, method 3200 further includes validating an accuracy of the machine learning model by comparing the predicted geomechanical parameters with actual geomechanical parameters obtained from the geomechanical simulator for a validation dataset.

In some aspects, method 3200 further includes retraining the machine learning model if the accuracy of the machine learning model falls below a predetermined threshold.

In some aspects of method 3200, the reservoir flow simulator and the geomechanical simulator are coupled using an iterative coupling scheme.

In some aspects of method 3200, the iterative coupling scheme comprises: providing the one or more second fluid flow parameters to the geomechanical simulator; generating updated geomechanical parameters using the geomechanical simulator; and providing the updated geomechanical parameters back to the reservoir flow simulator.

In some aspects, method 3200 further includes using the one or more second fluid flow parameters to predict one or more of: well production rates, well injection rates, or reservoir pressure distribution.

Note that FIG. 35 is just one example of a method, and other methods including fewer, additional, or alternative operations are possible consistent with this disclosure.

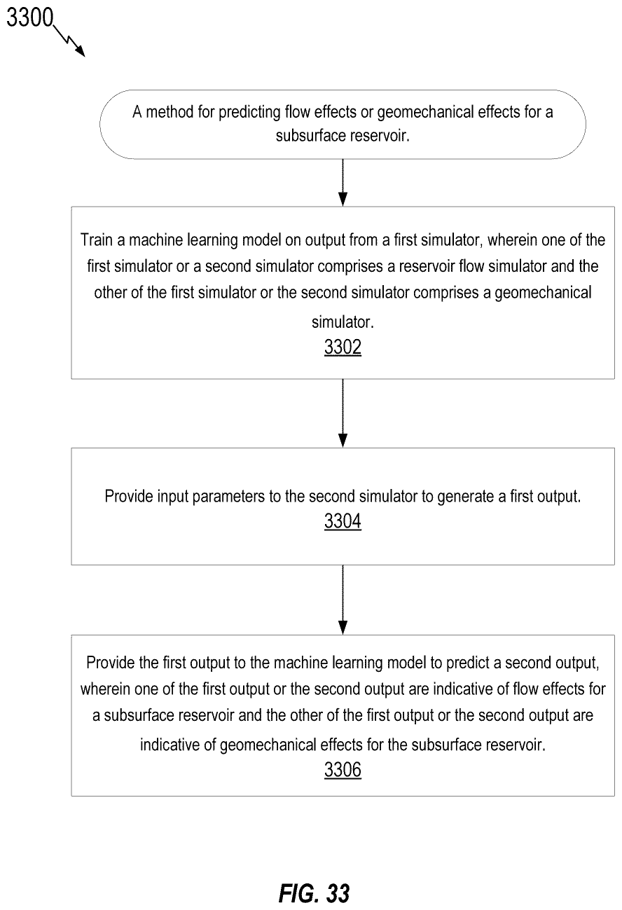

FIG. 33 depicts an example method 3300 for predicting flow effects or geomechanical effects for a subsurface reservoir. Method 3300 may be performed by one or more processor(s) of a computing device, such as processor(s) 3502 of computing system 3500 described below with respect FIG. 35.

Method 3300 begins, at step 3302, with training a machine learning model on output from a first simulator, wherein one of the first simulator or a second simulator comprises a reservoir flow simulator and the other of the first simulator or the second simulator comprises a geomechanical simulator.

Method 3300 proceeds to step 3304, with providing input parameters to the second simulator to generate a first output.

Method 3300 proceeds to step 3306, with providing the first output to the machine learning model to predict a second output, wherein one of the first output or the second output are indicative of flow effects for a subsurface reservoir and the other of the first output or the second output are indicative of geomechanical effects for the subsurface reservoir.

In some aspects of method 3300, the input parameters comprise one or more of: well locations, well injection rates, well production rates, fluid properties, or rock properties.

In some aspects of method 3300, the first output comprises one or more of: fluid pressure, fluid saturation, fluid velocity, stress, strain, or displacement.

In some aspects of method 3300, the second output comprises one or more of: fluid pressure, fluid saturation, fluid velocity, stress, strain, or displacement.

In some aspects, method 3300 further includes training a second machine learning model on output from the second simulator; and providing the second output to the second machine learning model to predict a third output, wherein the third output is indicative of a same effect as the first output.

In some aspects, method 3300 further includes retraining one or both of the machine learning models based on comparing the first output and the third output to assess an accuracy of the machine learning models.

In some aspects of method 3300, the machine learning model comprises a convolutional neural network (CNN) for processing spatial data from the first simulator or the second simulator.

In some aspects of method 3300, the machine learning model comprises a recurrent neural network (RNN) for processing time-series data from the first simulator or the second simulator.

In some aspects, method 3300 further includes preprocessing the output from the first simulator before training the machine learning model, the preprocessing comprising one or more of: data cleaning, data normalization, or feature extraction.

In some aspects, method 3300 further includes postprocessing the second output from the machine learning model, the postprocessing comprising one or more of: data denormalization, data formatting, or data visualization.

In some aspects of method 3300, the subsurface reservoir comprises one or more of: an oil reservoir, a gas reservoir, a carbon dioxide storage reservoir, or a geothermal reservoir.

In some aspects, method 3300 further includes using the second output to optimize one or more of: well placement, well injection rates, well production rates, or reservoir stimulation strategies.

In some aspects, method 3300 further includes using the second output to assess one or more of: reservoir performance, well performance, or subsurface environmental impact.

In some aspects of method 3300, the first simulator and the second simulator are coupled using a two-way coupling scheme, such that the output from one simulator is used as input to the other simulator in an iterative manner.

In some aspects of method 3300, the machine learning model is trained using transfer learning, such that the model is initially trained on a large dataset from a different but related problem before being fine-tuned on the output from the first simulator.

In some aspects, method 3300 further includes using an ensemble of machine learning models, each trained on a different subset of the output from the first simulator, to predict the second output; and combining the predictions from the ensemble of machine learning models to obtain a final prediction.

Note that FIG. 33 is just one example of a method, and other methods including fewer, additional, or alternative operations are possible consistent with this disclosure.

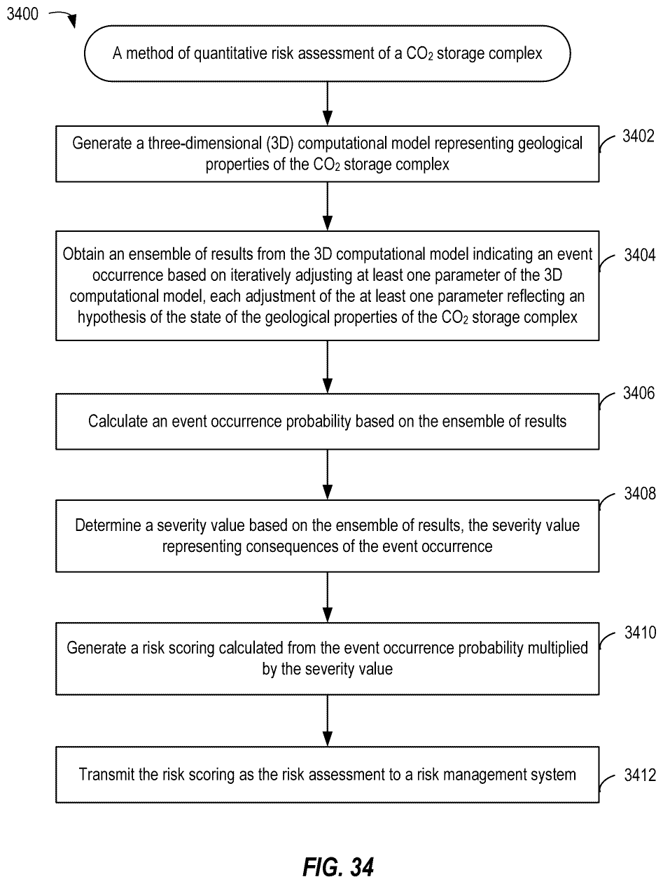

FIG. 34 shows a method 3400 implementing aspects of the present disclosure to provide quantitative risk assessment of a CO₂ storage complex.

At block 3402, the method 3400 generates a three-dimensional (3D) computational model representing geological properties of the CO₂ storage complex. The 3D computational model may include couplings (e.g., predefined evolution laws) between two or more parameters, the couplings representing interrelations between the two or more parameters. The 3D computational model may be hosted on a computing device such as computing device 3902A shown in FIG. 35. Moreover, processors, such as processors 3502 of FIG. 35 and machine learning modules 3530 of FIG. 35 may be utilized to implement the 3D computational model and perform computations to develop a quantitative risk assessment.

At block 3404, the method 3400 obtains an ensemble of results from the 3D computational model indicating an event occurrence based on iteratively adjusting at least one parameter of the 3D computational mode. Each adjustment of the at least one parameter reflects an hypothesis of the state of the geological properties of the CO₂ storage complex. In certain aspects of the present disclosure, the method 3400 may perform an uncertainty analysis on the 3D computational model to create a range of values for each of the at least one parameter. These range of values may be used as adjustment values to the 3D computational model to obtain the ensemble of results.

At block 3406, the method 3400 calculates an event occurrence probability based on the ensemble of results.

At block 3408, the method 3400 determines a severity value based on the ensemble of results. The severity value represents consequences of the event occurrence. The severity value may represent an average severity for the event occurrence based on the ensemble of results. Alternatively the severity value may represent maximum severity for the event occurrence based on the ensemble of results.

At block 3410, the method 3400 generates a risk scoring calculated from the event occurrence probability multiplied by the severity value. The risk scoring may be calculated for the event occurrence having the severity value that exceeds a severity threshold.

At block 3412, the method 3400 transmits the risk scoring as a risk assessment to a risk management system. The risk management system may be implemented, for example, on computing devices 3502B shown in FIG. 35. Moreover, the risk management system may be in communication with equipment, such CO₂ injection systems, pumps, shut-off valves, and the like, present at the CO₂ storage complex. The risk management system may be configured to perform actions intended to prevent or mitigate the risk. Such actions may include activating a shut-off valve, or reducing the injection pressure of the CO₂ injection systems, for example. Alternatively, the risk management system may issue a risk assessment report, a warning notification or alarm, for example.

In some aspects, method 3400 further includes performing an uncertainty analysis on the 3D computational model to create a range of values for each of the at least one parameter.

In some aspects of method 3400, the 3D computational model includes couplings between two or more parameters, wherein the couplings between the two or more parameters represent interrelations between the two or more parameters.

In some aspects of method 3400, the risk scoring is calculated for the event occurrence having the severity value that exceeds a severity threshold.

In some aspects of method 3400, the severity value represents an average severity for the event occurrence.

In some aspects of method 3400, calculating the event occurrence probability comprises determining a percentage of the ensemble of results that indicate the event occurrence.

In some aspects of method 3400, determining the severity value comprises: categorizing each result of the ensemble of results into a severity category; and assigning a numerical value to each severity category.

In some aspects, method 3400 further includes determining a risk mitigation strategy based on comparing the risk scoring to a risk threshold value.

In some aspects of method 3400, the risk mitigation strategy comprises at least one of adjusting an injection rate, adjusting an injection pressure, or adjusting a location of an injection well.

In some aspects, method 3400 further includes updating the 3D computational model based on new data obtained from the CO2 storage complex; obtaining a second ensemble of results from the updated 3D computational model indicating a second event occurrence based on iteratively adjusting at least one parameter of the updated 3D computational model, each adjustment of the at least one parameter reflecting an hypothesis of a state of the geological properties of the CO2 storage complex; calculating a second event occurrence probability based on the second ensemble of results; determining a second severity value based on the second ensemble of results, the second severity value representing consequences of the second event occurrence; and generating a second risk scoring calculated from the second event occurrence probability multiplied by the second severity value.

In some aspects of method 3400, the event occurrence comprises at least one of a CO2 leakage event, an induced seismicity event, and a ground deformation event.

In some aspects of method 3400, transmitting the risk scoring comprises displaying the risk scoring on a user interface of the risk management system.

In some aspects of method 3400, displaying the risk scoring comprises displaying a risk matrix comprising a plurality of cells, each cell representing a combination of an event occurrence probability and a severity value.

Note that FIG. 34 is just one example of a method, and other methods including fewer, additional, or alternative operations are possible consistent with this disclosure.

### Example Processing System

FIG. 35 depicts an example processing system 3500 configured to perform various aspects described herein, including, for example, method 3000 as described above with respect to FIG. 30, method 3100 as described above with respect to FIG. 31, method 3200 as described above with respect to FIG. 32, method 3300 as described above with respect to FIG. 33, and method 3400 as described above with respect to FIG. 34.

Processing system 3900 is generally be an example of an electronic device configured to execute computer-executable instructions, such as those derived from compiled computer code, including without limitation personal computers, tablet computers, servers, smart phones, smart devices, wearable devices, augmented and/or virtual reality devices, and others.

In the depicted example, processing system 3500 includes one or more processors 3502, one or more input/output devices 3504, one or more display devices 3506, one or more network interfaces 3508 through which processing system 3500 is connected to one or more networks (e.g., a local network, an intranet, the Internet, or any other group of processing systems communicatively connected to each other), and computer-readable medium 3512. In the depicted example, the aforementioned components are coupled by a bus 3510, which may generally be configured for data exchange amongst the components. Bus 3510 may be representative of multiple buses, while only one is depicted for simplicity.

Processor(s) 3502 are generally configured to retrieve and execute instructions stored in one or more memories, including local memories like computer-readable medium 3512, as well as remote memories and data stores. Similarly, processor(s) 3502 are configured to store application data residing in local memories like the computer-readable medium 3512, as well as remote memories and data stores. More generally, bus 3510 is configured to transmit programming instructions and application data among the processor(s) 3502, display device(s) 3506, network interface(s) 3508, and/or computer-readable medium 3512. In certain embodiments, processor(s) 3502 are representative of a one or more central processing units (CPUs), graphics processing unit (GPUs), tensor processing unit (TPUs), accelerators, and other processing devices.

Input/output device(s) 3504 may include any device, mechanism, system, interactive display, and/or various other hardware and software components for communicating information between processing system 3500 and a user of processing system 3500. For example, input/output device(s) 3504 may include input hardware, such as a keyboard, touch screen, button, microphone, speaker, and/or other device for receiving inputs from the user and sending outputs to the user.

Display device(s) 3506 may generally include any sort of device configured to display data, information, graphics, user interface elements, and the like to a user. For example, display device(s) 3506 may include internal and external displays such as an internal display of a tablet computer or an external display for a server computer or a projector. Display device(s) 3506 may further include displays for devices, such as augmented, virtual, and/or extended reality devices. In various embodiments, display device(s) 916 may be configured to display a graphical user interface.

Network interface(s) 3508 provide processing system 3500 with access to external networks and thereby to external processing systems. Network interface(s) 3508 can generally be any hardware and/or software capable of transmitting and/or receiving data via a wired or wireless network connection. Accordingly, network interface(s) 3508 can include a communication transceiver for sending and/or receiving any wired and/or wireless communication.

Computer-readable medium 3512 may be a volatile memory, such as a random access memory (RAM), or a nonvolatile memory, such as nonvolatile random access memory (NVRAM), or the like. In this example, computer-readable medium 3512 includes a generating component 3514, obtaining component 3516, calculating component 3518, determining component 3520, transmitting component 3522, performing component 3524, providing component 3526, and a training component 3528.

In certain aspects, the generating component 3514 is configured to generate a three-dimensional (3D) computational model representing geological properties of the CO2 storage complex, as described in block 3402 of method 3400 depicted in FIG. 34.

In certain aspects, the obtaining component 3516 is configured to obtain an ensemble of results from the 3D computational model indicating an event occurrence based on iteratively adjusting at least one parameter of the 3D computational model, each adjustment of the at least one parameter reflecting a hypothesis of a state of the geological properties of the CO2 storage complex, as described in block 3404 of method 3400 depicted in FIG. 34.

In certain aspects, the calculating component 3518 is configured to calculate an event occurrence probability based on the ensemble of results, as described in block 3406 of method 3400 depicted in FIG. 34.

In certain aspects, the determining component 3420 is configured to determine a severity value based on the ensemble of results, the severity value representing consequences of the event occurrence, as described in step 3808 of method 3800 depicted in FIG. 34.

In certain aspects, the transmitting component 3422 is configured to transmit the risk scoring as a risk assessment to a risk management system, as described in block 3412 of method 3400 depicted in FIG. 34.

In certain aspects, the performing component 3524 is configured to perform a plurality of simulations using a geomechanical model and a fluid flow property model of a geological storage complex, wherein model parameters are varied for one or more simulations of the plurality of simulations, as described in step 3102 of method 3100 depicted in FIG. 35.

In certain aspects, the providing component 3526 is configured to provide a first set of reservoir parameters to a reservoir flow simulator to generate one or more fluid flow parameters, as described in step 3202 of method 3200 depicted in FIG. 32. Note that FIG. 35 is just one example of a processing system consistent with aspects described herein, and other processing systems having additional, alternative, or fewer components are possible consistent with this disclosure.

### Example Clauses

Implementation examples are described in the following numbered clauses:

Clause 1: A method of quantitative risk assessment of a CO2 storage complex, comprising: generating a three-dimensional (3D) computational model representing geological properties of the CO2 storage complex; obtaining an ensemble of results from the 3D computational model indicating an event occurrence based on iteratively adjusting at least one parameter of the 3D computational model, each adjustment of the at least one parameter reflecting an hypothesis of a state of the geological properties of the CO2 storage complex; calculating an event occurrence probability based on the ensemble of results; determining a severity value based on the ensemble of results, the severity value representing consequences of the event occurrence; generating a risk scoring calculated from the event occurrence probability multiplied by the severity value; and transmitting the risk scoring as a risk assessment to a risk management system.

Clause 2: The method of Clause 1, further comprising: performing an uncertainty analysis on the 3D computational model to create a range of values for each of the at least one parameter.

Clause 3: The method of Clause 1 or Clause 2, wherein the 3D computational model includes couplings between two or more parameters, wherein the couplings between the two or more parameters represent interrelations between the two or more parameters.

Clause 4: The method of any one of Clauses 1-3, wherein the risk scoring is calculated for the event occurrence having the severity value that exceeds a severity threshold.

Clause 5: The method of any one of Clauses 1-4, wherein the severity value represents an average severity for the event occurrence.

Clause 6: The method of any one of Clauses 1-5, wherein calculating the event occurrence probability comprises determining a percentage of the ensemble of results that indicate the event occurrence.

Clause 7: The method of any one of Clauses 1-6, wherein determining the severity value comprises: categorizing each result of the ensemble of results into a severity category; and assigning a numerical value to each severity category.

Clause 8: The method of any one of Clauses 1-7, further comprising determining a risk mitigation strategy based on comparing the risk scoring to a risk threshold value.

Clause 9: The method of Clause 8, wherein the risk mitigation strategy comprises at least one of adjusting an injection rate, adjusting an injection pressure, or adjusting a location of an injection well.

Clause 10: The method of any one of Clauses 1-9, further comprising: updating the 3D computational model based on new data obtained from the CO2 storage complex; obtaining a second ensemble of results from the updated 3D computational model indicating a second event occurrence based on iteratively adjusting at least one parameter of the updated 3D computational model, each adjustment of the at least one parameter reflecting an hypothesis of a state of the geological properties of the CO2 storage complex; calculating a second event occurrence probability based on the second ensemble of results; determining a second severity value based on the second ensemble of results, the second severity value representing consequences of the second event occurrence; and generating a second risk scoring calculated from the second event occurrence probability multiplied by the second severity value.

Clause 11: The method of any one of Clauses 1-10, wherein the event occurrence comprises at least one of a CO2 leakage event, an induced seismicity event, and a ground deformation event.

Clause 12: The method of any one of Clauses 1-11, wherein transmitting the risk scoring comprises displaying the risk scoring on a user interface of the risk management system.

Clause 13: The method of Clause 12, wherein displaying the risk scoring comprises displaying a risk matrix comprising a plurality of cells, each cell representing a combination of an event occurrence probability and a severity value.

Clause 14: A method for quantifying leakage risk in a geological storage complex, the method comprising: performing a plurality of simulated injections by executing geomechanical and fluid flow simulations on a subsurface model representing a geological storage complex, wherein model parameters are varied for one or more simulated injections of the plurality of simulated injections; determining, for one or more simulated injections of the plurality of simulated injections, one or more leakage volumes for one or more surface locations in the geological storage complex; calculating, for the one or more surface locations, one or more of: a leakage probability value based on the leakage volume determined for the surface location for the one or more simulated injections of the plurality of simulated injections, the leakage probability value indicating a simulated probability of leakage occurring at the surface location; or a leakage severity value based on the leakage volume determined for the surface location for the one or more simulated injections of the plurality of simulated injections, the leakage severity value indicating a simulated average amount of leakage volume at the surface location; and determining, for the one or more surface locations, a leakage risk based on one or more of the leakage probability value or the leakage severity value calculated for the surface location.

Clause 15: The method of Clause 14, wherein the leakage risk is based on the leakage probability value.

Clause 16: The method of Clause 14 or Clause 15, wherein the leakage risk is based on the leakage probability value and the leakage severity value.

Clause 17: The method of any one of Clauses 14-16, wherein the leakage risk is based on the leakage severity value.

Clause 18: The method of any one of Clauses 14-17, wherein the model parameters comprise one or more of: fluid injection rate, fluid injection pressure, fluid injection location, or fluid injection duration.

Clause 19: The method of any one of Clauses 14-18, wherein the one or more surface locations comprise one or more of: a well, a fault, or a caprock.

Clause 20: The method of any one of Clauses 14-19, further comprising: generating a risk assessment report that includes the leakage risk for the one or more surface locations; and displaying the risk assessment report on a user interface.

Clause 21: The method of Clause 20, wherein the risk assessment report comprises a risk map that includes a visual representation of the leakage risk for the one or more surface locations.

Clause 22: The method of any one of Clauses 14-21, wherein the geological storage complex comprises a subsurface reservoir for storing one or more of: carbon dioxide, hydrogen, or natural gas.

Clause 23: The method of any one of Clauses 14-22, wherein the leakage risk is calculated by multiplying the leakage probability value by the leakage severity value for each surface location.

Clause 24: The method of any one of Clauses 14-23, further comprising: updating the subsurface model based on the leakage risk; and performing a second plurality of simulated injections using the updated subsurface model.

Clause 25: The method of any one of Clauses 14-24, further comprising: determining a risk mitigation strategy based on the leakage risk; and implementing the risk mitigation strategy at the geological storage complex.

Clause 26: The method of Clause 25, wherein the risk mitigation strategy comprises one or more of: adjusting fluid injection parameters, reinforcing wellbores, or installing additional monitoring equipment.

Clause 27: The method of any one of Clauses 14-26, wherein the leakage probability value and the leakage severity value are calculated using one or more machine learning models trained on historical data from the geological storage complex or from similar geological storage complexes.

Clause 28: The method of Clause 27, wherein the one or more machine learning models comprise one or more of: a neural network, a support vector machine, a decision tree, or a random forest.

Clause 29: The method of any one of Clauses 14-28, wherein determining the leakage risk comprises: comparing the leakage risk to a predetermined risk threshold; and identifying a surface location as a high-risk location if the leakage risk exceeds the predetermined risk threshold.

Clause 30: A method for performing probabilistic risk assessments for a geological storage complex, comprising: performing a plurality of simulations using a geomechanical model and a fluid flow property model of a geological storage complex, wherein model parameters are varied for one or more simulation of the plurality of simulations; calculating a plurality of occurrence probabilities and a plurality of severity levels for one or more defined risk events based on the plurality of simulations; and determining, for the one or more defined risk events, a risk value based on the plurality of occurrence probabilities and the plurality of severity levels for the defined risk event.

Clause 31: The method of Clause 30, wherein the model parameters comprise one or more of: fluid injection rate, fluid injection pressure, fluid injection location, or fluid injection duration.

Clause 32: The method of Clause 30 or Clause 31, wherein the one or more defined risk events comprise one or more of: caprock fracturing, wellbore leakage, fault reactivation, or induced seismicity.

Clause 33: The method of any one of Clauses 30-32, further comprising: generating a risk assessment report that includes the risk value for the one or more defined risk events; and displaying the risk assessment report on a user interface.

Clause 34: The method of Clause 33, wherein the risk assessment report comprises a risk matrix that includes a plurality of cells, each cell corresponding to a different combination of occurrence probability and severity level.

Clause 35: The method of Clause 34, wherein the risk matrix is color-coded based on the risk value of each cell.

Clause 36: The method of any one of Clauses 30-35, wherein performing the plurality of simulations comprises: performing a first subset of the plurality of simulations using the geomechanical model to generate geomechanical simulation results; and performing a second subset of the plurality of simulations using the fluid flow property model and the geomechanical simulation results to generate fluid flow simulation results.

Clause 37: The method of Clause 36, wherein the geomechanical simulation results comprise one or more of: stress, strain, or displacement.

Clause 38: The method of Clause 36 or Clause 37, wherein the fluid flow simulation results comprise one or more of: fluid pressure, fluid saturation, or fluid velocity.

Clause 39: The method of any one of Clauses 30-38, wherein the geological storage complex comprises a subsurface reservoir for storing one or more of: carbon dioxide, hydrogen, or natural gas.

Clause 40: The method of any one of Clauses 30-39, wherein the risk value is calculated by multiplying an occurrence probability of the plurality of occurrence probabilities by a severity level of the plurality of severity levels for each defined risk event.

Clause 41: The method of any one of Clauses 30-40, further comprising: updating the geomechanical model or the fluid flow property model based on the risk value; and performing a second plurality of simulations using the updated geomechanical model or the updated fluid flow property model.

Clause 42: The method of any one of Clauses 30-41, further comprising: determining a risk mitigation strategy based on the risk value; and implementing the risk mitigation strategy at the geological storage complex.

Clause 43: The method of Clause 42, wherein the risk mitigation strategy comprises one or more of: adjusting fluid injection parameters, reinforcing wellbores, or installing additional monitoring equipment.

Clause 44: The method of any one of Clauses 30-43, wherein the occurrence probability of the plurality of occurrence probabilities and the severity level of the plurality of severity levels for each defined risk event are calculated using one or more machine learning models trained on historical data from the geological storage complex or from similar geological storage complexes.

Clause 45: A method for predicting fluid flow parameters, comprising: providing a first set of reservoir parameters to a reservoir flow simulator to generate one or more fluid flow parameters; providing the one or more fluid flow parameters to a machine learning model, trained on data from a geomechanical simulator, to generate one or more predicted geomechanical parameters; and providing at least a subset of the one or more predicted geomechanical parameters to the reservoir flow simulator to generate one or more second fluid flow parameters.

Clause 46: The method of Clause 45, wherein the first set of reservoir parameters comprises one or more of: porosity, permeability, fluid saturation, or fluid pressure.

Clause 47: The method of Clause 45 or Clause 46, wherein the one or more fluid flow parameters comprise one or more of: fluid velocity, fluid pressure, or fluid saturation.

Clause 48: The method of any one of Clauses 45-47, wherein the one or more predicted geomechanical parameters comprise one or more of: stress, strain, or displacement.

Clause 49: The method of any one of Clauses 45-48, further comprising: providing the one or more second fluid flow parameters to the machine learning model to generate one or more updated predicted geomechanical parameters.

Clause 50: The method of Clause 49, further comprising: iteratively providing the one or more updated predicted geomechanical parameters to the reservoir flow simulator and resulting fluid flow parameters based on the updated predicted geomechanical parameters back to the machine learning model until a convergence criterion is met.

Clause 51: The method of Clause 50, wherein the convergence criterion comprises a maximum number of iterations or a minimum change in the predicted geomechanical parameters between iterations.

Clause 52: The method of any one of Clauses 45-51, wherein the machine learning model comprises a neural network with an input layer, one or more hidden layers, and an output layer.

Clause 53: The method of Clause 52, wherein the neural network is trained using a backpropagation algorithm.

Clause 54: The method of any one of Clauses 45-53, wherein the machine learning model is trained on a dataset comprising pairs of fluid flow parameters and corresponding geomechanical parameters generated by the geomechanical simulator.

Clause 55: The method of Clause 54, wherein the dataset is preprocessed before training the machine learning model, the preprocessing comprising one or more of: normalization, feature scaling, or dimensionality reduction.

Clause 56: The method of any one of Clauses 45-55, further comprising: validating an accuracy of the machine learning model by comparing the predicted geomechanical parameters with actual geomechanical parameters obtained from the geomechanical simulator for a validation dataset.

Clause 57: The method of Clause 56, further comprising: retraining the machine learning model if the accuracy of the machine learning model falls below a predetermined threshold.

Clause 58: The method of any one of Clauses 45-57, wherein the reservoir flow simulator and the geomechanical simulator are coupled using an iterative coupling scheme.

Clause 59: The method of Clause 58, wherein the iterative coupling scheme comprises: providing the one or more second fluid flow parameters to the geomechanical simulator; generating updated geomechanical parameters using the geomechanical simulator; and providing the updated geomechanical parameters back to the reservoir flow simulator.

Clause 60: The method of any one of Clauses 45-59, further comprising: using the one or more second fluid flow parameters to predict one or more of: well production rates, well injection rates, or reservoir pressure distribution.

Clause 61: A method for predicting flow effects or geomechanical effects for a subsurface reservoir, comprising: training a machine learning model on output from a first simulator, wherein one of the first simulator or a second simulator comprises a reservoir flow simulator and the other of the first simulator or the second simulator comprises a geomechanical simulator; providing input parameters to the second simulator to generate a first output; and providing the first output to the machine learning model to predict a second output, wherein one of the first output or the second output are indicative of flow effects for a subsurface reservoir and the other of the first output or the second output are indicative of geomechanical effects for the subsurface reservoir.

Clause 62: The method of Clause 61, wherein the input parameters comprise one or more of: well locations, well injection rates, well production rates, fluid properties, or rock properties.

Clause 63: The method of Clause 61 or Clause 62, wherein the first output comprises one or more of: fluid pressure, fluid saturation, fluid velocity, stress, strain, or displacement.

Clause 64: The method of any one of Clauses 61-63, wherein the second output comprises one or more of: fluid pressure, fluid saturation, fluid velocity, stress, strain, or displacement.

Clause 65: The method of any one of Clauses 61-64, further comprising: training a second machine learning model on output from the second simulator; and providing the second output to the second machine learning model to predict a third output, wherein the third output is indicative of a same effect as the first output.

Clause 66: The method of Clause 65, further comprising retraining one or both of the machine learning models based on comparing the first output and the third output to assess an accuracy of the machine learning models.

Clause 67: The method of any one of Clauses 61-66, wherein the machine learning model comprises a convolutional neural network (CNN) for processing spatial data from the first simulator or the second simulator.

Clause 68: The method of Clause 67, wherein the machine learning model comprises a recurrent neural network (RNN) for processing time-series data from the first simulator or the second simulator.

Clause 69: The method of any one of Clauses 61-68, further comprising: preprocessing the output from the first simulator before training the machine learning model, the preprocessing comprising one or more of: data cleaning, data normalization, or feature extraction.

Clause 70: The method of any one of Clauses 61-69, further comprising: postprocessing the second output from the machine learning model, the postprocessing comprising one or more of: data denormalization, data formatting, or data visualization.

Clause 71: The method of any one of Clauses 61-70, wherein the subsurface reservoir comprises one or more of: an oil reservoir, a gas reservoir, a carbon dioxide storage reservoir, or a geothermal reservoir.

Clause 72: The method of any one of Clauses 61-71, further comprising: using the second output to optimize one or more of: well placement, well injection rates, well production rates, or reservoir stimulation strategies.

Clause 73: The method of any one of Clauses 61-72, further comprising: using the second output to assess one or more of: reservoir performance, well performance, or subsurface environmental impact.

Clause 74: The method of any one of Clauses 61-73, wherein the first simulator and the second simulator are coupled using a two-way coupling scheme, such that the output from one simulator is used as input to the other simulator in an iterative manner.

Clause 75: The method of any one of Clauses 61-74, wherein the machine learning model is trained using transfer learning, such that the model is initially trained on a large dataset from a different but related problem before being fine-tuned on the output from the first simulator.

Clause 76: The method of any one of Clauses 61-75, further comprising: using an ensemble of machine learning models, each trained on a different subset of the output from the first simulator, to predict the second output; and combining the predictions from the ensemble of machine learning models to obtain a final prediction.

Clause 77: A processing system, comprising: a memory comprising computer-executable instructions; and a processor configured to execute the computer-executable instructions and cause the processing system to perform a method in accordance with any one of Clauses 1-76.

Clause 78: A processing system, comprising means for performing a method in accordance with any one of Clauses 1-76.

Clause 79: A non-transitory computer-readable medium storing program code for causing a processing system to perform the steps of any one of Clauses 1-76.

Clause 80: A computer program product embodied on a computer-readable storage medium comprising code for performing a method in accordance with any one of Clauses 1-76.

### ADDITIONAL CONSIDERATIONS

The preceding description is provided to enable any person skilled in the art to practice the various embodiments described herein. The examples discussed herein are not limiting of the scope, applicability, or embodiments set forth in the claims. Various modifications to these embodiments will be readily apparent to those skilled in the art, and the generic principles defined herein may be applied to other embodiments. For example, changes may be made in the function and arrangement of elements discussed without departing from the scope of the disclosure. Various examples may omit, substitute, or add various procedures or components as appropriate. For instance, the methods described may be performed in an order different from that described, and various steps may be added, omitted, or combined. Also, features described with respect to some examples may be combined in some other examples. For example, an apparatus may be implemented or a method may be practiced using any number of the aspects set forth herein. In addition, the scope of the disclosure is intended to cover such an apparatus or method that is practiced using other structure, functionality, or structure and functionality in addition to, or other than, the various aspects of the disclosure set forth herein. It should be understood that any aspect of the disclosure disclosed herein may be embodied by one or more elements of a claim.

As used herein, the word “exemplary” means “serving as an example, instance, or illustration.” Any aspect described herein as “exemplary” is not necessarily to be construed as preferred or advantageous over other aspects.

As used herein, a phrase referring to “at least one of” a list of items refers to any combination of those items, including single members. As an example, “at least one of: a, b, or c” is intended to cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). Reference to an element in the singular is not intended to mean only one unless specifically so stated, but rather “one or more.” For example, reference to an element (e.g., “a processor,” “a memory,” etc.), unless otherwise specifically stated, should be understood to refer to one or more elements (e.g., “one or more processors,” “one or more memories,” etc.). The terms “set” and “group” are intended to include one or more elements, and may be used interchangeably with “one or more.” Where reference is made to one or more elements performing functions (e.g., steps of a method), one element may perform all functions, or more than one element may collectively perform the functions. When more than one element collectively performs the functions, each function need not be performed by each of those elements (e.g., different functions may be performed by different elements) and/or each function need not be performed in whole by only one element (e.g., different elements may perform different sub-functions of a function). Similarly, where reference is made to one or more elements configured to cause another element (e.g., an apparatus) to perform functions, one element may be configured to cause the other element to perform all functions, or more than one element may collectively be configured to cause the other element to perform the functions. Unless specifically stated otherwise, the term “some” refers to one or more.

As used herein, the term “determining” encompasses a wide variety of actions. For example, “determining” may include calculating, computing, processing, deriving, investigating, looking up (e.g., looking up in a table, a database, or another data structure), ascertaining and the like. Also, “determining” may include receiving (e.g., receiving information), accessing (e.g., accessing data in a memory) and the like. Also, “determining” may include resolving, selecting, choosing, establishing and the like.

The methods disclosed herein comprise one or more steps or actions for achieving the methods. The method steps and/or actions may be interchanged with one another without departing from the scope of the claims. In other words, unless a specific order of steps or actions is specified, the order and/or use of specific steps and/or actions may be modified without departing from the scope of the claims. Further, the various operations of methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

The following claims are not intended to be limited to the embodiments shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 USC § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

As described herein, machine learning models using training data generated from reservoir flow simulators and geomechanical simulators can provide predictions of geomechanical responses to changing pressures, saturations, and temperatures during fluid injection and production operations. Such predictions can be provided utilizing less computational compute time. In such an approach, geomechanical effects arising from subsurface fluid flow can be quickly predicted to enable quantification of fault reactivation risk, fracture growth risk, and other leakage pathways that could allow carbon dioxide to escape the storage zone. The coupled flow simulator and machine learning models can determine geomechanical risks that may lead to carbon dioxide leakage for a given subsurface formation and injection plan.

What is claimed is:

1. A method of quantitative risk assessment of a CO₂ storage complex, comprising:
generating a three-dimensional (3D) computational model representing geological properties of the CO₂ storage complex;
obtaining an ensemble of results from the 3D computational model indicating an event occurrence based on iteratively adjusting at least one parameter of the 3D computational model, each adjustment of the at least one parameter reflecting an hypothesis of a state of the geological properties of the CO₂ storage complex;
calculating an event occurrence probability based on the ensemble of results;
determining a severity value based on the ensemble of results, the severity value representing consequences of the event occurrence;
generating a risk scoring calculated from the event occurrence probability multiplied by the severity value; and
transmitting the risk scoring as a risk assessment to a risk management system.

2. The method of claim 1, further comprising: performing an uncertainty analysis on the 3D computational model to create a range of values for each of the at least one parameter.

3. The method of claim 1, wherein the 3D computational model includes couplings between two or more parameters, wherein the couplings between the two or more parameters represent interrelations between the two or more parameters.

4. The method of claim 1, wherein the risk scoring is calculated for the event occurrence having the severity value that exceeds a severity threshold.

5. The method of claim 1, wherein the severity value represents an average severity for the event occurrence.

6. The method of claim 1, wherein calculating the event occurrence probability comprises determining a percentage of the ensemble of results that indicate the event occurrence.

7. The method of claim 1, wherein determining the severity value comprises:
categorizing each result of the ensemble of results into a severity category; and
assigning a numerical value to each severity category.

8. The method of claim 1, further comprising determining a risk mitigation strategy based on comparing the risk scoring to a risk threshold value.

9. The method of claim 8, wherein the risk mitigation strategy comprises at least one of adjusting an injection rate, adjusting an injection pressure, or adjusting a location of an injection well.

10. The method of claim 1, further comprising:
updating the 3D computational model based on new data obtained from the CO₂ storage complex;
obtaining a second ensemble of results from the updated 3D computational model indicating a second event occurrence based on iteratively adjusting at least one parameter of the updated 3D computational model, each adjustment of the at least one parameter reflecting an hypothesis of a state of the geological properties of the CO₂ storage complex;
calculating a second event occurrence probability based on the second ensemble of results;
determining a second severity value based on the second ensemble of results, the second severity value representing consequences of the second event occurrence; and
generating a second risk scoring calculated from the second event occurrence probability multiplied by the second severity value.

11. The method of claim 1, wherein the event occurrence comprises at least one of a CO2 leakage event, an induced seismicity event, and a ground deformation event.

12. The method of claim 1, wherein transmitting the risk scoring comprises displaying the risk scoring on a user interface of the risk management system.

13. The method of claim 12, wherein displaying the risk scoring comprises displaying a risk matrix comprising a plurality of cells, each cell representing a combination of an event occurrence probability and a severity value.

14. A method for quantifying leakage risk in a geological storage complex, the method comprising:
performing a plurality of simulated injections by executing geomechanical and fluid flow simulations on a subsurface model representing a geological storage complex, wherein model parameters are varied for one or more simulated injections of the plurality of simulated injections;
determining, for one or more simulated injections of the plurality of simulated injections, one or more leakage volumes for one or more surface locations in the geological storage complex;
calculating, for the one or more surface locations, one or more of:
a leakage probability value based on the leakage volume determined for the surface location for the one or more simulated injections of the plurality of simulated injections, the leakage probability value indicating a simulated probability of leakage occurring at the surface location; or
a leakage severity value based on the leakage volume determined for the surface location for the one or more simulated injections of the plurality of simulated injections, the leakage severity value indicating a simulated average amount of leakage volume at the surface location; and
determining, for the one or more surface locations, a leakage risk based on one or more of the leakage probability value or the leakage severity value calculated for the surface location.

15. The method of claim 14, further comprising:
generating a risk assessment report that includes the leakage risk for the one or more surface locations; and
displaying the risk assessment report on a user interface.

16. The method of claim 14, further comprising:
updating the subsurface model based on the leakage risk; and
performing a second plurality of simulated injections using the updated subsurface model.

17. The method of claim 14, further comprising:
determining a risk mitigation strategy based on the leakage risk; and
implementing the risk mitigation strategy at the geological storage complex.

18. The method of claim 17, wherein the risk mitigation strategy comprises one or more of: adjusting fluid injection parameters, reinforcing wellbores, or installing additional monitoring equipment.

19. The method of claim 14, wherein the leakage probability value and the leakage severity value are calculated using one or more machine learning models trained on historical data from the geological storage complex or from similar geological storage complexes.

20. A processing system, comprising:
a memory comprising computer-executable instructions; and
a processor configured to execute the computer-executable instructions and cause the processing system to:
generate a three-dimensional (3D) computational model representing geological properties of a CO2 storage complex;
obtain an ensemble of results from the 3D computational model indicating an event occurrence based on iteratively adjusting at least one parameter of the 3D computational model, each adjustment of the at least one parameter reflecting an hypothesis of a state of the geological properties of the CO2 storage complex;
calculate an event occurrence probability based on the ensemble of results;
determine a severity value based on the ensemble of results, the severity value representing consequences of the event occurrence;
generate a risk scoring calculated from the event occurrence probability multiplied by the severity value; and
transmit the risk scoring as a risk assessment to a risk management system.
